(19) United States
(12) Patent Application Publication
(10) Pub. No.: US 2022/0277790 A1
(43) Pub. Date: Sep. 1, 2022

(54) MEMORY CHIP AND METHOD OF CONTROLLING MEMORY CHIP

(71) Applicant: Sony Semiconductor Solutions Corporation, Kanagawa (JP)

(72) Inventors: Haruhiko Terada, Kanagawa (JP); Yoshiyuki Shibahara, Tokyo (JP)

(21) Appl. No.: 17/627,989

(22) PCT Filed: Jul. 21, 2020
(86) PCT No.: PCT/JP2020/028259

§ 371 Date: Jan. 18, 2022

(30) Foreign Application Priority Data
Aug. 30, 2019 (JP) 2019-157824

(51) Int. Cl. G11C 13/00

(52) U.S. Cl. CPC G11C 13/0033; G11C 13/0026; G11C 13/0028

(57) ABSTRACT

An object of the present disclosure is to provide a memory chip and a method of controlling a memory chip that make it possible to detect a disturb failure. The memory chip includes: a memory cell including a variable resistor element and a switching element, the variable resistor element reversibly changeable between a low resistive state and a high resistive state, and the switching element having nonlinear current-voltage characteristics and being coupled in series to the variable resistor element; a voltage generator that generates a first voltage to be applied to the memory cell in a case where the variable resistor element is changed to the low resistive state, a second voltage to be applied to the memory cell in a case where a resistive state of the variable resistor element is detected, and a specific voltage that is equal to or higher than a half of the first voltage and lower than the second voltage; and a control unit that controls the memory cell.

### TECHNICAL FIELD

The present disclosure relates to a memory chip and a method of controlling a memory chip.

### BACKGROUND ART

Recently, as a memory having a storage capacity exceeding a storage capacity of a DRAM and high speed comparable to speed of the DRAM while having nonvolatility, a ReRAM (Resistive RAM) has attracted attention. The ReRAM records information according to the state of a resistance value of a cell that changes by application of a voltage. In particular, a Xp-ReRAM (cross-point ReRAM) has a cell structure in which a variable resistor element (VR: Variable Resistor) functioning as a storage element and a selector element (SE: Selector Element) having bidirectional diode characteristics are coupled in series at an intersection of a word line and a bit line.

A semiconductor storage device including such a memory is known to cause various failures and errors during its operation. In the semiconductor storage device, in order to ensure reliability of the operation, it is extremely important to handle such failures and errors. PTL 1 discloses a semiconductor storage device that is able to prevent a write error, a read error, and the like by reducing a leak current in a defective memory cell even if a short circuit failure has occurred in the memory cell.

It has been confirmed that in the Xp-ReRAM, a random error (a soft error) and a hard failure (a hard error) occur. The random error is a transient error in which a failure in writing of data or reading of wrong data occurs with a constant probability due to manufacturing variations, variations in an environment such as voltage and temperature, or an influence of noise, cosmic rays, or the like. Accordingly, performing rewriting of data to respond to a failure in writing of data and performing rereading of data to respond to an error in reading of data makes it possible to eliminate the error.

Meanwhile, the hard failure is an error in which a state of a memory cell is stuck or fixed at 1 (a high level state) or 0 (a low level state) or the state of the memory cell becomes unstable due to deterioration over time, a wearout failure, or a stochastic failure, resulting in a failure in writing of data or an error in reading of data. Unlike the random error, the hard failure is a permanent failure from which recovery is not possible even if access is made again or restart is executed.

### CITATION LIST

### Patent Literature

PTL 1: Japanese Unexamined Patent Application Publication No. 2010-20811

### SUMMARY OF THE INVENTION

### Problem to be Solved by the Invention

Hard failures in a Xp-ReRAM include a disturb failure resulting from a decrease in threshold voltage of a selector element. The disturb failure has a possibility that a malfunction occurs in reading and writing of data from and to memory cells provided on the same word line or the same bit line as a memory cell in which the disturb failure has occurred. However, there is an issue that even if data is written to a memory cell or data is read from the memory cell, it is difficult to determine whether or not a disturb failure has occurred in the memory cell.

An object of the present disclosure is to provide a memory chip and a method of controlling a memory chip that make it possible to detect a disturb failure.

### Means for Solving the Problem

A memory chip according to an embodiment of the present disclosure includes: a memory cell including a variable resistor element and a switching element, the variable resistor element reversibly changeable between a low resistive state and a high resistive state, and the switching element having nonlinear current-voltage characteristics and being coupled in series to the variable resistor element; a voltage generator that generates a first voltage to be applied to the memory cell in a case where the variable resistor element is changed to the low resistive state, a second voltage to be applied to the memory cell in a case where a resistive state of the variable resistor element is detected, and a specific voltage that is equal to or higher than a half of the first voltage and lower than the second voltage; and a control unit that controls the memory cell.

In addition, a method of controlling a memory chip according to an embodiment of the present disclosure including: in a case where a write command including information that gives an instruction to write data to a memory cell, and write data to be written to the memory cell are inputted from outside, the memory cell including a variable resistor element and a switching element, the variable resistor element reversibly changeable between a low resistive state and a high resistive state, and the switching element having nonlinear current-voltage characteristics and being coupled in series to the variable resistor element, executing a first voltage application process, a specific voltage application process, and a third voltage application process by a control unit that controls the memory cell, the first voltage application process in which a first voltage to be applied to the memory cell in a case where the variable resistor element is changed to the low resistive state is applied to the memory cell, the specific voltage application process in which after the first volage is applied, a specific voltage is applied to the memory cell, the specific voltage being equal to or higher than a half of the first voltage and lower than a second voltage to be applied to the memory cell in a case where a resistive state of the variable resistor element is detected, and a third voltage application process in which after the specific voltage is applied, a third voltage to be applied to the memory cell in a case where the variable resistor element is changed to the high resistive state is applied to the memory cell.

### BRIEF DESCRIPTION OF THE DRAWINGS

FIG. 1 is a block diagram illustrating an example of a schematic configuration of a memory system according to an embodiment of the present disclosure.

FIG. 2 is a diagram illustrating an example of a hardware configuration of a semiconductor storage device according to the embodiment of the present disclosure.

FIG. 3 is a diagram illustrating an example of a schematic configuration of a memory chip according to the embodiment of the present disclosure.

FIG. 4 is a block diagram illustrating an example of a schematic structure of a memory bank included in the memory chip according to the embodiment of the present disclosure.

FIG. 5 is a diagram illustrating an example of a schematic configuration of a memory tile included in the memory chip according to the embodiment of the present disclosure.

FIG. 6 is a block diagram illustrating an example of a schematic configuration of a peripheral unit provided in the memory chip according to the embodiment of the present disclosure.

FIG. 7 is a block diagram illustrating an example of a schematic configuration of a voltage generator provided in the peripheral unit of the memory chip according to the embodiment of the present disclosure.

FIG. 8 is a diagram illustrating an example of a circuit configuration of a portion (a positive-side write voltage regulator) of a positive-side voltage generator provided in a voltage generator of the memory chip according to the embodiment of the present disclosure.

FIG. 9 is a diagram illustrating an example of a circuit configuration of a portion (a positive-side read voltage regulator) of the positive-side voltage generator provided in the voltage generator of the memory chip according to the embodiment of the present disclosure.

FIG. 10 is a diagram illustrating an example of a circuit configuration of a portion (a negative-side write voltage regulator) of a negative-side voltage generator provided in the voltage generator of the memory chip according to the embodiment of the present disclosure.

FIG. 11 is a diagram illustrating an example of a circuit configuration of a portion (a positive-side read voltage regulator) of the negative-side voltage generator provided in the voltage generator of the memory chip according to the embodiment of the present disclosure.

FIG. 12 is a block diagram illustrating an example of a schematic configuration of a cell array circuit provided in the memory tile of the memory chip according to the embodiment of the present disclosure.

FIG. 13 is a diagram for describing reading and writing of data from and to a memory cell included in the memory chip according to the embodiment of the present disclosure.

FIG. 14 is a diagram illustrating an example of voltage-current characteristics of the memory cell included in the memory chip according to the embodiment of the present disclosure.

FIG. 15 is a diagram for describing reading of data from a lower memory cell included in the memory chip according to the embodiment of the present disclosure.

FIG. 16 is a diagram for describing reading of data from an upper memory cell included in the memory chip according to the embodiment of the present disclosure.

FIG. 17 is a diagram for describing writing (a set operation) of data to the lower memory cell included in the memory chip according to the embodiment of the present disclosure.

FIG. 18 is a diagram for describing writing (a reset operation) of data to the lower memory cell included in the memory chip according to the embodiment of the present disclosure.

FIG. 19 is a diagram for describing writing (the set operation) of data to the upper memory cell included in the memory chip according to the embodiment of the present disclosure.

FIG. 20 is a diagram for describing writing (the reset operation) of data to the upper memory cell included in the memory chip according to the embodiment of the present disclosure.

FIG. 21 is a diagram for describing a normal write operation process on the memory cell included in the memory chip according to the embodiment of the present disclosure.

FIG. 22 is a diagram for describing a write operation process with disturb failure detection for the memory cell included in the memory chip according to the embodiment of the present disclosure.

FIG. 23 is a diagram illustrating an example of a flowchart of the normal write operation process on the memory cell included in the memory chip according to the embodiment of the present disclosure.

FIG. 24 is a diagram illustrating an example of a flowchart of a preread process in the normal write operation process on the memory cell included in the memory chip according to the embodiment of the present disclosure.

FIG. 25 is a diagram illustrating an example of a flowchart of a set operation process in the normal write operation process on the memory cell included in the memory chip according to the embodiment of the present disclosure.

FIG. 26 is a diagram illustrating an example of a flowchart of a reset operation process in the normal write operation process on the memory cell included in the memory chip according to the embodiment of the present disclosure.

FIG. 27 is a diagram illustrating an example of a flowchart of a verifying operation process in the normal write operation process on the memory cell included in the memory chip according to the embodiment of the present disclosure.

FIG. 28 is a diagram illustrating an example of a flowchart of the write operation process with disturb failure detection for the memory cell included in the memory chip according to the embodiment of the present disclosure.

FIG. 29 is a diagram illustrating an example of a flowchart of a disturb failure detection operation process in the write operation process with disturb failure detection for the memory cell included in the memory chip according to the embodiment of the present disclosure.

### MODES FOR CARRYING OUT THE INVENTION

Hereinafter, modes for carrying out the present disclosure (embodiments) are described with reference to the drawings. The following description is directed to a specific example of the present disclosure, and the present disclosure is not limited to the following embodiments.

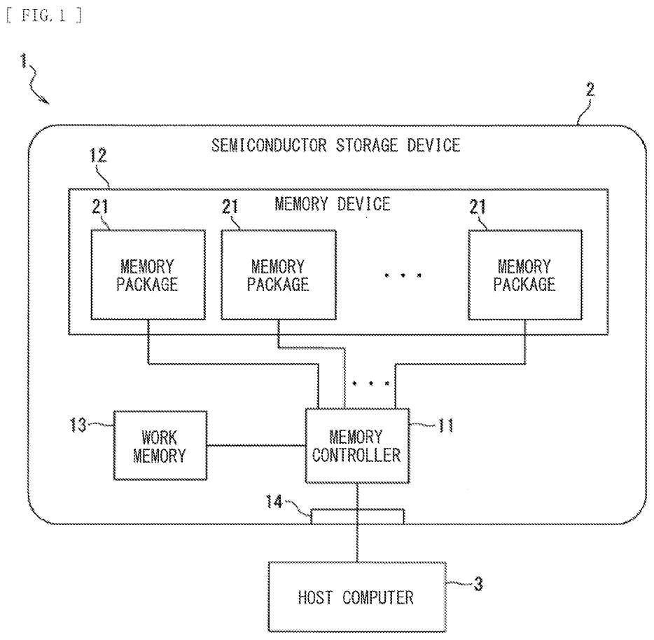

Description is given of a memory chip and a method of controlling a memory chip according to an embodiment of the present disclosure with reference to FIGS. 1 to 30. First, description is given of schematic configurations of the memory chip according to the embodiment, a semiconductor storage device including the memory chip, and a memory system including the semiconductor storage device with reference to FIGS. 1 to 12.

As illustrated in FIG. 1, an information processing system 1 including the memory chip (not illustrated in FIG. 1) according to the present embodiment includes a semiconductor storage device 2 and a host computer 3. The host computer 3 is configured to direct or execute each process in the information processing system 1. The host computer 3 is coupled to a memory interface 13 provided in the semiconductor storage device 2.

The semiconductor storage device 2 includes a memory controller 11 coupled to the host computer 3 through the memory interface 14, a memory device 12 that includes a plurality of (e.g., ten in the present embodiment) memory packages 21 coupled to the memory controller 11, and, for example, one work memory 13 coupled to the memory controller 11.

The memory controller 11 is a component that totally controls an operation of the semiconductor storage device 2. The memory controller 11 includes, for example, a DDR4 (Double-Data-Rate4)-based custom interface (hereinafter abbreviated to a “DDR4 custom IF”) and a DDR4 DRAM (Dynamic Random Access Memory) interface (hereinafter abbreviated to a “DDR4 DRAM IF”). The memory controller 11 is coupled to the plurality of memory packages 21 by the DDR4 custom IF. Accordingly, the memory controller 11 includes, for example, a 20-channel DDR4 custom IF. The memory controller 11 is coupled to the work memory 13 by the DDR4 DRAM IF. Accordingly, the memory controller 11 includes, for example, one-channel DDR4 DRAM IF.

Each of the memory packages 21 provided in the memory device 12 includes a plurality of (e.g., eight) memory chips (not illustrated in FIG. 1). The memory chip is also referred to as a “memory die”. For example, the eight memory chips are stacked (stacked) inside the memory package 21. The eight memory chips are displaced and stacked to prevent the memory chips disposed adjacent to each other from covering input/output units. The memory package 21 includes two systems of interface channels. Of the eight memory chips provided inside the memory package 21, four memory chips are coupled to one of the two systems of interface channels, and the other four memory chips are coupled to the other of the two systems of interface channels.

The memory chips each have a storage capacity of 8 gigabytes (GBytes (hereinafter abbreviated to “GB”). Accordingly, each of the memory packages 21 has a storage capacity of 64 GB (=8 GB×8). The memory device 12 includes, for example, ten memory packages 21, and therefore has a storage capacity of 640 GB (=64 GB×10). The memory device 12 is configured to store data in, for example, eight memory packages 21 of the ten memory packages 21 and store information about a defective memory cell and the like in the other two memory packages 21. Accordingly, the memory device 12 has an effective data storage capacity of 512 GB (=64 GB×8). A specific configuration of the memory chip is described later.

A work memory WN includes, for example, a DRAM. The work memory 13 stores management information such as a logical-physical translation table as an address translation table. The work memory 13 is used to refer to the stored management information at high speed. The logical-physical translation table (hereinafter referred to as “logical-physical translation table”) stored in the work memory 13 is a table that holds mapping information for translating a logical space address indicated by an access command received from the host computer 3 into a physical space address on the memory chip. The logical-physical translation table is updated and managed under control by the memory controller 11.

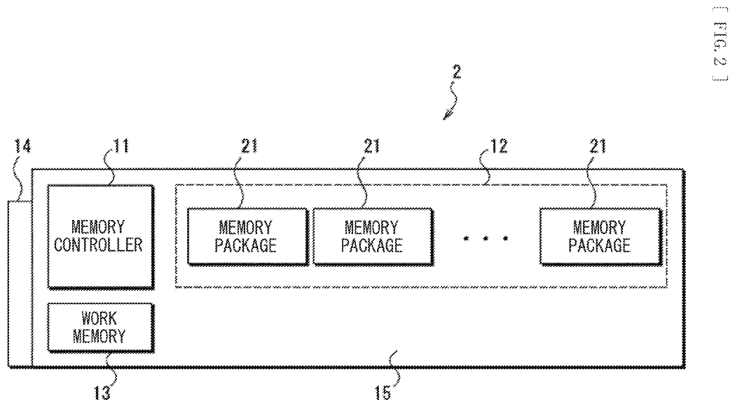

As illustrated in FIG. 2, the semiconductor storage device 2 includes, for example, a printed circuit board 15 having a thin rectangular shape. The memory controller 11, the plurality of memory packages 21, and the work memory WN are mounted on the printed circuit board 15. A half (e.g., five) of the plurality of memory packages 21 is mounted on one surface of the printed circuit board 15, and the other half of the plurality of memory packages 21 is mounted on another surface of the printed circuit board 15. It is to be noted that the one surface is, for example, a surface where the memory controller 11 and the work memory WN are mounted. The other surface is, for example, a surface on back side of the surface where the memory controller 11 and the work memory WN are mounted. The memory interface 14 is provided to protrude from the printed circuit board 15 on one short side of the printed circuit board 15.

The semiconductor storage device 2 is able to achieve the following five performances with use of a memory cell (to be described in detail later) having a three-dimensional cross point (3DXP) configuration. A first performance is a storage capacity of 512 GB per semiconductor storage device, which is difficult for a DRAM to achieve. A second performance is nonvolatility that is not achievable for the DRAM. The semiconductor storage device 2 is able to hold, for example, data without power supply for three months. A third performance is a transfer speed comparable to the DRAM. The semiconductor storage device 2 is able to achieve, for 32 GB/sec for reading of data and 12.8 GB/sec for writing of data. A fourth performance is low latency comparable to the DRAM. The semiconductor storage device 2 is able to achieve, for example, a reading time shorter than 300 nsec. A fifth performance is reliability sufficient to endure unlimited writing for five years. The semiconductor storage device 2 enables writing of 2 EB (=2×1018 bytes) in total, for example, by continuously performing writing at a maximum transfer speed for five years.

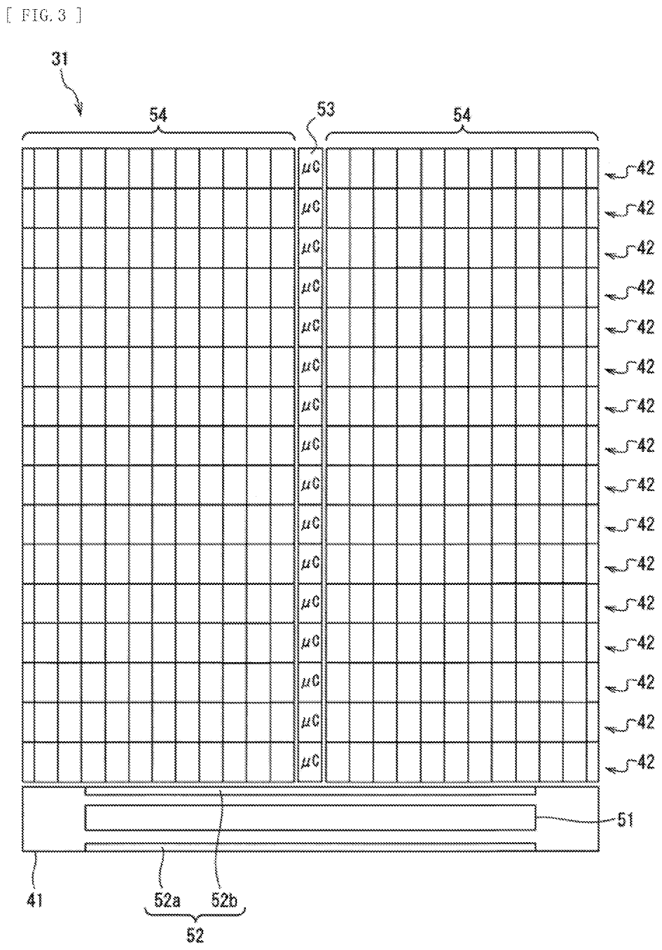

As illustrated in FIG. 3, the memory chip 31 according to the present embodiment has a thin rectangular parallelepiped shape. The memory chip 31 includes a peripheral unit 41 including a peripheral interface unit 52 and a peripheral circuit 51. In the peripheral interface unit 52, write data and a bit address (to be described in detail later) to be written to a memory cell (not illustrated in FIG. 3) are inputted, and read data read out from the memory cell is outputted. The peripheral circuit 51 includes a voltage generator (not illustrated in FIG. 3). The peripheral unit 41 is disposed on one short side of the memory chip 31. In addition, the memory chip 31 includes a plurality of (sixteen in the present embodiment) memory banks 42 that are provided in parallel to the peripheral unit 41.

As described in detail later, the peripheral unit 41 is a component that generates an internal voltage source, a current source, a clock, and the like that are to be supplied to each of the plurality of memory banks 42. The peripheral unit 41 is configured to be able to make access (reading and writing of data) to each of the plurality of memory banks 42 through the peripheral interface unit 52. The peripheral unit 41 is configured to make access to each of the plurality of memory banks 42 in access units of 32 bytes. Each of the plurality of memory banks 42 is configured to be able to store data of 4 gigabits.

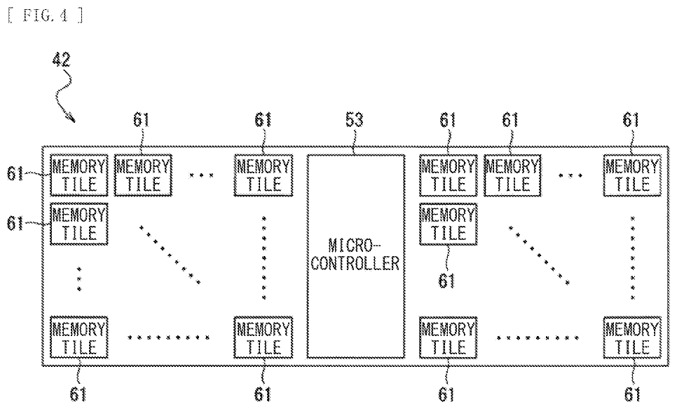

The plurality of memory banks 42 has mutually the same configuration. The memory banks 42 provided in the memory chip 31 each include a microcontroller (one example of a control unit) 53 that controls the memory cells (not illustrated in FIG. 3). In FIG. 3, the microcontroller is represented by “μC”. The microcontroller 53 is provided in a middle in the memory bank 42. The memory bank 42 includes memory cell arrangement regions 54 including a plurality of memory chips controlled by the microcontroller 53. The memory cell arrangement regions 54 are disposed on both sides of the microcontroller 53. Next, description is given of a specific configuration of the memory bank 42 with reference to FIGS. 4 to 8 while referring to FIG. 3.

### (Memory Bank)

As illustrated in FIG. 4, the memory cell arrangement regions 54 provided in the memory bank 42 each include a plurality of (256 in the present embodiment) memory tiles 61. It is to be noted that, for each of understanding, FIG. 4 illustrates twelve memory tiles 61 of the plurality of memory tiles 61 provided in the memory cell arrangement region 54. As described in detail later, the plurality of memory tiles 61 includes mutually the same plurality of memory cells. Each of the plurality of memory tiles 61 is a storage element having a storage capacity of 16 megabits and an access unit of 1 bit. The microcontroller 53 is a circuit that controls operations of all the memory tiles 61 provided in the memory bank 42 including that microcontroller 53 in accordance with a predetermined procedure. The memory bank 42 achieves an access unit of the same number as the number (256 bits, that is, 32 bytes in the present embodiment) of memory tiles 61 by cooperatively operating all the memory tiles 61 provided in that memory bank 42.

### (Memory Tile)

As illustrated in FIG. 5, the memory tile 61 provided in the memory chip 31 includes a plurality of bit lines (one example of first lines) BL0, BL1, BL2, and BL3 provided in parallel with each other. The memory tile 61 also includes a plurality of upper word lines (one example of second lines) UWL0, UWL1, UWL2, and UWL3 and a plurality of lower word lines (one example of second lines) LWL0, LWL1, LWL2, and LWL3 that are provided in parallel with each other and are disposed to intersect with the plurality of bit lines BL0, BL1, BL2, and BL3 provided in parallel with each other. Some (e.g., the upper word lines UWL0, UWL1, UWL2, and UWL3) of a plurality of word lines are disposed to be opposed to remaining ones (e.g., the lower word line LWL0, LWL1, LWL2, LWL3) of the plurality of word lines with the plurality of bit line BL0, BL1, BL2, and BL3 interposed therebetween. For ease of understanding, FIG. 5 illustrates four bit lines BL0 to BL3, four upper word lines UWL0 to UWL3, and four lower word lines LWL0 to LWL3. However, the memory tile 61 includes, for example, 4096 upper word lines UWLi (i is a natural number of 0 and 1 to 4095), 4096 lower word lines LWLj (j is a natural number of 0 and 1 to 4095), and 2048 bit lines BLk (k is a natural number of 0 and 1 to 2047).

The memory tile 61 includes memory cells MC each including a variable resistor element VR that are reversibly changeable between a low resistive state and a high resistive state, and a selector element (one example of a switching element) SE that has nonlinear current-voltage characteristics and is coupled in series to the variable resistor element VR. The memory cells MC are disposed at respective intersections of the plurality of upper word lines UWL0 to UWL3 and lower word lines LWL0 to LWL3 with the plurality of bit lines BL.

More specifically, some of a plurality of memory cells MC included in the memory tile 61 are disposed at intersections of intersections of the plurality of upper word lines UWL0 to UWL3 and the plurality of bit lines BL0 to BL3. In addition, the remaining memory cells MC of the plurality of memory cells MC included in the memory tile 61 are disposed at intersections of intersections of the plurality of lower word line LWL0 to LWL3 and the plurality of bit lines BL0 to BL3. In the memory cells MC disposed at the respective intersections of the plurality of upper word lines UWL0 to UWL3 and the plurality of bit lines BL0 to BL3 (hereinafter referred to as “upper memory cells UMC”), the variable resistor elements VR are disposed on side of the plurality of upper word lines UWL0 to UWL3, and the selector elements SE are disposed on side of the plurality of bit lines BL. In the memory cells MC disposed at the respective intersections of the plurality of lower word lines LWL0 to LWL3 and the plurality of bit lines BL0 to BL3 (hereinafter referred to as “lower memory cells LMC”), the variable resistor elements VR are disposed on side of the plurality of bit lines BL0 to BL3, and the selector elements SE are disposed on side of the plurality of lower word lines LWL0 to LWL3. Hereinafter, for description of the memory cells, the memory cells are collectively referred to as “memory cells MC” in a case where no discrimination is made between the “upper memory cells UMC” and the “lower memory cells LMC”.

The variable resistor element VR is configured to store information of 1 bit by magnitude of a resistance value. The selector element SE has, for example, bidirectional diode characteristics as nonlinear characteristics. Accordingly, the selector element SE is brought into conduction in a case where a selection voltage is applied to the memory cell MC, and is brought out of conduction in a case where a voltage lower than the selection voltage is applied to the memory cell MC. The variable resistor element VR and the selector element SE have a series structure. In the memory cell MC, even if the selector element SE is in a conduction state, magnitude of a current flowing through the memory cell MC and magnitude of an inter-terminal voltage of the memory cell MC differ depending on the resistance value of the variable resistor element VR. Accordingly, detecting the magnitude of the current or the magnitude of the inter-terminal voltage in the memory cell MC makes it possible to detect information of 1 bit stored in the memory cell MC.

A ReRAM material including a copper ion is used for the variable resistor element VR. An OTS (Ovonic Threshold Switch) material with boron and carbon is used for the selector element SE.

The memory tile 61 includes 16777216 (=4096×2048×2) memory cells MC that each are able to store information of 1 bit, and therefore has a storage capacity of 16 megabits.

A memory cell array 611 provided in the memory tile 61 is configured by the plurality of memory cells MC, the plurality of upper word lines UWL0 to UWL3, the plurality of lower word lines LWL0 to LWL3, and the plurality of bit lines BL0 to BL3.

As illustrated in FIG. 5, the memory tile 61 provided in the memory chip 31 includes a tile circuit (one example of a cell array circuit) 612 that executes a data write process or a data read process on the memory cell MC selected from among the plurality of memory cells MC. The tile circuit 612 is provided below the memory cell array 611. The tile circuit 612 is disposed on side of the plurality of lower word lines LWL0 to LWL3.

The tile circuit 612 includes an even number-side word line decoder 621 coupled to even-numbered upper word lines UWL0 and UWL2 and even-numbered lower word lines LWL0 and LWL2. The tile circuit 612 includes an odd number-side word line decoder 622 coupled to odd-numbered upper word lines UWL1 and UWL3 and odd-numbered lower word lines LWL1 and LWL3. The even number-side word line decoder 621 is disposed below one-end sections of the plurality of upper word lines UWL0 to UWL3 and the plurality of lower word lines LWL0 to LWL3. The odd number-side word line decoder 622 is disposed below other-end sections of the plurality of upper word lines UWL0 to UWL3 and the plurality of lower word lines LWL0 to LWL3. The even number-side word line decoder 621 and the odd number-side word line decoder 622 are formed to be opposed to each other on a semiconductor substrate. The even number-side word line decoder 621 and the odd number-side word line decoder 622 are described in detail later.

The tile circuit 612 includes an even number-side bit line decoder 623 coupled to even-numbered bit lines BL0 and BL2 and an odd number-side bit line decoder 624 coupled to odd-numbered bit lines BL1 and BL3. The even number-side bit line decoder 623 is disposed below one-end sections of the plurality of bit lines BL0 to BL3. The odd number-side bit line decoder 624 is disposed below other-end sections of the plurality of bit lines BL0 to BL3. The even number-side bit line decoder 623 and the odd number-side bit line decoder 624 are formed to be opposed to each other on the semiconductor substrate. The even number-side bit line decoder 623 and the odd number-side bit line decoder 624 are described in detail later.

The tile circuit 612 includes a voltage switching unit 625, a data latch unit 626, and a data detector 627 formed on the semiconductor substrate in a region surrounded by the even number-side word line decoder 621, the odd number-side word line decoder 622, the even number-side bit line decoder 623, and the odd number-side bit line decoder 624. The voltage switching unit 625, the data latch unit 626, and the data detector 627 are described in detail later.

The memory chip 31 includes a plurality of memory cells MC in a two-story configuration. In addition, the memory chip 31 has a configuration in which the tile circuit 612 is disposed in a region below the plurality of memory cells MC and the plurality of memory cells MC and the tile circuit 612 are stacked. Accordingly, the memory chip 31 is achievable at cost equal to or less than ¼ of cost of a DRAM that has the same storage capacity and is formed with the same minimum feature size.

As described above, each of the plurality of memory banks 42 included in the memory chip 31 includes a plurality of memory banks that each include the plurality of upper word lines ULWi, the plurality of lower word lines LWLj, the plurality of bit lines BLk, the plurality of memory cells MC, the tile circuit 612 that executes a data write process or a data read process on the memory cell selected from among the plurality of memory cells MC, and the microcontroller 53.

### (Peripheral Unit)

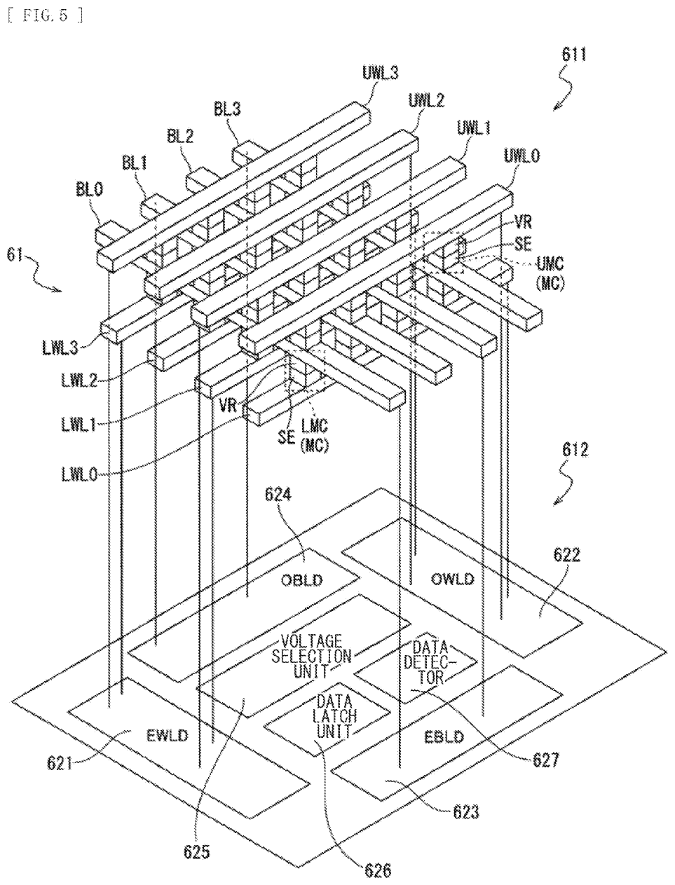

As illustrated in FIG. 6, the peripheral unit 41 included in the memory chip 31 includes the peripheral circuit 51 and the peripheral interface unit 52. The peripheral interface unit 52 is disposed on each of both ends on long side of the peripheral unit 41. The peripheral interface unit 52 includes a controller-side interface unit 52a (hereinafter the “controller-side interface unit” abbreviated to “controller-side IF unit”) coupled to the memory controller 11 (see FIG. 1). In addition, the peripheral interface unit 52 includes a bank-side interface unit 52b (hereinafter, the “bank-side interface unit” is abbreviated to “bank-side IF unit”) coupled to each of the plurality of memory banks 42 (see FIG. 3). The peripheral circuit 51 is disposed between the controller-side IF unit 52a and the bank-side IF unit 52b.

The controller-side IF unit 52a includes a signal input/output unit 521 that outputs, to a memory access control unit 511 (to be described in detail later) provided in the peripheral circuit 51, data, a command, and the like to which signals conforming to the DDR4 custom IF are inputted from the memory controller 11, and outputs, to the memory controller 11, data inputted from the memory access control unit 511. In addition, the controller-side IF unit 52a includes a power input unit 522 that outputs, to a voltage generator 516 (to be described in detail later) provided in the peripheral circuit 51, a predetermined power supply voltage inputted from the memory controller 11. For example, a command CMD such as a write command to direct writing of data and a read command to direct reading of data, and information such as a bank address BA of the memory bank 42 to be activated among the plurality of memory banks 42 or a physical address PA of the memory cell MC as a data write or data read target are inputted to the signal input/output unit 521. In addition, for example, write data and read data are inputted to and outputted from the signal input/output unit 521. Furthermore, for example, a logic voltage DVDD+ (e.g., 1.2 V) that is a power supply of the memory access control unit 511 (to be described in detail later) and the like is inputted to the signal input/output unit 521.

For example, analog voltages AVDD+ of +3.3 V and +6.0 V and an analog voltage AVDD− of −4.3 V are inputted as predetermined power supplies to the power input unit 522. As described in detail later, a voltage for controlling the memory cell MC such as a write voltage and a read voltage is generated from the analog voltage AVDD+.

The bank-side IF unit 52b includes a signal input/output unit 523 that outputs, to the memory bank 42, a signal inputted from the memory access control unit 511 provided in the peripheral circuit 51, and outputs, to the memory access control unit 511, a signal and read data inputted from the memory bank 42. In addition, the bank-side IF unit 52b includes an analog voltage output unit 524 that outputs, to the tile circuit 612 (see FIG. 5) provided in the memory bank 42, various types of voltages inputted from the voltage generator 516 provided in the peripheral circuit 51. Furthermore, the bank-side IF unit 52b includes a current output unit 525 that outputs, to the tile circuit 612, a constant current inputted from a current source 517 provided in the peripheral circuit 51.

The peripheral circuit 51 includes the memory access control unit 511 that controls the plurality of memory banks 42. The memory access control unit 511 is coupled to the signal input/output unit 521. Accordingly, the command CMD, the physical address PA, the bank address BA, write data, the logic voltages DVDD+, and the like are inputted to the memory access control unit 511 through the signal input/output unit 521. The memory access control unit 511 activates one of the plurality of memory banks 42 on the basis of the bank address BA inputted from outside. The memory access control unit 511 outputs, to the voltage generator 516, selection signals t_w+<6:0>, t_r+<5:0>, t_d+<5:0>, t_w−<6:0>, t_r−<5:0>, and t_d−<5:0> for selecting voltage levels of various types of voltages to be outputted from the voltage generator 516.

The peripheral circuit 51 includes a write data register 512, a read data register 513, and a mode register (one example of a storage unit) 514 that are coupled to the memory access control unit 511. The write data register 512 is a component that is controlled by the memory access control unit 511 to temporarily store write data inputted through the signal input/output unit 521. The read data register 513 is a component that is controlled by the memory access control unit 511 to temporarily store read data read from the memory bank 42. The mode register 514 is a component that is controlled by the memory access control unit 511 to store information inputted from the microcontroller 53.

Various types of information in a signal format conforming to the DDR4 custom IF are inputted from the memory controller 11 to the memory access control unit 511. The memory access control unit 511 is configured to analyze a signal inputted from the memory controller 11 and extract a command (e.g., a write command and a readout command) for controlling the memory bank 42. In addition, the memory access control unit 511 is configured to output an extracted command CMD to the microcontroller 53 provided in the memory bank 42 as an activation target through the signal input/output unit 523.

In addition, the memory access control unit 511 is configured to output write data WDATA, which is included in a signal inputted from the memory controller 11, to the microcontroller 53 provided in the memory bank 42 as the activation target through the signal input/output unit 523. In addition, the memory access control unit 511 is configured to generate a clock signal CLK and output the generated clock signal CLK to the microcontroller 53 provided in the memory bank 42 as the activation target through the signal input/output unit 523. In addition, the memory access control unit 511 is configured to output a control signal Ctrl including control information to the microcontroller 53 provided in the memory bank 42 as the activation target through the signal input/output unit 523. In addition, the memory access control unit 511 is configured to receive memory cell information (to be described in detail later) inputted from the microcontroller 53 through the signal input/output unit 523 and store the information in the mode register 514.

The peripheral circuit 51 includes a direct-current/direct-current (DC/DC) converter 515 coupled to the power input unit 522 and the voltage generator 516 coupled to the DC/DC converter 515. The DC/DC converter 515 is a component that generates a power supply voltage for various types of voltages to be applied to the memory cells MC during writing of data with use of the analog voltage AVDD+ inputted from the power input unit 522.

More specifically, the DC/DC converter 515 generates, with use of the analog power supply AVDD+ of +6.0 V inputted through the power input unit 522, a reference power supply V40+ for generating a positive electrode-side write voltage to be applied to the memory cell MC in a data write operation (to be described in detail later) and an output power supply Vp43+ of an output unit that outputs the write voltage. In addition, the DC/DC converter 515 generates, with use of the analog power supply AVDD− of −4.3 V inputted through the power input unit 522, a reference power supply V40− for generating a negative electrode-side write voltage to be applied to the memory cell MC in the data write operation and an output power supply Vp43− of an output unit that outputs the write voltage.

In addition, the DC/DC converter 515 generates, with use of the analog power supply AVDD+ of +3.3 V inputted through the power input unit 522, a reference power supply V30+ for generating a positive electrode-side write voltage or a positive electrode-side disturb detection voltage to be applied to the memory cell MC in a data read operation (to be described in detail later) or a disturb failure detection operation (to be described in detail later), and an output power supply Vp33+ of an output unit that outputs the write voltage or the disturb detection voltage. Furthermore, the DC/DC converter 515 generates, with use of the analog power supply AVDD− of −4.3 V inputted through the power input unit 522, a reference power supply V30− for generating a negative electrode-side write voltage or a negative electrode-side disturb detection voltage to be applied to the memory cell MC in the data read operation or the disturb failure detection operation, and an output power supply Vp33− of an output unit that outputs the write voltage and the disturb detection voltage.

The peripheral circuit 51 includes the voltage generator 516 coupled to the DC/DC converter 515. The voltage generator 516 is configured to generate a reset voltage (one example of a first voltage) Vrst of a write voltage Vw to be applied to the memory cell MC in a case where the variable resistor element VR is changed to the low resistive state, a read voltage (a second voltage) Vr to be applied to the memory cell MC in a case where the resistive state of the variable resistor element VR is detected, and a disturb failure detection voltage (one example of a specific voltage) Vd that is equal to or higher than a half of the reset voltage Vrst and lower than the read voltage Vr. In addition, the voltage generator 516 is configured to generate a set voltage (one example of a third volage) Vset of the write voltage Vw, and a reference voltage Vref to be used in a case where the resistive state of the variable resistor element VR of the memory cell MC is detected. A specific configuration of the voltage generator 516 is described later.

The write voltage Vw is a potential difference between a potential of a positive electrode-side write voltage Vw+ generated by a positive-side voltage generator 531 (not illustrated in FIG. 6, and to be described in detail later) provided in the voltage generator 516 and a potential of a negative electrode-side write voltage Vw− generated by a negative-side voltage generator 532 (not illustrated in FIG. 6, and to be described in detail later) provided in the voltage generator 516. The set voltage Vset is the write voltage Vw in a set operation. The reset voltage Vrst is the write voltage Vw in a reset operation. The read voltage Vr is a potential difference between a potential of a positive electrode-side read voltage Vr+ generated by the positive-side voltage generator 531 and a potential of a negative electrode-side read voltage Vr− generated by the negative-side voltage generator 532. The disturb failure detection voltage Vd is a potential difference between a potential of a positive electrode-side disturb failure detection voltage Vd+ generated by the positive-side voltage generator 531 and a potential of a negative electrode-side disturb failure detection voltage Vd− generated by the negative-side voltage generator 532. The reference voltage Vref is a generic name for an upper reference voltage Vrefu and a lower reference voltage Vrefl generated by a reference voltage generator 533 (not illustrated in FIG. 6, and to be described in detail later) provided in the voltage generator 516. The positive electrode-side write voltage Vw+, the negative electrode-side write voltage Vw−, the positive electrode-side read voltage Vr+, the negative electrode-side read voltage Vr−, the positive electrode-side disturb failure detection voltage Vd+, the negative electrode-side disturb failure detection voltage Vd−, the upper reference voltage Vrefu, and the lower reference voltage Vrefl are described in detail later.

The peripheral circuit 51 includes the current source 517 that generates a current to be supplied to the memory cell MC in a case where data is written to the memory cell MC. The current source 517 is configured to generate a set current Iset to be supplied to the memory cell MC as a data write target in the set operation and a reset current Irst to be supplied to the memory cell MC as the data write target in the reset operation. The current source 517 is configured to also supply the set current Iset to the memory cell MC in the data read operation.

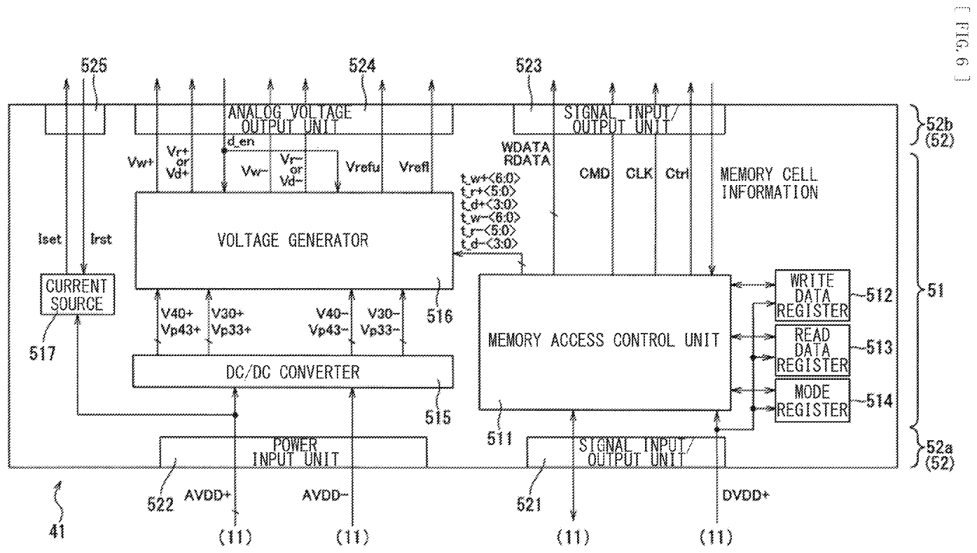

Here, description is given of a specific configuration of the voltage generator 516 with reference to FIGS. 7 to 11.

As illustrated in FIG. 7, the voltage generator 516 includes the positive-side voltage generator 531 that generates a positive-side voltage to be applied to the memory cell MC, the negative-side voltage generator 532 that generates a negative-side voltage to be applied to the memory cell MC, and the reference voltage generator 533 that generates a reference voltage to be used upon reading of data.

The positive-side voltage generator 531 is configured to generate a positive electrode-side write voltage (hereinafter also referred to as a “positive-side write voltage) Vw+ to be applied to the memory cell MC in the data write operation on the basis of the reference power supply V40+ and an output power supply V43+ inputted from the DC/DC converter 515 (see FIG. 6) and the selection signal t_w+<6:0> inputted from the memory access control unit 511 (see FIG. 6). The positive-side voltage generator 531 is configured to output the generated positive-side write voltage Vw+ to the analog voltage output unit 524 (see FIG. 6).

In addition, the positive-side voltage generator 531 is configured to generate a positive electrode-side read voltage (hereinafter also referred to as a “positive-side read voltage”) Vr+ to be applied to the memory cell MC in the data read operation on the basis of the reference power supply V30+ and an output power supply V33+ inputted from the DC/DC converter 515 and the selection signal t_r+<5:0> inputted from the memory access control unit 511. The positive-side read voltage Vr+ is applied to the memory cell MC even in a preread (preread) operation (to be described in detail later) to be executed before a write operation and a verifying (verify) operation (to be described in detail later) that verifies whether or not desired data has been written.

In addition, the positive-side voltage generator 531 is configured to generate the positive-side read voltage Vr+ to be applied to the memory cell MC in the data read operation on the basis of the reference power supply V30+ inputted from the DC/DC converter 515 and the selection signal t_r+<5:0> inputted from the memory access control unit 511.

In addition, the positive-side voltage generator 531 is configured to generate a positive electrode-side disturb failure detection voltage (hereinafter also referred to as a “positive-side disturb failure detection voltage”) Vd+ to be applied to the memory cell MC upon detection of a disturb failure on the basis of the reference power supply V30+ inputted from the DC/DC converter 515 and the selection signal t_d+<3:0> inputted from the memory access control unit 511.

In addition, the positive-side voltage generator 531 is configured to select one of the generated positive-side read voltage Vr+ and the generated positive-side disturb failure detection voltage Vd+ on the basis of a selection signal d_en inputted from the microcontroller 53 (see FIG. 4) provided in the memory bank 42. Furthermore, the positive-side voltage generator 531 is configured to output a voltage selected from between the positive-side read voltage Vr+ and the positive-side disturb failure detection voltage Vd+, from an output unit 553 (not illustrated in FIG. 7, and to be described in detail later) that operates by the output power supply V33+ inputted from the DC/DC converter 515.

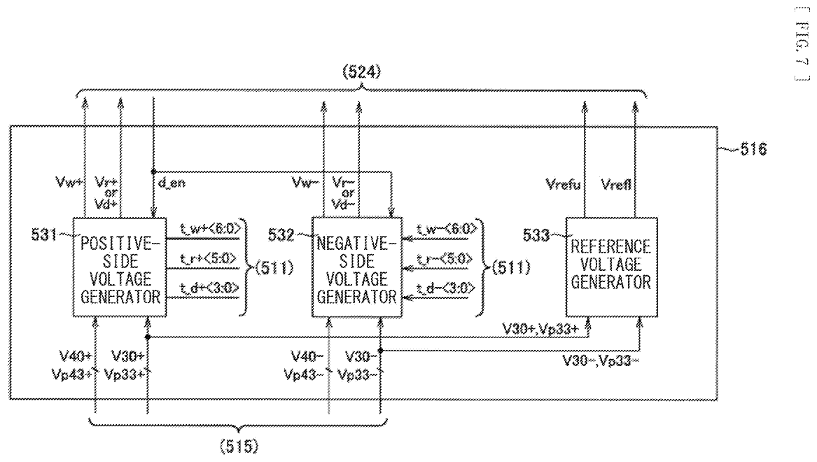

Here, description is given of a specific configuration of the positive-side voltage generator 531 with reference to FIGS. 8 and 9.

As illustrated in FIG. 8, the positive-side voltage generator 531 includes a positive-side write voltage regulator 541 that generates the positive-side write voltage Vw+. The positive-side write voltage regulator 541 includes a digital-analog converter 542 that generates the positive-side write voltage Vw+ and an output unit 543 that outputs the positive-side write voltage Vw+ inputted from the digital-analog converter 542.

The digital-analog converter 542 includes a ladder resistor circuit 542a including a plurality of resistor elements r that is coupled in series, and an analog voltage selection unit 542b that outputs, as the positive-side write voltage Vw+, one voltage of a plurality of voltages inputted from the ladder resistor circuit 542a. The plurality of resistor elements r provided in the ladder resistor circuit 542a is coupled in series between to the reference power supply V40+ (e.g., +4.0 V) inputted from the DC/DC converter 515 and a reference potential (e.g., 0 V). This makes it possible for the ladder resistor circuit 542a to generate a plurality of levels of positive potentials (voltages with reference to the reference potential) obtained by resistively dividing a potential difference between the reference potential and the potential of the reference power supply V40+ by the plurality of resistor elements r.

Some of the plurality of voltages generated by the ladder resistor circuit 542a are inputted to the analog voltage selection unit 542b. A plurality of voltages to be inputted to the analog voltage selection unit 542b includes a positive-side write voltage to be applied to the memory cell MC in a data write operation of each of the set operation and the reset operation. For example, the memory chip 31 according to the present embodiment is designed to apply a voltage of +3.5 V as the positive-side write voltage Vw+ to the memory cell MC in the set operation and apply a voltage of +3.0 V to the memory cell MC in the reset operation. Accordingly, for example, a total of 128 levels of voltages from +2.52 V to +3.80 V at intervals of 0.01 V are inputted to the analog voltage selection unit 542b to include voltages of +3.0 V and +3.5 V.

The selection signal t_w+<6:0> is inputted from the memory access control unit 511 to the analog voltage selection unit 542b. In the memory chip 31, an error between chips in a threshold voltage of the selector element SE and the like occurs, for example, due to manufacturing variations and the like. Due to this error between chips, a value of an optimum write voltage to be applied to the memory cell MC in the data write operation may differ for each memory chip 31. Accordingly, in the memory chip 31 according to the present embodiment, information about the optimum write voltage is stored by the value of the selection signal t_w+<6:0> in a predetermined storage region of the memory access control unit 511. The memory access control unit 511 outputs, to the analog voltage selection unit 542b, the selection signal t_w+<6:0> having a value read out from this storage region in a case where the set operation or the reset operation of the memory cell MC is executed. The analog voltage selection unit 542b selects one voltage from among a plurality of voltages inputted from the ladder resistor circuit 542a on the basis of the value of the inputted selection signal t_w+<6:0>, and outputs the selected voltage as the positive-side write voltage Vw+ to the output unit 543. Thus, the analog voltage selection unit 542b exerts a function as a multiplexer circuit that switches an analog signal.

As illustrated in FIG. 8, the output unit 543 includes an amplifier 543a coupled to the analog voltage selection unit 542b, a PMOS transistor 543b coupled to the amplifier 543a, and a capacitor 543c coupled to the PMOS transistor 543b. The output unit 543 exerts a function as an amplifier unit by the amplifier 543a, the PMOS transistor 543b, and the capacitor 543c.

The amplifier 543a includes, for example, an operational amplifier. A non-inverting input terminal (+) of the amplifier 543a is coupled to an output terminal of the analog voltage selection unit 542b. An output terminal of the amplifier 543a is coupled to a gate terminal G of the PMOS transistor 543b. An inverting input terminal (−) of the amplifier 543a is coupled to a coupling section between a drain terminal D of the PMOS transistor 543b and one electrode of the capacitor 543c. The coupling section between the drain terminal D of the PMOS transistor 543b and the one electrode of the capacitor 543c serves as an output terminal of the output unit 543.

A source terminal S of the PMOS transistor 543b is coupled to an output terminal of the output power supply Vp43 of the DC/DC converter 515. Accordingly, an output power supply VP43 is applied to the source terminal S of the PMOS transistor 543b. Another electrode of the capacitor 543c is coupled to a ground terminal. A potential of the ground terminal is the same as a reference potential to be applied to the ladder resistor circuit 542a. A terminal to which the reference potential is to be applied of the ladder resistor circuit 542a may be coupled to the ground terminal.

The coupling section between the drain terminal D of the PMOS transistor 543b and the one electrode of the capacitor 543c has substantially the same voltage as an output voltage of the amplifier 543a. The output unit 543 functions as a voltage follower circuit as a whole, and is able to output the positive-side write voltage Vw+. In addition, the output unit 543 includes the capacitor 543c, thereby achieving stabilization of the voltage level of the positive-side write voltage Vw+ to be outputted.

As illustrated in FIG. 9, the positive-side voltage generator 531 included in the voltage generator 516 includes a positive-side read voltage regulator 551 that generates the positive-side read voltage Vr+ and the positive-side disturb failure detection voltage Vd+. The positive-side read voltage regulator 551 includes a digital-analog converter 552 that generates the read voltage (one example of a second voltage) Vr and the disturb failure detection voltage (one example of a specific voltage) Vd. The digital-analog converter 552 is configured to generate the positive-side read voltage Vr+ of the read voltage Vr and the positive-side disturb failure detection voltage Vd+ of the disturb failure detection voltage Vd.

The digital-analog converter 552 includes a ladder resistor circuit 552a including a plurality of resistor elements r that is coupled in series. In addition, the digital-analog converter 552 includes an analog voltage selection unit 552b (one example of a first selection unit) that selects the read voltage Vr from among a plurality of analog voltages inputted from the ladder resistor circuit 552a. In addition, the digital-analog converter 552 includes an analog voltage selection unit 552c (one example of a second selection unit) that selects the disturb failure detection voltage Vd from among the plurality of analog voltages inputted from the ladder resistor circuit 552a. The digital-analog converter 552 includes a selection unit 552d (one example of a third selection unit) that selects one of the read voltage Vr and the disturb failure detection voltage Vd.

The positive-side read voltage regulator 551 included in the positive-side voltage generator 531 of the voltage generator 516 includes the output unit 553 that outputs, to the memory cell MC, a voltage inputted from the selection unit 552d.

More specifically, the analog voltage selection unit 552b is a component that outputs, as the positive-side read voltage Vr+ of the read voltage Vr, one positive voltage selected from among a plurality of positive voltages (analog voltages) inputted from the ladder resistor circuit 552a. The analog voltage selection unit 552c is a component that outputs, as the positive-side disturb failure detection voltage Vd+ of the disturb failure detection voltage Vd, one positive voltage selected from among the plurality of positive voltages (analog voltages) inputted from the ladder resistor circuit 552a. The selection unit 552d is a component that selects and outputs one of the positive-side read voltage Vr+ inputted from the analog voltage selection unit 552b and the positive-side disturb failure detection voltage Vd+ inputted from the analog voltage selection unit 552c.

The plurality of resistor elements r provided in the ladder resistor circuit 552a is coupled in series between the reference power supply V30+ (e.g., +3.0 V) inputted from the DC/DC converter 515 and the reference potential (e.g., 0 V). This makes it possible for the ladder resistor circuit 552a to generate a plurality of levels of potentials (voltages with reference to the reference potential) obtained by resistively dividing a potential difference between the reference potential and the potential of the reference power supply V30+ by the plurality of resistor elements r.

Some of a plurality of positive voltages generated by the ladder resistor circuit 552a are inputted to the analog voltage selection unit 552b. A plurality of positive voltage inputted to the analog voltage selection unit 552b includes the positive-side read voltage Vr+ to be applied to the memory cell MC in the data read operation. For example, the memory chip 31 according to the present embodiment is designed to apply a voltage of +2.5 V as the positive-side read voltage Vr+ to the memory cell MC in the read operation. Accordingly, for example, a total of 64 levels of voltages from +2.80 V to +2.17 V at intervals of 0.01 V are inputted to the analog voltage selection unit 552b to include a voltage of +2.5 V.

Another some of the plurality of voltages generated by the ladder resistor circuit 552a are inputted to the analog voltage selection unit 552c. A plurality of voltages inputted to the analog voltage selection unit 552c includes the positive-side disturb failure detection voltage Vd+ to be applied to the memory cell MC in the disturb failure detection operation. The disturb failure detection voltage Vd is set to a voltage equal to or higher than a half of the reset voltage Vrst and lower than the read voltage Vr. Accordingly, the positive-side disturb failure detection voltage Vd+ is set to a voltage equal to or higher than a half of a positive-side reset voltage Vrst+ and lower than the positive-side read voltage Vr+. For example, the memory chip 31 according to the present embodiment is designed to apply a voltage of +1.75 V as the positive-side disturb failure detection voltage Vd+ to the memory cell MC in the disturb failure detecting operation. Accordingly, for example, a total of 64 levels of voltages from +1.68 V to +1.83 V at intervals of 0.01 V are inputted to the analog voltage selection unit 552c to include a voltage of +1.75 V.

The selection signal t_r+<5:0> is inputted from memory access control unit 511 to the analog voltage selection unit 552b to cope with the error between chips described above. In the memory chip 31 according to the present embodiment, information about an optimum read voltage is stored by a value of the selection signal t_r+<5:0> in a predetermined storage region of the memory access control unit 511. In a case where the read operation, the preread operation, and the verifying operation of the memory cell MC are executed, the memory access control unit 511 outputs, to the analog voltage selection unit 552b, the selection signal t_r+<5:0> having a value read out from this storage region. The analog voltage selection unit 552b selects one positive voltage from among the plurality of positive voltages inputted from the ladder resistor circuit 552a on the basis of the value of the inputted selection signal t_r+<5:0>, and outputs the selected positive voltage as the positive-side read voltage Vr+ to the selection unit 552d. The analog voltage selection unit 552b exerts a function as a multiplexer circuit that switches an analog signal.

The selection signal t_d+<3:0> is inputted from the memory access control unit 511 to the analog voltage selection unit 552c to cope with the error between chips. In the memory chip 31 according to the present embodiment, information about an optimum positive-side disturb failure detection voltage Vd+ is stored by a value of the selection signal t_d+<3:0> in a predetermined storage region of the memory access control unit 511. In a case where the disturb failure detecting operation of the memory cell MC is executed, the memory access control unit 511 outputs, to the analog voltage selection unit 552c, the selection signal t_d+<3:0> having a value read out from this storage region. The analog voltage selection unit 552c selects one positive voltage from among the plurality of positive voltages inputted from the ladder resistor circuit 552a on the basis of the value of the inputted selection signal t_d+<3:0>, and outputs the selected positive voltage as the positive-side disturb failure detection voltage Vd+ to the selection unit 552d. Thus, the analog voltage selection unit 552c exerts a function as a multiplexer circuit that switches an analog signal.

The selection signal d_en is inputted from the microcontroller 53 to the selection unit 552d. In a case where the read operation, the preread operation, and the verifying operation are executed for the memory tile 61 as a control target, the microcontroller 53 outputs, for example, the selection signal d_en having a low level to the analog voltage section unit 552d. In contrast, in a case where the disturb failure detecting operation is executed for the memory tile 61 as the control target, the microcontroller 53 outputs, for example, the selection signal d_en having a high level to the analog voltage selection unit 552d. In a case where the selection signal d_en having the low level is inputted, the selection unit 552d selects the positive-side read voltage Vr+ inputted from the analog voltage selection unit 552b, and outputs the positive-side read voltage Vr+ to the output unit 553. In contrast, in a case where the selectin signal d_en having the high level is inputted, the selection unit 552d selects the positive-side disturb failure detection voltage Vd+ inputted from the analog voltage selection unit 552c, and outputs the positive-side disturb failure detection voltage Vd+ to the output unit 553.

As illustrated in FIG. 8, the output unit 553 includes an amplifier 553a coupled to the selection unit 552d, a PMOS transistor 553b coupled to the amplifier 553a, and a capacitor 553c coupled to the PMOS transistor 553b. The output unit 553 exerts a function as an amplifier unit by the amplifier 553a, the PMOS transistor 553b, and the capacitor 553c.

The amplifier 553a includes, for example, an operational amplifier. A non-inverting input terminal (+) of the amplifier 553a is coupled to an output terminal of the selection unit 552d. An output terminal of the amplifier 553a is coupled to a gate terminal G of the PMOS transistor 553b. An inverting input terminal (−) of the amplifier 553a is coupled to a coupling section between a drain terminal D of the PMOS transistor 553b and one electrode of the capacitor 553c. The coupling section between the drain terminal D of the PMOS transistor 553b and the one electrode of the capacitor 553c serves as an output terminal of the output unit 553.

A source terminal S of the PMOS transistor 553b is coupled to an output terminal of an output power supply Vp33+ (e.g., +3.3V) of the DC/DC converter 515. Accordingly, the output power supply VP33+ is applied to the source terminal S of the PMOS transistor 553b. Another electrode of the capacitor 553c is coupled to a ground terminal. A potential of the ground terminal is, for example, the same as a reference potential to be applied to the ladder resistor circuit 552a. A terminal to which the reference potential is to be applied of the ladder resistor circuit 552a may be coupled to the ground terminal.

The coupling section between the drain terminal D of the PMOS transistor 553b and the one electrode of the capacitor 553c has substantially the same voltage as the output voltage of the amplifier 553a. The output unit 553 functions as a voltage follower circuit as a whole. In a case where the positive-side read voltage Vr+ is inputted from the selection unit 552d, the output unit 553 is able to output the positive-side read voltage Vr+. In addition, in a case where the positive-side disturb failure detection voltage Vd+ is inputted from the selection unit 552d, the output unit 553 is able to output the positive-side disturb failure detection voltage Vd+. In addition, the output unit 553 includes the capacitor 553c, thereby achieving stabilization of the voltage level of the positive-side read voltage Vr+ or the positive-side disturb failure detection voltage Vd+ to be outputted.

Referring back to FIG. 7, the negative-side voltage generator 532 provided in the voltage generator 516 is configured to generate a negative electrode-side write voltage (hereinafter also referred to as a “negative-side write voltage”) Vw− to be applied to the memory cell MC in the data write operation on the basis of the reference power supply V40− and the output power supply V43− inputted from the DC/DC converter 515 and the selection signal t_w−<6:0>− inputted from the memory access control unit 511. The negative-side voltage generator 532 is configured to output the generated negative-side write voltage Vw− to the analog voltage output unit 524.

In addition, the negative-side voltage generator 532 is configured to generate a negative electrode-side read voltage (hereinafter, also referred to as a “negative-side read voltage”) Vr− to be applied to the memory cell MC in the data read operation on the basis of the reference power supply V30− and the output power supply V33− inputted from the DC/DC converter 515 and the selection signal t_r−<5:0> inputted from the memory access control unit 511.

In addition, the negative-side voltage generator 532 is configured to generate the negative-side read voltage Vr− to be applied to the memory cell MC in the data read operation on the basis of the reference power supply V30− inputted from the DC/DC converter 515 and the selection signal t_r−<5:0> inputted from the memory access control unit 511. As described in detail later, the negative-side read voltage Vr− is applied to the memory cell MC even in the preread operation and the verifying operation.

In addition, the negative-side voltage generator 532 is configured to generate a positive electrode-side disturb failure detection voltage (hereinafter also referred to as a “negative-side disturb failure detection voltage”) Vd− to be applied to the memory cell MC upon detection of a disturb failure on the basis of the reference power supply V30− inputted from the DC/DC converter 515 and the selection signal t_d+<3:0> inputted from the memory access control unit 511.

In addition, the negative-side voltage generator 532 is configured to select one of the generated negative-side read voltage Vr− and the negative-side disturb failure detection voltage Vd− on the basis of the selection signal d_en inputted from the microcontroller 53 provided in the memory bank 42. Furthermore, the negative-side voltage generator 532 is configured to output a voltage selected from between the negative-side read voltage Vr− and the negative-side disturb failure detection voltage Vd−, from an output unit 573 (not illustrated in FIG. 7, and to be described in detail later) operated by the output power supply V33− inputted from the DC/DC converter 515.

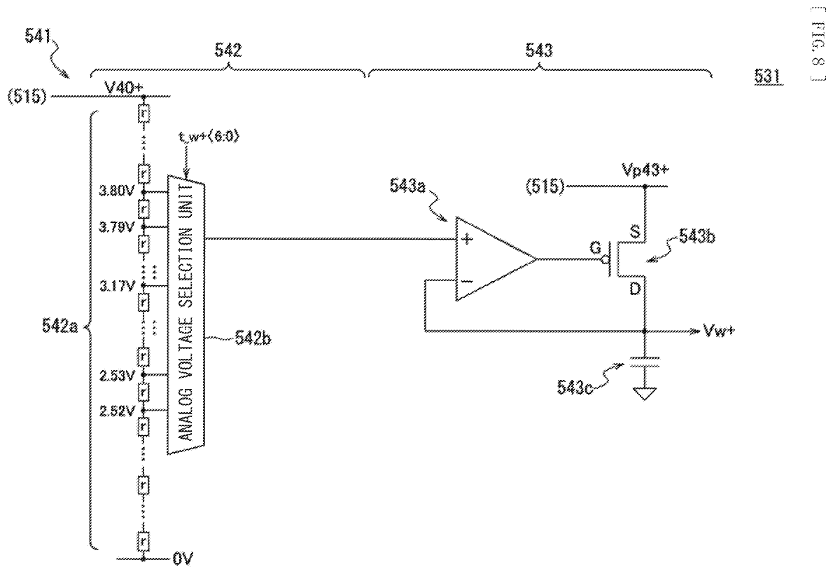

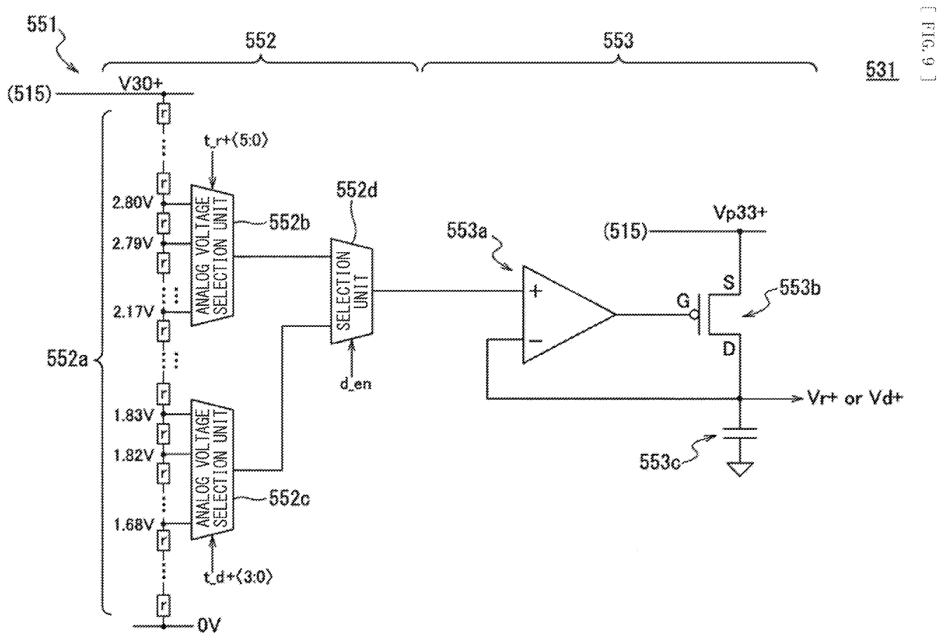

Here, description is given of a specific configuration of the negative-side voltage generator 532 with reference to FIGS. 10 and 11.

As illustrated in FIG. 10, the negative-side voltage generator 532 includes a negative-side write voltage regulator 561 that generates the negative-side write voltage Vw−. The negative-side write voltage regulator 561 includes a digital-analog converter 562 that generates the negative-side write voltage Vw− and an output unit 563 that outputs the negative-side write voltage Vw− inputted from the digital-analog converter 562.

The digital-analog converter 562 includes a ladder resistor circuit 562a having a plurality of resistor elements r coupled in series, and a analog voltage selection unit 562b that outputs, as the negative-side write voltage Vw−, one voltage of a plurality of voltages inputted from the ladder resistor circuit 562a. The plurality of resistor elements r provided in the ladder resistor circuit 562a is coupled in series between the reference potential (e.g., 0 V) and the reference power supply V40− (e.g., −4.0V) inputted from the DC/DC converter 515. This makes it possible for the ladder resistor circuit 562a to generate a plurality of levels of negative potentials (voltages with reference to the reference potential) obtained by resistively dividing a potential difference between the potential of the reference power supply V40− and the reference potential by the plurality of resistor elements r.

Some of the plurality of voltages generated by the ladder resistor circuit 562a are inputted to the analog voltage selection unit 562b. A plurality of voltages to be inputted to the analog voltage selection unit 562b includes the negative-side write voltage Vw− to be applied to the memory cell MC in the data write operation of each of the set operation and the reset operation. For example, the memory chip 31 according to the present embodiment is designed to apply a voltage of −3.5 V as the negative-side write voltage Vw− to the memory cell MC in the set operation and apply a voltage of −3.0 V to the memory cell MC in the reset operation. Accordingly, for example, a total of 128 levels of voltages from −3.80 V to −2.52 V at intervals of 0.01 V are inputted to the analog voltage selection unit 562b to include voltages of −3.5 V and −3.0 V.

The selection signal t_w−<6:0> is inputted from the memory access control unit 511 to the analog voltage selection unit 562b to cope with the error between chips described above. In the memory chip 31 according to the present embodiment, information about an optimum write voltage is stored by a value of the selection signal t_w−<6:0> in a predetermined storage region of the memory access control unit 511. In a case where the set operation and the reset operation of the memory cell MC are executed, the memory access control unit 511 outputs, to the analog voltage selection unit 562b, the selection signal t_w−<6:0> having a value read out from this storage region. The analog voltage selection unit 562b selects one voltage from among the plurality of voltages inputted from the ladder resistor circuit 562a on the basis of the value of the inputted selection signal t_w−<6:0>, and outputs the selected voltage as the negative-side write voltage Vw−. Thus, the analog voltage selection unit 562b exerts a function as a multiplexer circuit that switches an analog signal.

As illustrated in FIG. 10, the output unit 563 includes an amplifier 563a coupled to the analog voltage selection unit 562b, an NMOS transistor 563b coupled to the amplifier 563a, and a capacitor 563c coupled to the NMOS transistor 563b. The output unit 563 exerts a function as an amplifier unit by the amplifier 563a, the NMOS transistor 563b and the capacitor 563c.

The amplifier 563a includes, for example, an operational amplifier. A non-inverting input terminal (+) of amplifier 563a is coupled to an output terminal of the analog voltage selection unit 562b. An output terminal of the amplifier 563a is coupled to a gate terminal G of the NMOS transistor 563b. An inverting input terminal (−) of the amplifier 563a is coupled to a coupling section between a drain terminal D of the NMOS transistor 563b and one electrode of the capacitor 563c. The coupling section between the drain terminal D of the NMOS transistor 563b and the one electrode of the capacitor 563c serves as an output terminal of the output unit 563.

A source terminal S of the NMOS transistor 563b is coupled to an output terminal of the output power supply VP43− of the DC/DC converter 515. Accordingly, an output power supply VP43− is applied to the source terminal S of the NMOS transistor 563b. Another electrode of the capacitor 563c is coupled to a ground terminal. A potential of the ground terminal is, for example, the same as a reference potential to be applied to the ladder resistor circuit 562a. A terminal to which the reference potential is to be applied of the ladder resistor circuit 562a may be coupled to the ground terminal.

The coupling section between the drain terminal D of the NMOS transistor 563b and the one electrode of the capacitor 563c has substantially the same voltage as an output voltage of the amplifier 563a. The output unit 563 functions as a voltage follower circuit as a whole, and is able to output the negative-side write voltage Vw−. In addition, the output unit 563 includes the capacitor 563c, thereby achieving stabilization of the voltage level of negative-side write voltage Vw− to be outputted.

As illustrated in FIG. 11, the negative-side voltage generator 532 included in the voltage generator 516 includes a negative-side read voltage regulator 571 that generates the negative-side read voltage Vr− and the negative-side disturb failure detection voltage Vd−. The negative-side read voltage regulator 571 includes a digital-analog converter 572 that generates the read voltage (one example of a second voltage) Vr and the disturb failure detection voltage (one example of a specific voltage) Vd. The digital-analog converter 572 is configured to generate the negative-side read voltage Vr− of the read voltage Vr and the negative-side disturb failure detection voltage Vd− of the disturb failure detection voltage Vd.

The digital-analog converter 572 includes a ladder resistor circuit 572a including a plurality of resistor element r that is coupled in series. In addition, the digital-analog converter 572 includes an analog voltage selection unit 572b (one example of a first selection unit) that selects the read voltage Vr from among a plurality of analog voltages inputted from the ladder resistor circuit 572a. In addition, the digital-analog converter 572 includes an analog voltage selection unit 572c (one example of a second selection unit) that selects the disturb failure detection voltage Vd from among the plurality of analog voltages inputted from ladder resistor circuit 572a. The digital-analog converter 572 includes a selection unit 572d (one example of a third selection unit) that selects one of the read voltage Vr and the disturb failure detection voltage Vd.

The negative-side read voltage regulator 571 included in the negative-side voltage generator 532 of the voltage generator 516 includes an output unit 563 that outputs, to the memory cell MC, a voltage inputted from the selection unit 572d.

More specifically, the analog voltage selection unit 572b is a component that outputs, as the negative-side read voltage Vr− of the read voltage Vr, one negative voltage selected from among a plurality of negative voltages (analog voltages) inputted from the ladder resistor circuit 572a. The analog voltage selection unit 572c is a component that outputs, as the negative-side disturb failure detection voltage Vd− of the disturb failure detection voltage Vd, one negative voltage selected from among the plurality of negative voltages (analog voltage) inputted from the ladder resistor circuit 572a. The selection unit 572d is a component that selects and outputs one of the negative-side read voltage Vr− inputted from the analog voltage selection unit 572b and the negative-side disturb failure detection voltage Vd− inputted from analog voltage selection unit 572c.

The plurality of resistor elements r provided in the ladder resistor circuit 572a is coupled in series between the reference potential (e.g., 0 V) and the reference power supply V30− (e.g., −3.0V) inputted from the DC/DC converter 515. This makes it possible for the ladder resistor circuit 572a to generate a plurality of levels of negative potentials (voltages with reference to the reference potential) obtained by resistively dividing a potential difference between the potential of the reference power supply V30− and the reference potential by the plurality of resistor elements r.

Some of a plurality of negative voltages generated by the ladder resistor circuit 572a are inputted to the analog voltage selection unit 572b. A plurality of negative voltages inputted to the analog voltage selection unit 572b includes a negative-side read voltage Vr− to be applied to the memory cell MC in the data read operation. For example, the memory chip 31 according to the present embodiment is designed to apply a voltage of −2.5 V as the negative-side read voltage Vr− to the memory cell MC in the read operation. Accordingly, for example, a total of 64 levels of voltages from −2.80 V to −2.17 V at intervals of 0.01 V are inputted to the analog voltage selection unit 572b to include a voltage of −2.5 V.

Another some of the plurality of negative voltages generated by the ladder resistor circuit 572a are inputted to the analog voltage selection unit 572c. A plurality of negative voltages inputted to the analog voltage selection unit 572c includes the negative-side disturb failure detection voltage Vd− to be applied to the memory cell MC in the disturb failure detecting operation. The disturb failure detection voltage Vd is set to a voltage equal to or higher than a half of the reset voltage Vrst and lower than the read voltage Vr. Accordingly, the negative-side disturb failure detection voltage Vd− is set to a voltage equal to or lower than a half of a negative-side reset voltage Vrst− and higher than the negative-side read voltage Vr−. For example, the memory chip 31 according to the present embodiment is designed to apply a voltage of −1.75 V as the negative-side disturb failure detection voltage Vd− to the memory cell MC in the disturb failure detecting operation. Accordingly, for example, a total of 64 levels of voltages from −1.83 V to −1.68 V at intervals of 0.01 V are inputted to the analog voltage selection unit 572c to include a voltage of −1.75 V.

The selection signal t_r−<5:0> is inputted from the memory access control unit 511 to the analog voltage selection unit 572b to cope with the error between chips described above. In the memory chip 31 according to the present embodiment, information about an optimum negative-side read voltage Vr− is stored as a value of the selection signal t_r−<5:0> in a predetermined storage region of the memory access control unit 511. In a case where the read operation, the preread operation, and the verifying operation of the memory cell MC are executed, the memory access control unit 511 outputs, to the analog voltage selection unit 572b, the selection signal t_r−<5:0> having a value read out from this storage region. The analog voltage selection unit 572b selects one negative voltage from among the plurality of negative voltages inputted from the ladder resistor circuit 572a on the basis of the value of the inputted selection signal t_r−<5:0>, and outputs the selected negative voltage as the negative-side read voltage Vr−. Thus, the analog voltage selection unit 572b exerts a function as a multiplexer circuit that switches an analog signal.

The selection signal t_d−<3:0> is inputted from the memory access control unit 511 to the analog voltage selection unit 572c to cope with the error between chips. In the memory chip 31 according to the present embodiment, information about an optimum negative-side disturb failure detection voltage Vd− is stored by a value of the selection signal t_d−<3:0> in a predetermined storage region of the memory access control unit 511. In a case where the disturb failure detecting operation of the memory cell MC is executed, the memory access control unit 511 outputs, to the analog voltage selection unit 572c, the selection signal t_d−<3:0> having a value read out from this storage region. The analog voltage selection unit 572c selects one negative voltage from among the plurality of negative voltages inputted from the ladder resistor circuit 572a on the basis of the value of the inputted selection signal t_d−<3:0>, and outputs the selected negative voltage as the disturb failure detection voltage Vd− to the selection unit 572d. Thus, the analog voltage selection unit 572c exerts a function as a multiplexer circuit that switches an analog signal.

The selection signal d_en is inputted from the microcontroller 53 to the selection unit 572d. Accordingly, in a case where the selection signal d_en having the low level is inputted, the selection unit 572d selects the negative-side read voltage Vr− inputted from the analog voltage selection unit 572b and outputs the negative-side read voltage Vr− to the output unit 573. In contrast, in a case where the selection signal d_en having the high level is inputted, the selection unit 572d selects the negative-side disturb failure detection voltage Vd− inputted from the analog voltage selection unit 572c and outputs the negative-side disturb failure detection voltage Vd− to the output unit 573.

As illustrated in FIG. 11, the output unit 573 includes an amplifier 573a coupled to the selection unit 572d, an NMOS transistor 573b coupled to the amplifier 573a, and a capacitor 573c coupled to the NMOS transistor 573b. The output unit 573 exerts a function as an amplifier unit by the amplifier 573a, the NMOS transistor 573b, the capacitor 573c.

The amplifier 573a includes, for example, an operational amplifier. A non-inverting input terminal (+) of the amplifier 573a is coupled to an output terminal of the selection unit 572d. An output terminal of the amplifier 573a is coupled to a gate terminal G of the NMOS transistor 573b. An inverting input terminal (−) of the amplifier 573a is coupled to a coupling section between a drain terminal D of the NMOS transistor 573b and one electrode of the capacitor 573c. The coupling section between the drain terminal D of the NMOS transistor 573b and the one electrode of the capacitor 573c serves as an output terminal of the output unit 573.

A source terminal S of the NMOS transistor 573b is coupled to an output terminal of the output power supply Vp33− (e.g., −3.3 V) of the DC/DC converter 515. Accordingly, the output power supply VP33− is applied to the source terminal S of the NMOS transistor 573b. Another electrode of the capacitor 573c is coupled to a ground terminal. A potential of the ground terminal is, for example, the same as a reference potential to be applied to the ladder resistor circuit 572a. A terminal to which the reference potential is to be applied of the ladder resistor circuit 572a may be coupled to the ground terminal.

The coupling section between the drain terminal D of the NMOS transistor 573b and the one electrode of the capacitor 573c has substantially the same voltage as the output voltage of the amplifier 573a. The output unit 573 functions as a voltage follower circuit as a whole. In a case where the negative-side read voltage Vr− is inputted from the selection unit 572d, the output unit 573 is able to output the negative-side read voltage Vr−. In addition, in a case where the negative-side disturb failure detection voltage Vd− is inputted from the selection unit 572d, the output unit 573 is able to output the negative-side disturb failure detection voltage Vd−. In addition, the output unit 573 includes the capacitor 573c, thereby achieving stabilization of the voltage level of the negative-side read voltage Vr− or the negative-side disturb failure detection voltage Vd− to be outputted.

Referring back to FIG. 7, the reference voltage generator 533 provided in the voltage generator 516 is configured to generate an upper-side reference voltage (hereinafter also referred to as an “upper reference voltage”) Vrefu that is compared with a voltage detected from the upper memory cell UMC (see FIG. 5) in the data read operation on the basis of the reference power supply V30+ and the output power supply V33+ inputted from the DC/DC converter 515. In addition, the reference voltage generator 533 is configured to generate a lower-side reference voltage (hereinafter also referred to as a “lower reference voltage”) Vrefl that is compared with a voltage detected from the lower memory cell LMC in the data read operation on the basis of the reference power supply V30− and the output power supply V33− inputted from the DC/DC converter 515. The reference voltage generator 533 is configured to output the generated upper reference voltage Vrefu and the generated lower reference voltage Vrefl to the analog voltage output unit 524.

Although not illustrated, the reference voltage generator 533 includes a upper reference voltage regulator. The upper reference voltage regulator includes a resistance division circuit that generates, for example, the upper reference voltage Vrefu of 1 V from the reference power supply V30+, and an output unit that uses the output power supply V33+ as a power supply and has a configuration similar to the output unit 543 provided in the positive-side write voltage regulator 541 (see FIG. 8). The upper reference voltage regulator is configured to output, from the output unit, the upper reference voltage Vrefu inputted from the resistance division circuit.

Although not illustrated, the reference voltage generator 533 includes a lower reference voltage regulator. The lower reference voltage regulator includes a resistance division circuit that generates, for example, the lower reference voltage Vrefl of −1 V from the reference power supply V30−, and an output unit that uses the output power supply V33− as a power supply and has a configuration similar to the output unit 563 provided in the negative-side write voltage regulator 561 (see FIG. 10). The lower reference voltage regulator is configured to output, from the output unit, the lower reference voltage Vrefl inputted from the resistance division circuit.

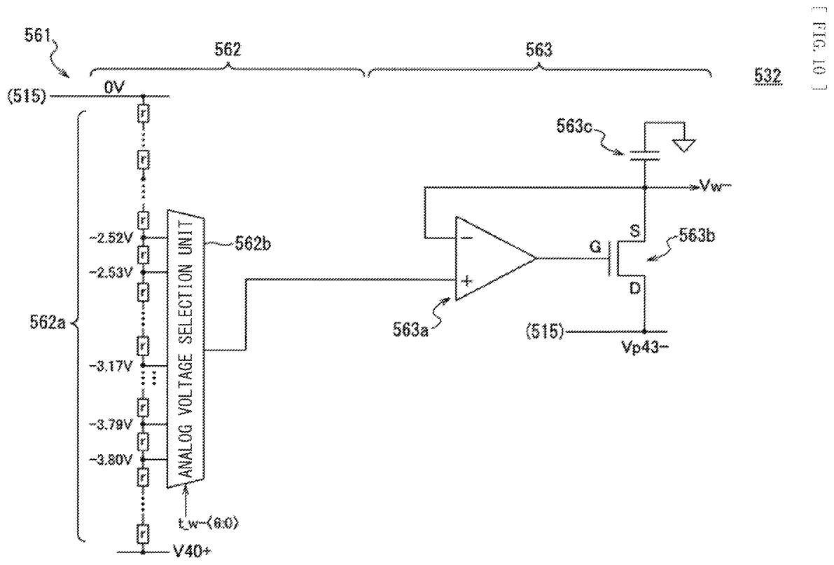

Next, description is given of the tile circuit 612 provided in the memory tile 61 (see FIG. 4) with reference to FIG. 12 while referring to FIGS. 3 to 7.

As illustrated in FIG. 12, the tile circuit 612 includes a global bit line (one example of a first global line) GBL to which one positive electrode-side potential (the positive-side write voltage Vw+, the positive-side read voltage Vr+, or the positive-side disturb failure detection voltage Vd+) or one negative electrode-side potential (the negative-side write voltage Vw−, the negative-side read voltage Vr−, or the negative-side disturb failure detection voltage Vd−) of the write voltage Vw, the read voltage Vr, and the disturb failure detection voltage Vd is applied as necessary. The tile circuit 612 includes a global word line (one example of a second global line) to which one negative electrode-side potential (the negative-side write voltage Vw−, the negative-side read voltage Vr−, or the negative-side disturb failure detection voltage Vd−) or one positive electrode-side potential (the positive-side write voltage Vw+, the positive-side read voltage Vr+, or the positive-side disturb failure detection voltage Vd+) of the write voltage Vw, the read voltage Vr, and the disturb failure detection voltage Vd is applied as necessary.

The tile circuit 612 includes an even number-side bit line decoder 623 and an odd number-side bit line decoder 624 (both of which are examples of a first decoder) that are coupled to the global bit line GBL by selecting a selected bit line (one example of a selected first line) selected from a plurality of bit lines BLk on the basis of a bit line address BLA inputted from the microcontroller 53 (see FIG. 4). The tile circuit 612 includes an even number-side word line decoder 621 and an odd number-side word line decoder 622 (both of which are examples of a second decoder) that are coupled to the global word line by selecting a selected word line (one example of a selected second line) selected from a plurality of upper word lines UWLi and a plurality of lower word lines LWLj on the basis of a word line address WLA inputted from the microcontroller 53 (see FIG. 4).

The tile circuit 612 includes a voltage switching unit 625 that switches a voltage to be applied to the global bit line GBL and the global word line GWL among the write voltage Vw, the read voltage Vr, and the disturb failure detection voltage Vd. The tile circuit 612 includes a data detector (one example of a detector) 627 that detects the resistive state of the variable resistor element VR provided in the memory cell MC corresponding to that tile circuit 612. The tile circuit 612 includes a data latch unit (one example of a holding unit) 626 that is able to hold write data and read data.

The configuration of the tile circuit 612 is described in more detail. As illustrated in FIG. 12, the voltage switching unit 625 provided in the tile circuit 12 is coupled to the voltage generator 516 through the analog voltage output unit 524 (see FIG. 6 for both) provided in the peripheral unit 41. More specifically, the voltage switching unit 625 is coupled to the positive-side voltage generator 531 and the negative-side voltage generator 532 (see FIG. 7) provided in the voltage generator 516 through the analog voltage output unit 524. Thus, the positive-side write voltage Vw+, the negative-side write voltage Vw−, the positive-side read voltage Vr+, the negative-side read voltage Vr−, the positive-side disturb failure detection voltage Vd+, and the negative-side disturb failure detection voltage Vd− that are generated by the voltage generator 516 are inputted to the voltage switching unit 625.

In addition, the voltage switching unit 625 is coupled to the microcontroller 53, the global bit line GBL, and the global word line GWL. The microcontroller 53 is configured to input, to the voltage switching unit 625, a switching control signal CTLsw of an analog voltage to be applied to the global bit line GBL and the global word line GWL. The voltage switching unit 625 respectively inputs positive electrode-side and negative electrode-side voltages as a set out of analog voltages such as the positive-side write voltage Vw+ inputted from the voltage generator 516 to the global bit line GBL and the global word line GWL on the basis of the switching control signal CTLsw inputted from the microcontroller 53. For example, the voltage switching unit 625 applies the negative-side write voltage Vw− to the global word line GWL in a case where positive-side write voltage Vw+ is applied to the global bit line GBL. Thus, the voltage switching unit 625 is configured to be controlled by the microcontroller 53 to switch the analog voltages to be applied to the global bit line GBL and the global word line GWL.

In addition, the voltage switching unit 625 is coupled to the data latch unit 626. Accordingly, the write data WDATA temporarily held by the data latch unit 626 is inputted to the voltage switching unit 625 as necessary.

The even number-side word line decoder 621 is coupled to the voltage switching unit 625 through the global word line GWL. The even number-side word line decoder 621 is also coupled to the microcontroller 53. The even number-side word line decoder 621 is also coupled to a plurality of memory cells MC through even-numbered upper word lines UWLi (i is an even number of 0 and 1 to 4095) and even-numbered lower word lines LWLj (j is an even number of 0 and 1 to 4095). In addition, in the write operation and the read operation, a blocking voltage Vinh_wl is inputted to the even number-side word line decoder 621. The blocking voltage Vinh_wl blocks the write voltage Vw and the read voltage Vr from being applied to the memory cell MC that is not a data write target nor a data read target. The blocking voltage Vinh_wl is, for example, a voltage lower than the disturb failure detection voltage Vd, and is a reference voltage. The reference voltage is, for example, a voltage having the same potential as a ground.

The odd number-side word line decoder 622 is coupled to the voltage switching unit 625 through the global word line GWL. The odd number-side word line decoder 622 is also coupled to the microcontroller 53. The odd number-side word line decoder 622 is also coupled to a plurality of memory cells MC through odd-numbered upper word lines UWLi (i is an odd number of 1 to 4095) and odd-numbered lower word lines LWLj (j is an odd number of 1 to 4095). In addition, the blocking voltage Vinh_wl is also inputted to the odd number-side word line decoder 622.

The microcontroller 53 inputs, to the even number-side word line decoder 621 and the odd number-side word line decoder 622, the word line address WLA to which an analog voltage such as the positive-side write voltage Vw+ is to be applied. In a case where the word line address WLA inputted from the microcontroller 53 is an address of an even-numbered word line, the even number-side word line decoder 621 couples the word line WLi corresponding to the word line address WLA and the global word line GWL to each other, and applies the blocking voltage Vinh_wl to the remaining even-numbered word lines WLi. In addition, in a case where the word line address WLA inputted from the microcontroller 53 is an address of an even-numbered word line, the odd number-side word line decoder 622 applies the blocking voltage Vinh_wl to all the odd-numbered word lines WLi. Thus, an analog voltage applied to the global word line GWL is applied to the even-numbered word line WLi coupled to the memory cell MC as a control target, and the blocking voltage Vinh_wl is applied to the remaining word lines WLi.

In contrast, in a case where the word line address WLA inputted from the microcontroller 53 is an address of an odd-numbered word line, the odd number-side word line decoder 622 couples the word line WLi corresponding to the word line address WLA and the global word line GWL to each other, and applies the blocking voltage Vinh_wl to the remaining odd-numbered word lines WLi. In addition, in a case where the word line address WLA inputted from the microcontroller 53 is an address of an odd-numbered word line, the even number-side word line decoder 621 applies the blocking voltage Vinh_wl to all the odd-numbered word lines WLi. Thus, the analog voltage applied to the global word line GWL is applied to the odd-numbered word line WLi coupled to the memory cell MC as a control target, and the blocking voltage Vinh_wl is applied to the remaining word lines WLi.

The even number-side bit line decoder 623 is coupled to the voltage switching unit 625 through the global bit line GBL. The even number-side bit line decoder 623 is also coupled to the microcontroller 53. The even number-side bit line decoder 623 is also coupled to a plurality of memory cells MC through even-numbered bit lines BLk (k is an even number of 0 and 1 to 2047). In addition, in the write operation and the read operation, a blocking voltage Vinh_bl is inputted to the even number-side bit line decoder 623. The blocking voltage Vinh_bl blocks the write voltage Vw and the read voltage Vr from being applied to the memory cell MC that is not a data write target nor a data read target. The blocking voltage Vinh_bl is, for example, a voltage lower than the disturb failure detection voltage Vd, and is a reference voltage. The reference voltage is, for example, a voltage having the same potential as the ground.

The odd number-side bit line decoder 624 is coupled to the voltage switching unit 625 through the global bit line GBL. The odd number-side bit line decoder 624 is also coupled to the microcontroller 53. The odd number-side bit line decoder 624 is also coupled to a plurality of memory cells MC through odd-numbered bit lines BLk (k is an odd number of 1 to 2047). In addition, the blocking voltage Vinh_blis is also inputted to the odd number-side bit line decoder 624.

The microcontroller 53 inputs, to the even number-side bit line decoder 623 and the odd number-side bit line decoder 624, the bit line address BLA to which an analog voltage such as the positive-side write voltage Vw+ is to be applied. In a case where the bit line address BLA inputted from the microcontroller 53 is an address of an even-numbered bit line, the even number-side bit line decoder 623 couples the bit line BLk corresponding to the bit line address BLA and the global bit line GBL to each other, and applies the blocking voltage Vinh_bl to the remaining even-numbered bit lines BLk. In addition, in a case where the bit line address BLA inputted from the microcontroller 53 is an address of an even-numbered bid line, the odd number-side bit line decoder 624 applies the blocking voltage Vinh_bl to all the odd-numbered bit lines BLk. Thus, an analog voltage applied to the global bit line GBL is applied to the even-numbered bit line BLk coupled to the memory cell MC as a control target, and the blocking voltage Vinh_bl is applied to the remaining bit lines BLk.

In contrast, in a case where the bit line address BLA inputted from the microcontroller 53 is an address of an odd-numbered bit line, the odd number-side bit line decoder 624 couples the bit line BLk corresponding to the bit line address BLA and the global bit line GBL to each other, and applies the blocking voltage Vinh_bl to the remaining odd-numbered bit lines BLk. In addition, in a case where the bit line address BLA inputted from the microcontroller 53 is an address of an odd-numbered bit line, the even number-side bit line decoder 623 applies the blocking voltage Vinh_bl to all the odd-numbered bit lines BLk. Thus, the analog voltage applied to the global bit line GBL is applied to the odd-numbered bit line BLk coupled to the memory cell MC as a control target, and the blocking voltage Vinh_bl is applied to the remaining bit lines BLk.

Thus, the voltage switching unit 625, the even number-side word line decoder 621, the odd number-side word line decoder 622, the even number-side bit line decoder 623, and the odd number-side bit line decoder 624 are controlled by the microcontroller 53, and a predetermined voltage is applied to the memory cell MC as a control target.

As illustrated in FIG. 12, the data detector 627 is coupled to the voltage generator 516 through the analog voltage output unit 524 provided in the peripheral unit 41. More specifically, the data detector 627 is coupled to the reference voltage generator 533 (see FIG. 7) provided in the voltage generator 516 through the analog voltage output unit 524. Thus, the upper reference voltage Vrefu and the lower reference voltage Vrefl generated by the reference voltage generator 533 are inputted to the data detector 627.

In addition, the data detector 627 is coupled to the microcontroller 53, the global word line GWL, and the data latch unit 626. The data detector 627 is configured to output the read data RDATA to the data latch unit 626 on the basis of a data readout control signal CTLr inputted from the microcontroller 53. As described in detail later, the data latch unit 626 includes an upper sense amplifier that outputs, as the read data RDATA, a result of comparison between a detected voltage, which is detected by the upper memory cell UMC and inputted through the global word line GWL, and the upper reference voltage Vrefu. The data latch unit 626 also includes a lower sense amplifier that outputs, as the read data RDATA, a result of comparison between a detected voltage, which is detected by the lower memory cell LMC and inputted through the global word line GWL, and the lower reference voltage Vrefl.

As illustrated in FIG. 12, the data latch unit 626 is coupled to the memory access control unit 511 (see FIG. 6) provided in the peripheral circuit 51 through the signal input/output unit 523 (see FIG. 6) provided in the peripheral unit 41. The data latch unit 626 is also coupled to the microcontroller 53, the voltage switching unit 625, and the data detector 627. The data latch unit 626 includes a write data latch circuit (not illustrated) that temporarily holds the write data WDATA inputted from the signal input/output unit 523, and a read data latch circuit (not illustrated) that temporarily holds the read data RDATA inputted from the data detector 627. As described in detail later, the data latch unit 626 includes a set verification latch circuit, a reset verification latch circuit, and a disturb failure detection latch circuit (all of which are not illustrated).

The data latch unit 626 is configured to hold the write data WDATA inputted from the signal input/output unit 523 in the write data latch circuit and output the write data held by the write data latch circuit to the voltage switching unit 625 on the basis of a data latch control signal CTL1 inputted from the microcontroller 53. In addition, the data latch unit 626 is configured to hold the read data RDATA inputted from the data latch unit 626 in the read data latch circuit and output the read data RDATA held by the read data latch circuit to the memory access control unit 511 on the basis of the data latch control signal CTL1 inputted from the microcontroller 53.

The voltage generator 516 is coupled in parallel to the voltage switching units 625 of all the tile circuits 612 provided in the plurality of memory banks 42 through the analog voltage output unit 524. Accordingly, the positive-side write voltage Vw+, the negative-side write voltage Vw−, the positive-side read voltage Vr+, the negative-side read voltage Vr−, the positive-side disturb failure detection voltage Vd+, and the negative-side disturb failure detection voltage Vd− are inputted to the voltage switching units 625 of all the tile circuits 612 provided in the plurality of memory banks 42. However, the microcontrollers 53 other than the microcontroller 53 provided in the activated memory bank 42 do not operate. Accordingly, of all the voltage switching units 625 formed in the memory chip 31, only all the voltage switching units 625 provided in the activated memory bank 42 are able to apply a predetermined analog voltage such as the positive-side write voltage Vw+ to the global bit line GBL and the global word line GWL.

The voltage generator 516 is coupled in parallel to the data detectors 627 of all the tile circuits 612 provided in the plurality of memory banks 42 through the analog voltage output unit 524. Accordingly, the upper reference voltage Vrefu and the lower reference voltage Vrefl are inputted to the data detectors 627 of all the tile circuits 612 provided in the plurality of memory banks 42. However, the microcontrollers 53 other than the microcontroller provided in the activated memory bank 42 do not operate. Accordingly, of all the data detectors 627 formed in the memory chip 31, only all the data detectors 627 provided in the activated memory bank 42 are able to detect a voltage inputted from the memory cell MC as a control target.

Next, description is given of the data write operation to the memory cell MC and the data read operation from the memory cell MC with reference to FIGS. 13 to 20.

An equivalent circuit of a portion of the memory cell array 611 is illustrated on left side in FIG. 13, and the direction of a current supplied to the memory cell MC in the data write operation and the like is illustrated on right side in FIG. 13.

As illustrated on the left side in FIG. 13, the memory cell MC has a series structure of the variable resistor element VR and the selector element SE. That is, the memory cell MC is a one-selector element-one variable resistor element (1S1R) memory element. In addition, the memory cell MC is disposed at an intersection (intersection point) of the bit line BL and the word line WL, and has a cross-point (XP) structure.

A plurality of upper memory cells UMC (only one of which is illustrated in FIG. 13) is disposed between the upper word lines UWLi and the bit lines BLk in a state in which the variable resistor elements VR are disposed on side of the upper word lines UWLi and the selector elements SE are disposed on side of the bit lines BLk. As illustrated on the right side in FIG. 13, in the set operation in the data write operation or the data read operation, a voltage is applied to the upper memory cell UMC to cause a current from the variable resistor element VR to the selector element SE to flow. Accordingly, in a case of the set operation in the data write operation, the positive-side write voltage Vw+ is applied to the upper word line UWLi, and the negative-side write voltage Vw− is applied to the bit line BLk. Furthermore, in the case of the set operation in the data write operation, a set current Iset (e.g., a constant current having a current amount of 50 μA) flowing in a direction of “the upper word line UWLi→the variable resistor element VR→the selector element SE→the bit line BLk” is supplied from the current source 517 (see FIG. 6) provided in the peripheral circuit 51 of the peripheral unit 41.

In addition, in a case of the data read operation, the preread operation, and the verifying operation, the positive-side read voltage Vr+ is applied to the upper word line UWLi, and the negative-side read voltage Vr− is applied to the bit line BLk. Furthermore, in the case of the data read operation, the preread operation, and the verifying operation, the set current Iset (e.g., a constant current having a current amount of 50 μA) flowing in a direction of “the upper word line UWLi→the variable resistor element VR→the selector element SE→the bit line BLk” is supplied from the current source 517 (see FIG. 6) provided in the peripheral circuit 51 of the peripheral unit 41.

In contrast, as illustrated on the right side in FIG. 13, in the reset operation in the data write operation, a voltage is applied to the upper memory cell UMC to cause a current from the selector element SE to the variable resistor element VR to flow. Accordingly, in a case of the reset operation in the data write operation, the negative-side write voltage Vw− is applied to the lower word line LWLj, and the positive-side write voltage Vw+ is applied to the bit line BLk. Furthermore, in the case of the reset operation in the data write operation, a reset current Irst (e.g., a constant current having a current amount of 30 μA) flowing in a direction of “the lower word line LWLj→the selector element SE→the variable resistor element VR→the bit line BLk” is supplied from the current source 517.

A plurality of lower memory cells LMC (only one of which is illustrated in FIG. 13) is disposed between the bit lines BLk and the lower word lines LWLj in a state in which the variable resistor elements VR are disposed on side of the bit lines BLk and the selector elements SE are disposed on side of the lower word lines LWLj. As illustrated on the right side in FIG. 13, in the set operation in the data write operation or the data read operation, a voltage is applied to the lower memory cell LMC to cause a current from the variable resistor element VR to the selector element SE to flow. Accordingly, in a case of the set operation in the data write operation, the positive-side write voltage Vw+ is applied to the bit line BLk, and the negative-side write voltage Vw− is applied to the lower word line LWLj. Furthermore, in the case of the set operation in the data write operation, the set current Iset (e.g., a constant current having a current amount of 50 μA) flowing in a direction of “the bit line BLk→the variable resistor element VR→the selector element SE→the lower word line LWLj ” is supplied from the current source 517.

In addition, in the case of the data read operation, the preread operation, and the verifying operation, the positive-side read voltage Vr+ is applied to the lower word line LWLj, and the negative-side read voltage Vr− is applied to the bit line BLk. Furthermore, in the case of the data read operation, the preread operation, and the verifying operation, the set current Iset (e.g., a constant current having a current amount of 50 μA) flowing in a direction of “the bit line BLk→the variable resistor element VR→the selector element SE→the lower word line LWLj ” is supplied from the current source 517.

In contrast, as illustrated on the right side in FIG. 13, in the reset operation in the data write operation, a voltage is applied to the lower memory cell LMC to cause a current from the selector element SE to the variable resistor element VR to flow. Accordingly, in the case of the reset operation in the data write operation, the positive-side write voltage Vw+ is applied to the lower word line LWLj, and the negative-side write voltage Vw− is applied to the bit line BLk. Furthermore, in the case of the reset operation in the data write operation, the reset current Irst (e.g., a constant current having a current amount of 30 μA) flowing in a direction of “the lower word line LWLj→the selector element SE→the variable resistor element VR→the bit line BLk” is supplied from the current source 517.

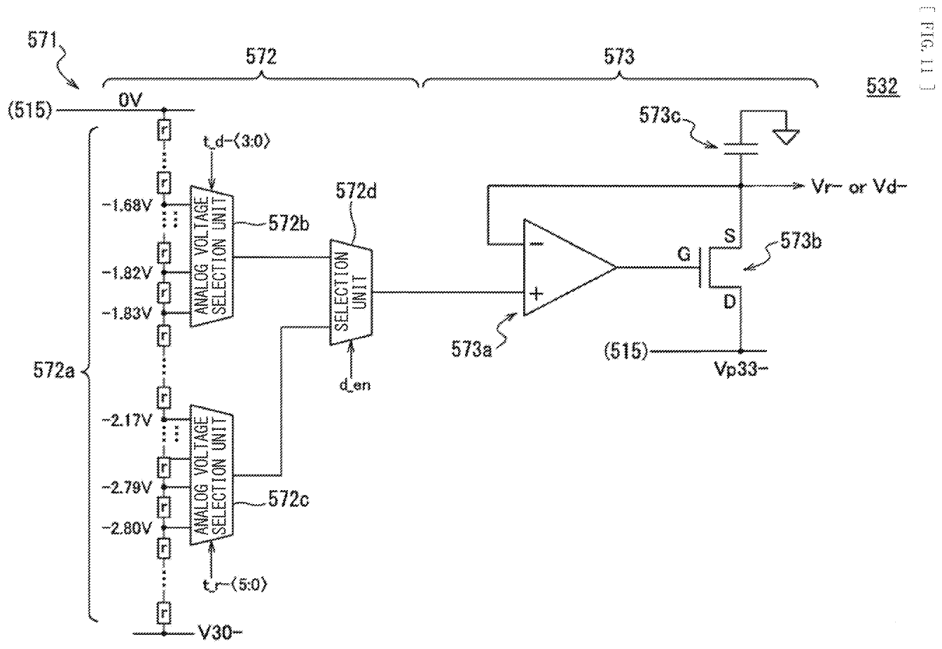

Next, description is given of current-voltage characteristics of the memory cell MC with reference to FIG. 14. A horizontal axis of a graph illustrated in FIG. 14 indicates a both-end voltage Vcell [V] to be applied across the memory cell MC. The memory cell MC has a series structure of the variable resistor element VR and the selector element SE. A vertical axis of the graph illustrated in FIG. 14 indicates a current Icell [A] flowing through the memory cell MC. In FIG. 14, “IVL” indicates current-voltage characteristics of the memory cell MC in which the variable resistor element VR is in the low resistive state. In FIG. 14, “IVH” indicates current-voltage characteristics of the memory cell MC in which the variable resistor element VR is in the high resistive state.

In a case where the both-end voltage Vcell to be applied across the memory cell MC in which the variable resistor element VR is in the low resistive state (Low Resistive State: LRS) is swept (swept) from 0 V to become higher, the current Icell flowing through the memory cell MC starts to flow at the both-end voltage Vcell of, for example, 1 V, and increases substantially linearly until the both-end voltage Vcell becomes, for example, 4 V, as illustrated by the current-voltage characteristics IVL in FIG. 14. The both-end voltage Vcell across the memory cell MC decreases, for example, when reaching 4 V, and the current Icell increases abruptly (see a broken line portion in the current-voltage characteristics IVL). A phenomenon in which the both-end voltage Vcell across the memory cell MC decreases and the current Icell starts to flow abruptly is called “snap phenomenon”, and the both-end voltage Vcell that causes the snap phenomenon is called “snap voltage”. In an example illustrated in FIG. 14, the snap voltage is 4 V. The memory cell MC sweeps the both-end voltage Vcell after the snap phenomenon has occurred in the low resistive state of the variable resistor element VR to increase the both-end voltage Vcell, which causes the current Icell to increase along nonlinear characteristics (see a curved portion of a solid line in the current-voltage characteristics IVL).

In a case where the both-end voltage Vcell across the memory cell MC in which the variable resistor element VR is in the high resistive state (High Resistive State: HRS) is swept from 0 V to become higher, the current Icell flowing through the memory cell MC starts to flow at the both-end voltage Vcell of, for example, 1 V, and increases substantially linearly until the both-end voltage Vcell becomes, for example, 6 V, as illustrated by the current-voltage characteristics IVH in FIG. 14. The both-end voltage Vcell across the memory cell MC decreases, for example, when reaching 6 V, and the current Icell increases abruptly (see a broken line portion of the current-voltage characteristics IVH). Thus, the snap voltage of the memory cell MC in a case where the variable resistor element VR is in the high resistive state is, for example, 6 V, which is higher than the snap voltage in a case where the variable resistor element VR is in the low resistive state. The memory cell MC sweeps the both-end voltage Vcell after the snap phenomenon has occurred in the high resistive state of the variable resistor element VR to increase the both-end voltage Vcell, which causes the current Icell to increase along nonlinear characteristics (see a curved portion of a solid line in the current-voltage characteristics IVH). The current-voltage characteristics of the memory cell MC after the snap phenomenon has occurred is substantially the same regardless of the resistive state of the variable resistor element VR.

As illustrated in FIG. 14, in the data read operation, the both-end voltage Vcell (e.g., 5 V) between the snap voltage in a case where the variable resistor element VR is in the low resistive state and the snap voltage in a case where the variable resistor element VR is in the high resistive state is applied as the read voltage Vr to the memory cell MC. By doing so, the snap phenomenon occurs in the memory cell MC in which the variable resistor element VR is in the low resistive state, whereas the snap phenomenon does not occur in the memory cell MC in which the variable resistor element VR is in the high resistive state. As a result, as illustrated in FIG. 14, a current value of the current Icell of the memory cell MC in which the variable resistor element VR is in the low resistive state becomes a current value CV1, and a current value of the current Icell of the memory cell MC in which the variable resistor element VR is in the high resistive state becomes a current value CVh. There is a difference of about 104 between the current value CV1 and the current value CVh. As described in detail later, the memory chip 31 according to the present embodiment is configured to determine the value of data stored in the memory cell MC with use of the difference in the current generated in a case where the read voltage Vr is applied to the memory cell MC.

The memory cell MC in which the variable resistor element VR is the high resistive state snaps to cause a current of about 50 μA to flow through the variable resistor element VR in a predetermined direction, which changes the variable resistor element VR to the low resistive state. In contrast, the memory cell MC in which the variable resistor element VR is in the low resistive state snaps to cause a current of about 30 μA to flow through the variable resistor element VR in a direction opposite to the direction in the case where the variable resistor element VR is in the high resistive state, which changes the variable resistor element VR to the high resistive state. The memory cell MC according to the present embodiment is configured to store data of 1 bit with use of this characteristics of the variable resistor element VR. In the present embodiment, the variable resistor element VR is set to the low resistive state in a case where the memory cell MC stores data of “1”. In addition, the variable resistor element VR is set to the high resistive state in a case where the memory cell MC stores data of “0”. Accordingly, the memory chip 31 executes the set operation in a case where the data of “1” is stored in the memory cell MC, and executes the reset operation in a case where the data of “0” is stored in the memory cell MC.

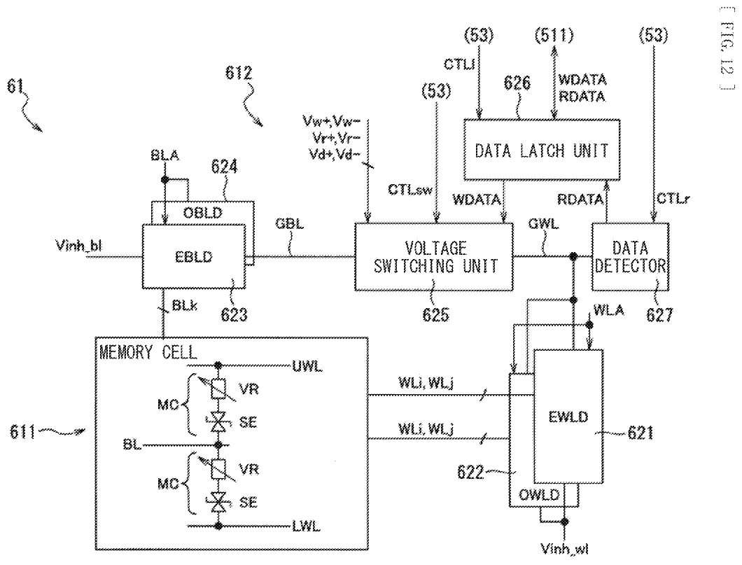

Next, description is given of the data write operation to the memory cell MC and the data read operation from the memory cell MC with reference to FIGS. 15 to 20. FIGS. 15, 17, and 19 schematically illustrate the lower word lines LWL0, and LWL1 and the bit lines BL0 and BL1. In addition, FIGS. 15, 17, and 19 schematically illustrate the lower memory cells LMC00 and LMC01 disposed at respective intersections of the lower word lines LWL0 and the bit lines BL0 and BL1, and the lower memory cells LMC10 and LMC11 disposed at respective intersections of the lower word lines LWL1 and the bit lines BL0 and BL1. In addition, FIGS. 15, 17, and 19 schematically illustrate the even number-side word line decoder 621, the odd number-side word line decoder 622, the even number-side bit line decoder 623, and the odd number-side bit line decoder 624. In addition, FIG. 15 illustrates a lower sense amplifier 627l provided in the data detector 627 coupled to the global word line GWL.

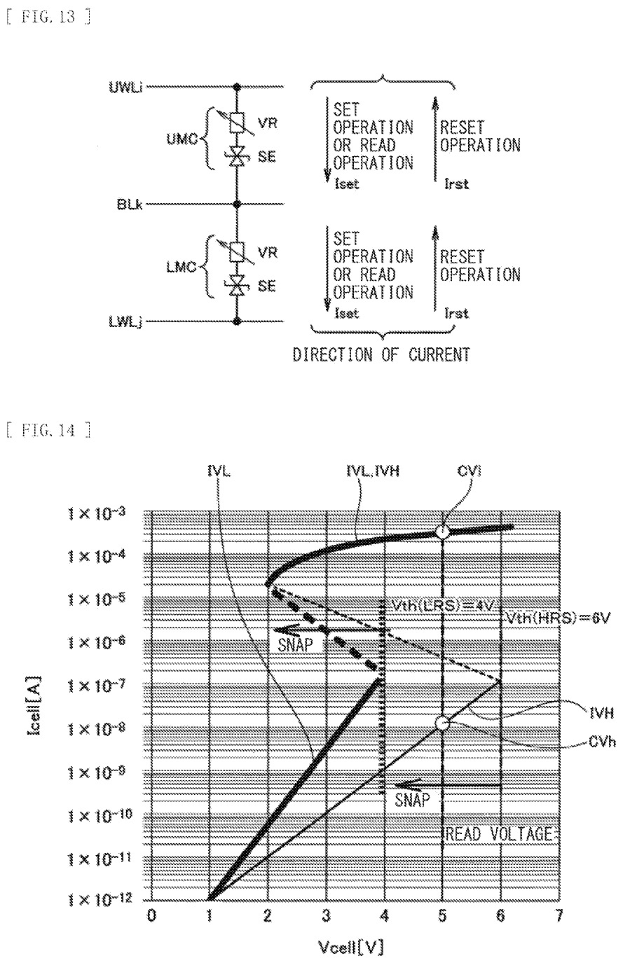

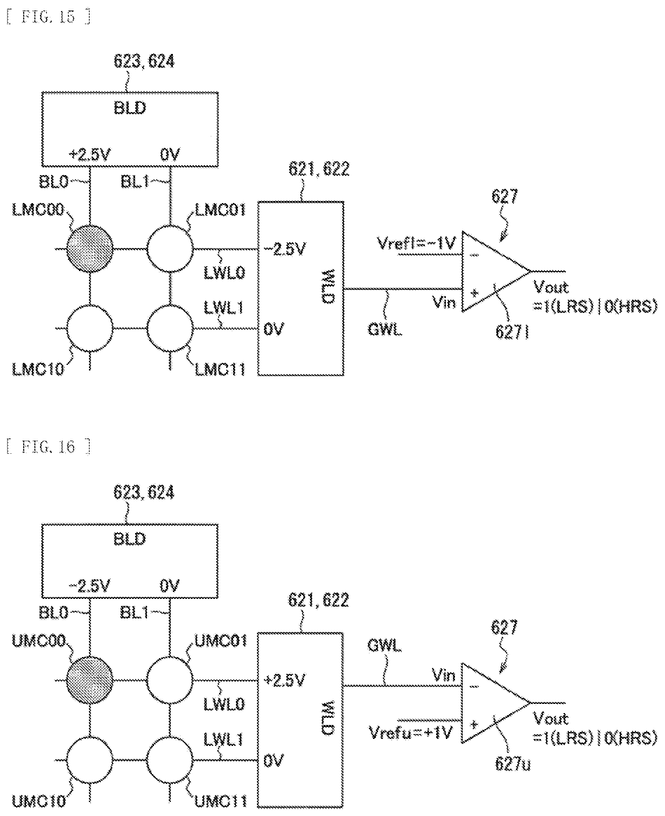

FIGS. 16, 18, and 20 schematically illustrate the upper word lines UWL0 and UWL1 and the bit lines BL0 and BL1. In addition, FIGS. 16, 18, and 20 schematically illustrate the upper memory cells UMC00 and UMC01 disposed at respective intersections of the upper word line UWL0 and the bit lines BL0 and BL1, and the upper memory cells UMC10 and UMC11 disposed at respective intersections of the upper word line UWL1 and the bit lines BL0 and BL1. In addition, FIGS. 16, 18, and 20 schematically illustrate the even number-side word line decoder 621, the odd number-side word line decoder 622, the even number-side bit line decoder 623, and the odd number-side bit line decoder 624. In addition, FIG. 16 illustrates an upper sense amplifier 627u provided in the data detector 627 coupled to the global word line GWL. In FIGS. 16 to 20, the odd number-side word line decoder 622 and the even number-side bit line decoder 623 are illustrated as common blocks.

First, description is given of the data read operation from the memory cell MC with reference to FIGS. 15 and 16. In FIG. 15, a memory cell as a data read target is the lower memory cell LMC00. In addition, in FIG. 16, a memory cell as a data read target is the upper memory cell UMC00.

In a case where data stored in the lower memory cell LMC is to be read out, as illustrated in FIG. 15, the negative-side read voltage Vr− (e.g., −2.5 V) is applied to the lower word line LWL0 coupled to the lower memory cell LMC00 as a read target, the blocking voltage Vinh_wl (e.g., 0 V) is applied to the lower word line LWL1 other than the lower word line LWL0, and the blocking voltage Vinh_bl (e.g., 0 V) is applied to all the bit lines BL0 and BL1. It is to be noted that in FIG. 15, a state in which the blocking voltage Vinh_bl is applied to the bit line BL0 is not illustrated.

The lower word line LWL0 (more specifically, a parasitic capacitance formed in the lower word line LWL0) is charged by the negative-side read voltage Vr−, and thereafter application of the negative-side read voltage Vr− to the lower word line LWL0 stops to change the lower word line LWL0 to a floating state. Next, as illustrated in FIG. 15, the positive-side read voltage Vr+ (e.g., +2.5 V) is applied to the bit line BL0. Thus, the read voltage Vr (e.g., +5V) that is a potential difference between a potential of the positive-side read voltage Vr+ and a potential of the negative-side read voltage V− is applied to the lower memory cell LMC00 as a read target.

In a case where the resistive state of the variable resistor element VR provided in the lower memory cell LMC00 as the read target is the low resistive state, the lower memory cell LMC00 snaps, which causes the parasitic capacitance formed in the lower word line LWL0 to be discharged. As a result, the potential of the lower word line LWL0 is increased to about 0 V.

In contrast, in a case where the resistive state of the variable resistor element VR provided in the lower memory cell LMC00 as the read target is the high resistive state, the lower memory cell LMC00 does not snap; therefore, only a slight leak current flows, and the parasitic capacitance formed in the lower word line LWL0 is hardly discharged. As a result, the potential of the lower word line LWL0 is kept at about the potential (e.g., −2.5 V) of the negative-side read voltage Vr−.

As illustrated in FIG. 15, the lower sense amplifier 627l includes, for example, an operational amplifier. The lower sense amplifier 627l functions as a comparator, and outputs a high-level voltage in a case where a voltage inputted to the non-inverting input terminal (+) is higher than a voltage inputted to the inverting input terminal (−). In contrast, the lower sense amplifier 627l outputs a low-level voltage in a case where the voltage inputted to the non-inverting input terminal (+) is lower than the voltage inputted to the inverting input terminal (−).

The inverting input terminal (−) of the lower sense amplifier 627l is coupled to an output terminal, from which the lower reference voltage Vrefl is outputted, of the reference voltage generator 533 provided in the voltage generator 516 (see FIG. 6). The non-inverting input terminal (+) of the lower sense amplifier 627l is coupled to the global word line GWL. In a case where the lower memory cell LMC00 is a read target, the lower word line LWL0 is coupled to the global word line GWL. Accordingly, the lower reference voltage Vrefl is inputted to the inverting input terminal (−) of the lower sense amplifier 627l, and the voltage of the lower word line LWL0 is inputted to the non-inverting input terminal (+) of the lower sense amplifier 627l through the global word line GWL.

In a case where the resistive state of the variable resistor element VR provided in the lower memory cell LMC00 is the low resistive state, the potential of the lower word line LWL0 is increased to higher than the negative-side read voltage Vr− to become higher (e.g., 0 V) than the lower reference voltage Vrefl (e.g., −1 V). Accordingly, the lower sense amplifier 627l outputs a high-level voltage.

In contrast, in a case where the resistive state of the variable resistor element VR provided in the lower memory cell LMC00 is the high resistive state, the potential of the lower word line LWL0 remains at substantially the same potential as the negative-side read voltage Vr−, and therefore becomes lower (e.g., −2.5 V) than the lower reference voltage Vrefl (e.g., −1 V). Accordingly, the lower sense amplifier 627l outputs a low-level voltage.

In a case where data stored in the upper memory cell UMC00 is to be read out, as illustrated in FIG. 16, the positive-side read voltage Vr+ (e.g., +2.5 V) is applied to the upper word line UWL0 coupled to the upper memory cell UMC00 as a read target, the blocking voltage Vinh_wu (e.g., 0 V) is applied to the upper word line UWL1 other than the upper word line UWL0, and the blocking voltage Vinh_bl (e.g., 0 V) is applied to all the bit lines BL0 and BL1. It is to be noted that in FIG. 16, a state in which the blocking voltage Vinh_bl is applied to the bit line BL0 is not illustrated.

The upper word line UWL0 (more specifically, a parasitic capacitance formed in the upper word line UWL0) is charged by the positive-side read voltage Vr+, and thereafter application of the positive-side read voltage Vr+ to the upper word line UWL0 stops to change the upper word line UWL0 to a floating state. Next, as illustrated in FIG. 16, the negative-side read voltage Vr− (e.g., −2.5 V) is applied to the bit line BL0. Thus, the read voltage Vr (e.g., +5 V) that is a potential difference between the potential of the positive-side read voltage Vr+ and the potential of the negative-side read voltage V− is applied to the upper memory cell UMC00 as a read target.

In a case where the resistive state of the variable resistor element VR provided in the upper memory cell UMC00 as the read target is the low resistive state, the upper memory cell UMC00 snaps, which causes the parasitic capacitance formed in the upper word line UWL0 to be discharged. As a result, the potential of the upper word line UWL0 is decreased to about 0 V.

In contrast, in a case where the resistive state of the variable resistor element VR provided in the upper memory cell UMC00 as the read target is the high resistive state, the upper memory cell UMC00 does not snap; therefore, only a slight leak current flows, and the parasitic capacitance formed in the upper word line UWL0 is hardly discharged. As a result, the potential of the upper word line UWL0 is kept at about the potential (e.g., +2.5 V) of the positive-side read voltage Vr+.

As illustrated in FIG. 16, the upper sense amplifier 627u includes, for example, an operational amplifier. The upper sense amplifier 627u functions as a comparator, and outputs a high-level voltage in a case where a voltage inputted to the non-inverting input terminal (+) is higher than a voltage inputted to the inverting input terminal (−). In contrast, the upper sense amplifier 627u outputs a low-level voltage in a case where the voltage inputted to the non-inverting input terminal (+) is lower than a voltage inputted to the inverting input terminal (−).

The non-inverting input terminal (+) of the lower sense amplifier 627l is coupled to the output terminal, from which the upper reference voltage Vrefu is outputted, of the reference voltage generator 533 provided in the voltage generator 516. The inverting input terminal (−) of the upper sense amplifier 627u is coupled to the global word line GWL. In a case where the upper memory cell UMC00 is a read target, the upper word line UWL0 is coupled to the global word line GWL. Accordingly, the upper reference voltage Vrefu is inputted to the non-inverting input terminal (+) of the upper sense amplifier 627u, and the voltage of the upper word line UWL0 is inputted to the inverting input terminal (−) of the upper sense amplifier 627u through the global word line GWL.

In a case where the resistive state of the variable resistor element VR provided in the upper memory cell UMC00 is the low resistive state, the potential of the upper word line UWL0 is decreased to lower than the positive-side read voltage Vr+ to become lower (e.g., 0 V) than the lower reference voltage Vrefl (e.g., +1 V). Accordingly, the lower sense amplifier 627l outputs a high-level voltage.

In contrast, in a case where the resistive state of the variable resistor element VR provided in the upper memory cell UMC00 is the high resistive state, the potential of the upper word line UWL0 remains at substantially the same potential as the positive-side read voltage Vr+, and therefore becomes higher (e.g., +2.5 V) than the upper reference voltage Vrefu (e.g., +1 V). Accordingly, the lower sense amplifier 627l outputs a low-level voltage.

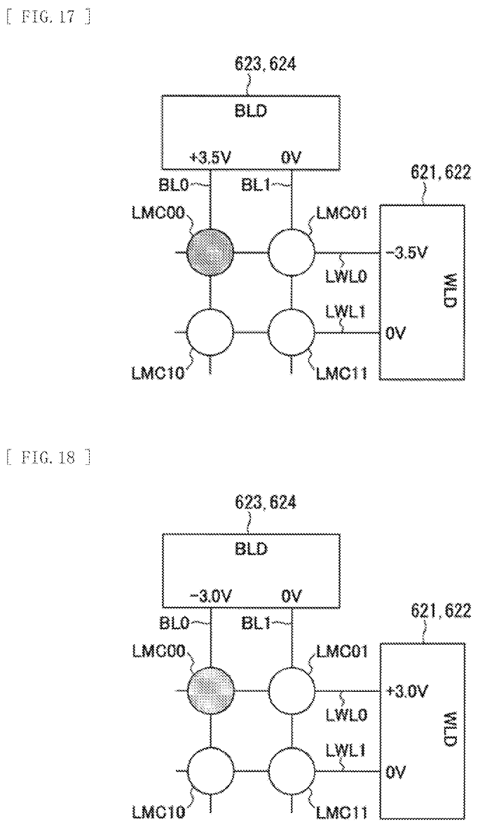

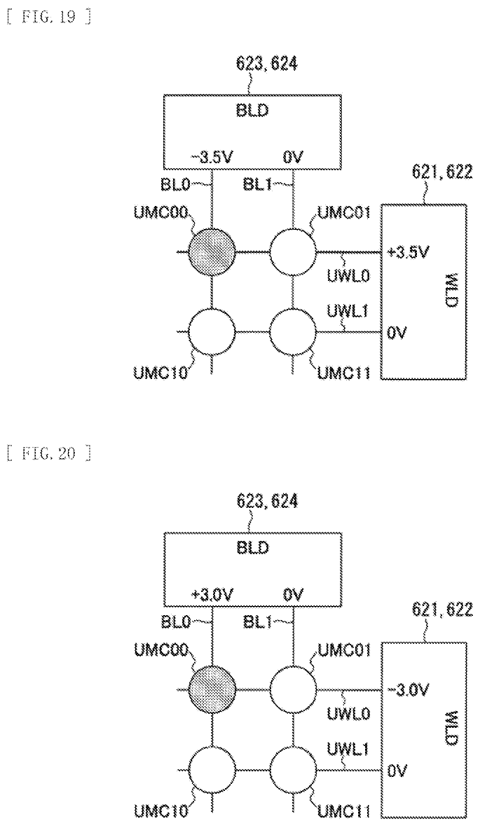

Next, description is given of the data write operation to the memory cell MC with reference to FIGS. 17 to 20. FIG. 17 illustrates the set operation on the lower memory cell LMC00 as a data write target. FIG. 18 illustrates the reset operation on the lower memory cell LMC00 as the data write target. FIG. 19 illustrates the set operation on the upper memory cell UMC00 as a data write target. FIG. 20 illustrates the reset operation on the upper memory cell UMC00 as the data write target.

As illustrated in FIG. 17, in a case where data of “1” is written to the lower memory cell LMC00 (that is, in a case of the set operation), the negative-side write voltage Vw− (e.g., −3.5 V) is applied to the lower word line LWL0 coupled to the lower memory cell LMC00 as a write target, and the positive-side write voltage Vw+ (e.g., +3.5 V) is applied to the bit line BL0. In addition, in a case where data of “1” is written to the lower memory cell LMC00, the blocking voltage Vinh_wu (e.g., 0 V) is applied to the lower word line LWL1 other than the lower word line LWL0, and blocking voltage Vinh_bl (e.g., 0 V) is applied to the bit line BL1 other than the bit line BL0. Thus, the lower memory cell LMC snaps in a state in which a voltage is higher on side of the variable resistor element VR than on side of the selector element SE. As described in detail later, the set operation is performed on the lower memory cell MC in which the variable resistor element VR is in the high resistive state. Accordingly, the variable resistor element VR of the lower memory cell LMC00 is changed from the high resistive state to the low resistive state.

As illustrated in FIG. 18, in a case where data of “0” is written to the lower memory cell LMC00 (that is, in a case of the reset operation), the positive-side write voltage Vw+ (e.g., +3.0 V) is applied to the lower word line LWL0 coupled to the lower memory cell LMC00 as the write target, and the positive-side write voltage Vw− (e.g., −3.0 V) is applied to the bit line BL0. In addition, in a case where data of “0” is written to the lower memory cell LMC00, the blocking voltage Vinh_wu (e.g., 0 V) is applied to the lower word line LWL1 other than the lower word line LWL0, and the blocking voltage Vinh_bl (e.g., 0 V) is applied to the bit line BL1 other than the bit line BL0. Thus, the lower memory cell LMC snaps in a state in the voltage is lower on side of the variable resistor element VR than on side of the selector element SE. As described in detail later, the reset operation is performed on the lower memory cell LMC in which the variable resistor element VR is in the low resistive state. Accordingly, the variable resistor element VR of the lower memory cell LMC00 is changed from the low resistive state to the high resistive state.

As illustrated in FIG. 19, in a case where data of “1” is written to the upper memory cell UMC00 (that is, in a case of the set operation), the positive-side write voltage Vw+ (e.g., +3.5 V) is applied to the upper word line UWL0 coupled to the upper memory cell UMC00 as a write target, and the negative-side write voltage Vw− (e.g., −3.5 V) is applied to the bit line BL0. In addition, in a case where data of “1” is written to the upper memory cell UMC00, the blocking voltage Vinh_wu (e.g., 0 V) is applied to the upper word line UWL1 other than the upper word line UWL0, and the blocking voltage Vinh_bl (e.g., 0 V) is applied to the bit line BL1 other than the bit line BL0. Thus, the lower memory cell LMC snaps in a state in which a voltage is higher on side of the variable resistor element VR than on side of the selector element SE. As described in detail later, the set operation is performed on the upper memory cell UMC in which the variable resistor element VR is in the high resistive state. Accordingly, the variable resistor element VR of the upper memory cell UMC00 is changed from the high resistive state to the low resistive state.

As illustrated in FIG. 20, in a case where data of “0” is written to the upper memory cell UMC00 (that is, in a case of the reset operation), the negative-side write voltage Vw− (e.g., −3.0 V) is applied to the upper word line UWL0 coupled to the upper memory cell UMC00 as the write target, the positive-side write voltage Vw+ (e.g., +3.0 V) is applied to the bit line BL0. In addition, in a case where data of “0” is written to the upper memory cell UMC00, the blocking voltage Vinh_wu (e.g., 0 V) is applied to the upper word line UWL1 other than the upper word line UWL0, and the blocking voltage Vinh_bl (e.g., 0 V) is applied to the bit line BL1 other than the bit line BL0. Thus, the upper memory cell UMC snaps in a state in which the voltage is lower on the side of the variable resistor element VR than on the side of the selector element SE. As described in detail later, the reset operation is performed on the upper memory cell UMC in which the variable resistor element VR is in the low resistive state. Accordingly, the variable resistor element VR of the upper memory cell UMC00 is changed from the low resistive state to the high resistive state.

Next, description is given of a series of processes in the data write operation with reference to FIG. 21. The series of processes in the data write operation include four processes including a preread process, a set operation process, a reset operation process, and a verifying operation process.

As illustrated in FIG. 21, as a first step of the series of processes of the data write operation, the preread process (preread) is executed. In the preread process, the present state (that is, data stored in the memory cell MC) of the variable resistor element VR provided in the memory cell MC as a write target is determined, and comparison between a value of the determined data and a value of data to be written is performed. In a case where the value (the present value) of the data stored in the memory cell MC is “0” (the variable resistor element VR is in the high resistive state) and the value of the data to be written is “1” (the variable resistor element VR is in the low resistive state), “1” is held by the set verification latch circuit (not illustrated) provided in the data latch unit 626 (see FIG. 12).

In contrast, in a case where the value (the present value) the data stored in the memory cell MC is “1” (the variable resistor element VR is in the low resistive state) and the value of the data to be written is “0” (the variable resistor element VR is in the high resistive state), “1” is held by the reset verification latch circuit (not illustrated) provided in the data latch unit 626 (see FIG. 12).

In addition, in a case where the value (the present value) of the data stored in the memory cell MC and the value of the data to be written are the same as each other, that is, in a case where the resistive state of the variable resistor element VR of the memory cell MC and the resistive state of the variable resistor element VR corresponding to the value of the data to be written are the same as each other, “0” is held by both the set verification latch circuit and the reset verification latch circuit.

As illustrated in FIG. 21, as a second step of the series of processes of the data write operation, the set operation process is executed as necessary. In the second step, in a case where “1” is held by the set verification latch circuit in the first step, the set operation process is executed as a write operation. As described above, in a case where the memory cell MC as the write target is the lower memory cell LMC, the positive-side write voltage Vw+ is applied to the bit line BL coupled to the lower memory cell LMC as the write target, and the negative-side write voltage Vw− is applied to the lower word line LWL coupled to the lower memory cell LMC as the write target.

In contrast, as described above, in a case where the memory cell MC as the write target is the upper memory cell UMC, the negative-side write voltage Vw− is applied to the bit line BL coupled to the upper memory cell UMC as the write target, and the positive-side write voltage Vw+ is applied to the upper word line UWL coupled to the upper memory cell UMC as the write target. Thus, the resistive state of the variable resistor element VR provided in the memory cell MC as the write target is changed from the high resistive state to the low resistive state.

In addition, in the second step, in a case where “0” is held by the set verification latch circuit, the set operation is not executed on the memory cell MC as the write target.

As illustrated in FIG. 21, as a third step of the series of processes of the data write operation, the reset operation process is executed as necessary. In the third step, in a case where “1” is held by the reset verification latch circuit in the first step, the reset operation process is executed as the write operation. As described above, in a case where the memory cell MC as the write target is the lower memory cell LMC, the negative-side write voltage Vw− is applied to the bit line BL coupled to the lower memory cell LMC as the write target, and the positive-side write voltage Vw+ is applied to the lower word line LWL coupled to the lower memory cell LMC as the write target.

In contrast, as described above, in a case where the memory cell MC as the write target is the upper memory cell UMC, the positive-side write voltage Vw+ is applied to the bit line BL coupled to the upper memory cell UMC as the write target, and the negative-side write voltage Vw− is applied to the upper word line UWL coupled to the upper memory cell UMC as the write target.

Ina addition, in the third step, in a case where “0” is held by the reset verification latch circuit, the reset operation is not executed on the memory cell MC as the write target.

As illustrated in FIG. 21, as a fourth step of the series of processes of the data write operation, the verifying operation process is executed as necessary. In the verifying operation process, whether or not target data has been written to the memory cell MC in the set operation process in the second step or the reset operation process in the third step is verified.

In the verifying operation process, a process similar to the data read operation described above is executed. In a case where the memory cell MC as the write target is the lower memory cell LMC, the process stops after the negative-side read voltage Vr− is applied to the lower word line LWL coupled to the lower memory cell LMC as the write target. Thereafter, the positive-side read voltage Vr+ is applied to the bit line BL coupled to the lower memory cell LMC as the write target, and a value of data held by the lower memory cell LMC as the write target is determined by the lower sense amplifier 627l (see FIG. 15). The determined value of the data is compared with a value of data to be written.

In contrast, in a case where the memory cell MC as the write target is the upper memory cell UMC, the process stops after the positive-side read voltage Vr+ is applied to the upper word line UWL coupled to the upper memory cell UMC as the write target. Thereafter, the negative-side read voltage Vr− is applied to the bit line BL coupled to the upper memory cell UMC as the write target, and a value of data held by the upper memory cell UMC as the write target is determined by the upper sense amplifier 627u (see FIG. 16). The determined value of the data is compared with a value of data to be written.

In a case where the determined value of the data and the value of the data to be written are the same as each other, it is determined that data writing succeeds. Accordingly, in a case where the data to be written is “1”, a value of “0” is held by the set verification latch circuit. In addition, in a case where the data to be written is “0”, a value of “0” is held by the reset verification latch circuit.

In contrast, in a case where the determined value of the data and the value of the data to be written are not the same as each other, the second to fourth steps are executed again, and are repeated until the determined value of the data and the value of the data to be written becomes the same as each other. Repeatedly executing the second to fourth steps in the memory chip 31 in such a manner is referred to as a “verification loop”.

In addition, in a case where “0” is held by both the set verification latch circuit and the reset verification latch circuit in the fourth step, neither the set operation nor the reset operation is executed on the memory cell MC as the write target; therefore, the verifying operation process is also not executed.

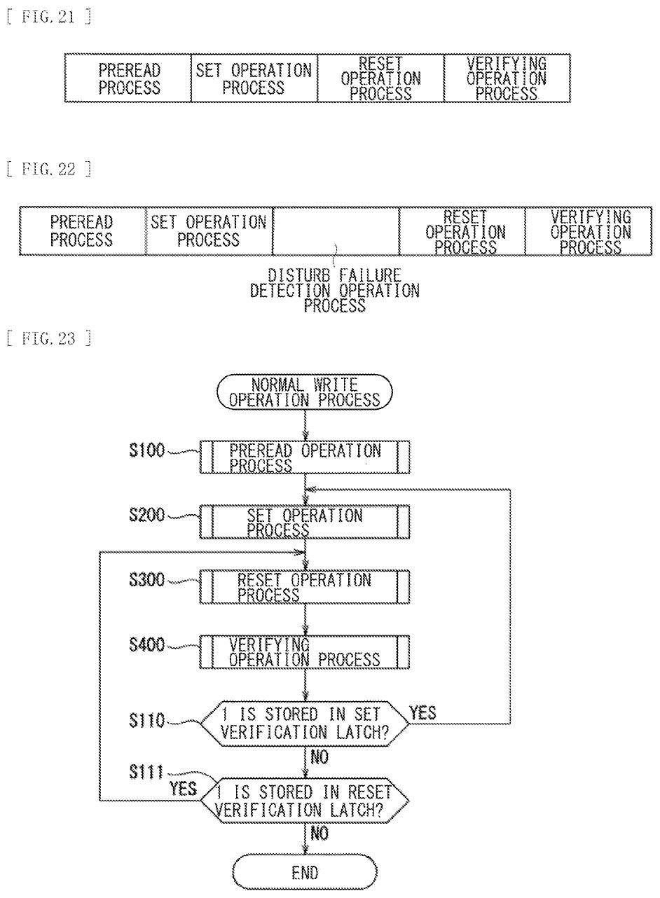

Next, description is given of a disturb failure and a disturb failure detection operation process in the memory chip according to the present embodiment with reference to FIGS. 22 to 30. “Memory Cell Failure Mode” in Table 1 indicates a type of a defect (failure) that occurs in a memory cell provided in the memory chip. “Read from Concerned Cell” in Table 1 indicates a state of the variable resistor element VR detected in a case where the read operation is executed on a memory cell in which a failure described in “Memory Cell Failure Mode” has occurred. “Rewrite to Concerned Cell” in Table 1 indicates whether or not it is possible to perform rewriting of data to the memory cell in which the failure described in “Memory Cell Failure Mode” has occurred. “After Rewrite” in Table 1 indicates a state of the memory cell in which the failure described in “Memory Cell Failure Mode” has occurred, after the rewrite operation is executed to the memory cell. “Read on Same WL or Same BL” in Table 1 indicates whether or not it is possible to execute the read operation on a memory cell coupled to the same word line or the same bit line as the memory cell in which the failure described in “Memory Cell Failure Mode” has occurred. “Rewrite on Same WL or Same BL” in Table 1 indicates whether or not it is possible to execute the rewrite operation on the memory cell coupled to the same word line or the same bit line as the memory cell in which the failure described in “Memory Cell Failure Mode” has occurred. “Main Cause” in Table 1 indicates a main cause of occurrence of the failure described in “Memory Cell Failure Mode”.

“Stuck-HRS” described in “Memory Cell Failure Mode” in Table 1 indicates a failure that the state of the variable resistor element VR is stuck or fixed at the high resistive state (HRS). “Stuck-LRS” described in “Memory Cell Failure Mode” in Table 1 indicates a failure that the state of the variable resistor element VR is stuck or fixed at the low resistive state (LRS). The stuck-HRS and the stuck-LRS are hard failures that occur due to deterioration over time, a wearout failure, or a stochastic failure.

“Recoverable Disturb Failure” described in “Memory Cell Failure Mode” in Table 1 indicates a state in which a disturb failure recoverable as a memory cell storing data of “0” has occurred. “Recovered Disturb Failure” described in “Memory Cell Failure Mode” in Table 1 indicates a state in which a disturb failure recovered as a memory cell storing data of “0” has occurred. “Unrecoverable Disturb Failure” described in “Memory Cell Failure Mode” in Table 1 indicates a state in which an unrecoverable disturb failure has occurred.

“HRS” described in “Read from Concerned Cell” indicates that the resistive state of the variable resistor element VR being the high resistive state is detected (that is, data of “0” is read out). “LRS” described in “Read from Concerned Cell” indicates that the resistive state of the variable resistor element VR being the low resistive state is detected (that is, data of “1” is read out).

“Not Possible” described in “Rewrite to Concerned Cell” in Table 1 indicates that rewriting of data to the memory cell is not possible, and “Possible” described in the column indicates that rewriting of data to the memory cell is possible.

“Possible” described in “Read on Same WL or Same BL” in Table 1 indicates that it is possible to execute the read operation on the memory cell coupled to the same word line as the memory cell in which the failure has occurred. “Not Possible” described in “Read on Same WL or Same BL” in Table 1 indicates that it is not possible to execute the read operation on the memory cell coupled to the same word line as the memory cell in which the failure has occurred. “Unstable” described in “Read on Same WL or Same BL” in Table 1 indicates that it may or may not be possible to execute the read operation on the memory cell coupled to the same word line as the memory cell in which the failure has occurred.

“Possible” described in “Rewrite on Same WL or Same BL” in Table 1 indicates that it is possible to execute the rewrite operation on the memory cell coupled to the same word line or the same bit line as the memory cell in which the failure has occurred. “Not Possible” described in “Rewrite on Same WL or Same BL” in Table 1 indicates that it is not possible to execute the rewrite operation on the memory cell coupled to the same word line or the same bit line as the memory cell in which the failure has occurred. “Unstable” described in “Rewrite on Same WL or Same BL” in Table 1 indicates that it may or may not be possible to execute the rewrite operation on the memory cell coupled to the same word line or the same bit line as the memory cell in which the failure has occurred.

TABLE 1

| | | | | | Read on | Rewrite | |
|---|---|---|---|---|---|---|---|
| | | Read from | Rewrite to | | Same | on Same | |
| | Memory Cell | Concerned | Concerned | After | WL or | WL or | |
| | Failure Mode | Cell | Cell | Rewrite | Same BL | Same BL | Main Cause |
| (1) | Stuck-HRS | HRS | Not | — | Possible | Possible | Wearout of VR |
| | | | Possible | | | | |
| (2) | Stuck-LRS | LRS | Not | — | Possible | Possible | Wearout of VR |
| | | | Possible | | | | |
| (3) | Recoverable | LRS | Possible | Become (4) | Possible | Unstable | Wearout of SE |
| | Disturb | | | | | | |
| | Failure | | | | | | |
| (4) | Recovered | HRS | Possible | Become (3) | Possible | Possible | Wearout of SE |
| | Disturb | | | | | | |
| | Failure | | | | | | |
| (5) | Unrecoverable | LRS | Not | — | Unstable | Unstable | Remarkable Wearout |
| | Disturb | | Possible | | | | of SE |
| | Failure | | | | | | Wearout of Both SE |
| | | | | | | | and VR |

As illustrated in Table 1, failures of “Stuck-HRS” and “Stuck-LRS” occur due to wearout of the variable resistor element VR as described in “Main Cause” respectively corresponding to “Stuck-HRS” and “Stuck-LRS” in the “Memory Cell Failure Mode”. Failures of “Recoverable Disturb Failure” and “Recovered Disturb Failure” occur due to wearout of the selector element SE as described in “Main Cause” respectively corresponding to “Recoverable Disturb Failure” and “Recovered Disturb Failure” in “Memory Cell Failure Mode”. A failure of “Unrecoverable Disturb Failure” occurs due to remarkable wearout of the selector element SE or wearout of both the selector element SE and the variable resistor element VR as described in “Main Cause” respectively corresponding to “Unrecoverable Disturb Failure” in “Memory Cell Failure Mode”.

Failures in a cross-point memory such as the memory cell MC may be classified into five failures illustrated in Table 1. Of the five failures, the recoverable disturb failure and the unrecoverable disturb failure affect the memory cells MC coupled to the same word line LW as the memory cell MC in which the failure has occurred. That is, in the recoverable disturb failure and the unrecoverable disturb failure, a failure in one memory cell MC impairs (disturbs) normal operations of other memory cells MC.

The recoverable disturb failure becomes a recovered disturb failure as illustrated by “Becomes (4)” in “After Write” in Table 1 by changing the resistive state of the variable resistor element VR provided in the memory cell MC to the high resistive state. Changing the resistive state of the variable resistor element VR to the high resistive state means rewriting data into “0”. Thus, the influence of the recovered disturb failure on the memory cell MC does not affect the memory cells MC coupled to the word line LW to which that memory cell MC is coupled.

An influence range of the disturb failure in one memory cell MC is the word line WL and the bit line BL to which the one memory cell MC is coupled, and it is not possible to use the memory cells MC coupled to that word line WL and that bit line BL. The disturb failure is a failure having a large influence range in such a manner. However, it is difficult to detect the disturb failure in a normal write operation and a normal read operation.

The memory chip 31 according to the present embodiment is therefore configured to be able to execute a disturb failure detection operation that allows for detection of the disturb failure. Furthermore, the memory chip 31 is configured to be able to change the memory cell MC in which the detected disturb failure has occurred into a state in which a recovered disturb failure has occurred.

As described with reference to FIGS. 15 to 20, the voltage generator 516 is configured to apply the disturb failure detection voltage Vd to the memory cell MC disposed at an intersection of a selected bit line selected from among the plurality of bit lines BLk and a selected word line selected from among the plurality of upper word lines UWLi and the plurality of lower word lines LWLj through the selected bit line and the selected word line. A voltage lower than the disturb failure detection voltage Vd is applied across the memory cells MC disposed at respective intersections of unselected bit lines, which are the plurality of bit lines other than the selected bit line, and unselected word lines, which are the plurality of word lines other than the selected word line.

In the data write operation to the memory cell MC and the data read operation from the memory cell MC, for example, a voltage equal to a half of a voltage to be applied to the memory cell MC as a data write target and a data read target is applied to a memory cell (hereinafter also referred to as a “semi-selected memory cell”) MC that is coupled to the word line WL to which the memory cell MC as the data write target and the data read target is coupled and is not the data write target and the data read target. In the data write operation to the memory cell MC and the data read operation from the memory cell MC, a highest voltage is applied to the memory cell MC in the set operation of the write operation, and for example, a voltage of +7 V is applied to the memory cell MC. In this case, a voltage of +3.5 V is applied to the semi-selected memory cell. A normal semi-selected memory cell does not snap even if the voltage of +3.5 V is applied to the normal semi-selected memory cell (see FIG. 14).

However, as illustrated in Table 1, wearout of the selector element SE that a main cause of the disturb failure results in a decrease in threshold voltage of the selector element SE. This shifts the entire current-volage characteristics of the memory cell MC illustrated in FIG. 14 to left side; therefore, the memory cell MC snaps by application of the voltage of +3.5 V.

In a case where the semi-selected memory cell snaps, it is not possible to apply a write voltage, which is to be applied in the set operation process, between the word line WL and the bit line BL to which the semi-selected memory cell is coupled. For this reason, it is not possible to normally make access to the memory cell MC as the data write target, thereby not making it possible to write data to the memory cell MC.

As described above, in a case where a disturb failure occurs, it is not possible to normally make access to the memory cell MC as the data write target or the data read target. However, as illustrated in Table 1, disturb failures include a recoverable disturb failure that is recoverable by rewriting data to change the variable resistor element VR to the high resistive state, and an unrecoverable disturb failure that is not recoverable because it is not possible to rewrite data. Accordingly, the memory chip 31 according to the present embodiment is able to determine whether or not a disturb failure has occurred in the memory cell MC and determine whether, in a case where a disturb failure has occurred, the disturb failure is a recoverable disturb failure or an unrecoverable disturb failure.

“Memory Cell Failure Mode” in Table 2 indicates the same contents as those of “Memory Cell Failure Mode” in Table 1. “Read, Preread, Verify” in Table 2 indicates the read operation, the preread operation, or the verifying operation. “Set” in Table 2 indicates the set operation in the data write operation. “Reset” in Table 2 indicates the reset operation in the data write operation. “Disturb Failure Detection” in Table 2 indicates a disturb detection operation.

“Normal HRS” described in “Memory Cell Failure Mode” in Table 2 indicates that the variable resistor element VR of a normal memory cell MC is in the high resistive state (HRS). “Normal LRS” described in “Memory Cell Failure Mode” in Table 2 indicates that the variable resistor element VR of the normal memory cell MC is in the low resistive state (LRS). “Normal HRS” and “Normal LRS” both indicate the state of the memory cell MC in which no disturb failure has occurred, but are described in “Memory Cell Failure Mode” in Table 2 for ease of understanding.

“Stuck-HRS”, “Stuck-LRS”, “Recoverable Disturb Failure”, “Recovered Disturb Failure”, and “Unrecoverable Disturb Failure” described in “Memory Cell Failure Mode” in Table 2 indicate the same contents as those of “Stuck-HRS”, “Stuck-LRS”, “Recoverable Disturb Failure”, “Recovered Disturb Failure”, and “Unrecoverable Disturb Failure” described in Table 1.

TABLE 2

| | | Read, | | | Disturb | |
|---|---|---|---|---|---|---|
| | Memory Cell | Preread, | | | Failure | |
| | Failure Mode | Verify | Set | Reset | Detection | Remarks |
| — | Normal HRS | HRS | Pass | Pass | Pass | |
| — | Normal LRS | LRS | Pass | Pass | Pass | |
| (A) | stuck-HRS | HRS | Fail | Pass | Pass | |
| (B) | stuck-LRS | LRS | Pass | Fail | Pass | |
| (C) | Recoverable | | | | | |
| | Disturb | LRS | Pass | Pass | Fail | |
| | Failure | | | | | |
| (D) | Recovered | HRS | Pass | Pass | Pass | Discriminate |
| | Disturb | | | | | from Normal |
| | Failure | | | | | HRS by Set and |
| | | | | | | Disturb Failure |
| | | | | | | Detection |
| (E) | Unrecoverable | LRS | Pass | Fail | Fail | |
| | Disturb | | | | | |
| | Failure | | | | | |

A lower limit value of a disturb failure detection voltage (one example of a specific voltage) Vd to be applied to the memory cell MC as the data write target in a disturb failure detection operation process is set to ½ of the highest voltage among voltages to be applied to the memory cell MC in the write operation, the preread operation, the read operation, and the verifying operation. Accordingly, a voltage equal to or higher than a voltage to be applied to the semi-selected memory cell in each of the write operation, the preread operation, and the verifying operation is applied to the memory cell MC as the data write target. In addition, an upper limit of the disturb failure detection voltage Vd is set to a volage lower than the read voltage Vr. This makes it possible to prevent data of the memory cell MC as the data write target from being read out in the disturb failure detection operation process.

As illustrated in Table 2, from the normal memory cell MC corresponding to “Normal HRS” in “Memory Cell Failure Mode”, data of “0” corresponding to the variable resistor element VR being in the high resistive state is read out in the preread operation, the read operation, and the verifying operation, and the set operation and the reset operation in the write operation are executed. Accordingly, the normal memory cell MC corresponding to “Normal HRS” is determined as “Pass” indicating that these operations have been normally executed. In addition, the normal memory cell MC corresponding to “Normal HRS” does not snap in the disturb failure detection operation, and is therefore determined as “Pass” indicating that no disturb failure has occurred.

As illustrated in Table 2, from the normal memory cell MC corresponding to “Normal LRS” in “Memory Cell Failure Mode”, data of “1” corresponding to the variable resistor element VR being in the low resistive state is read out in the preread operation, the read operation, and the verifying operation, and the set operation and the reset operation in the write operation are executed. Accordingly, the normal memory cell MC corresponding to “Normal LRS” is determined as “Pass” indicating that these operations have been normally executed. In addition, the normal memory cell MC corresponding to “Normal LRS” does not snap in the disturb failure detection operation, and is therefore determined as “Pass” indicating that no disturb failure has occurred.

As illustrated in Table 2, from the memory cell MC in which a failure corresponding to “Stuck-HRS in “Memory Cell Failure Mode” has occurred, data of “0” corresponding to the variable resistor element VR being in the high resistive state is read out in the preread operation, the read operation, and the verifying operation, and the reset operation in the write operation is executed. Accordingly, the memory cell MC in which the failure corresponding to “Stuck-HRS” has occurred is determined as “Pass” indicating that these operations have been normally executed. In addition, the memory cell MC corresponding to “Stuck-HRS” does not snap in the disturb failure detection operation, and is therefore determined as “Pass” indicating that no disturb failure has occurred. However, it is not possible to change the variable resistor element VR stuck at the high resistive state to the low resistive state; therefore, the memory cell MC in which the failure corresponding to “Stuck-HRS” has occurred is determined as “Fail” indicating that it is not possible to execute the set operation in the write operation.

As illustrated in Table 2, from the memory cell MC in which a failure corresponding to “Stuck-LRS” in “Memory Cell Failure Mode” has occurred, data of “1” corresponding to the variable resistor element VR being in the low resistive state is read out in the preread operation, the read operation, and the verifying operation, and the set operation in the write operation is executed. Accordingly, the memory cell MC in which the failure corresponding to “Stuck-LRS” has occurred is determined as “Pass” indicating that these operations have been normally executed. In addition, the memory cell MC in which the failure corresponding to “Stuck-LRS” has occurred does not snap in the disturb failure detection operation, and is therefore determined as “Pass” indicating that no disturb failure has occurred. However, it is not possible to change the variable resistor element VR stuck at the low resistive state to the high resistive state; therefore, the memory cell MC in which the failure corresponding to “Stuck-LRS” has occurred is determined as “Fail” indicating that it is not possible to execute the reset operation in the write operation.

As illustrated in Table 2, from the memory cell MC in which a failure corresponding to “Recoverable Disturb Failure” in “Memory Cell Failure Mode” has occurred, data of “0” corresponding to the variable resistor element VR being in the high resistive state is read out in the preread operation, the read operation, and the verifying operation, and the set operation and the reset operation in the write operation are executed. Accordingly, the memory cell MC in which the failure corresponding to “Stuck-LRS” has occurred is determined as “Pass” indicating that these operations have been normally executed. However, the memory cell MC in which the failure corresponding to “Recoverable Disturb Failure” has occurred snaps by the disturb failure detection voltage, and is therefore determined as “Fail” indicating that a disturb failure has occurred.

The reset operation is executed, thereby changing the memory cell MC in which the failure corresponding to “Recoverable Disturb Failure” in “Memory Cell Failure Mode” has occurred into the memory cell MC in which a failure corresponding to “Recovered Disturb Failure” in “Memory Cell Failure Mode” has occurred (see “Become (4)” in “After Rewrite” illustrated in Table 1). Accordingly, as illustrated in Table 2, from the memory cell MC in which the failure corresponding to “Recovered Disturb Failure” has occurred, data of “0” corresponding to the variable resistor element VR being in the high resistive state is read out in the preread operation, the read operation, and the verifying operation. In addition, the memory cell MC in which the failure corresponding to “Recovered Disturb Failure” has occurred is able to normally execute the set operation and the reset operation, and is therefore determined as “Pass”.

In addition, the memory cell MC in which the failure corresponding to “Recovered Disturb Failure” has occurred does not snap even if the disturb failure detection voltage is applied thereto. Accordingly, the memory cell MC in which the failure corresponding to “Recovered Disturb Failure” has occurred is determined as “Pass” indicating that no disturb failure has occurred. However, in the memory cell MC in which the failure corresponding to “Recovered Disturb Failure” has occurred, the variable resistor element VR is changed to the low resistive state by executing the set operation, which causes the memory cell MC to become a memory cell in which a failure corresponding to “Recoverable Disturb Failure” has occurred (see “Become (3)” in “After Rewrite” described in Table 1).

As illustrated in Table 2, from the memory cell MC in which a failure corresponding to “Unrecoverable Disturb Failure” in “Memory Cell Failure Mode” has occurred, data of “1” corresponding to the variable resistor element VR being in the low resistive state is read out in the preread operation, the read operation, and the verifying operation. In addition, the memory cell MC in which the failure corresponding to “Unrecoverable Disturb Failure” in “Memory Cell Failure Mode” has occurred is not able to perform the data rewrite operation (see “Not Possible” in Rewrite to Concerned Cell”). Accordingly, the memory cell MC in which the failure corresponding to “Unrecoverable Disturb Failure” in “Memory Cell Failure Mode” has occurred is determined as “Pass” indicating that the set operation has been normally executed, but is determined as “Fail” indicating that the reset operation is not normally executed. In addition, the memory cell MC in which the failure corresponding to “Unrecoverable Disturb Failure” in “Memory Cell Failure Mode” has occurred snaps by the disturb failure detection voltage, and is therefore determined as “Fail” indicating that the disturb failure has occurred.

As illustrated in Table 2, it is possible to determine, by the set operation and the disturb failure detection operation, whether or not the memory cell MC is in “Normal “HRS” or whether or not a disturb failure has occurred.

The memory chip 31 according to the present embodiment is configured to execute the disturb failure detection operation process in addition to a series of processes of the normal write operation (hereinafter is also referred to as a “normal write operation process”) illustrated in FIG. 21. In the present embodiment, the disturb failure detection operation process is executed between the set operation process and the reset operation process.

As illustrated in FIG. 22, in the write operation with the disturb failure detection operation process (hereinafter also referred to as a “write operation with disturb failure detection”), the disturb failure detection operation process is executed after the set operation process of the normal write operation process. In the disturb failure detection operation process, for example, a voltage equal to ½ of the set voltage Vset to be applied to the memory cell MC in the set operation in a write voltage is applied to the memory cell MC as a write target to detect whether or not that memory cell MC snaps. The memory cell MC snapping means that the memory cell MC is turned to an on state. In a case where the memory cell MC snaps, it is possible to determine that a recoverable disturb failure or an unrecoverable disturb failure has occurred in that memory cell MC (Fail).

As illustrated in FIG. 22, in the write operation process with disturb failure detection, the reset operation is executed on the memory cell MC that is determined as Fail in the disturb failure detection operation process. In a case where the variable resistor element VR provided in the memory cell MC is changed to the high resistive state by the reset operation (in a case of being determined as “Pass”), that memory cell MC is determined as a memory cell in which a “Recovered Disturb Failure” has occurred. In contrast, in a case where the variable resistor element VR provided in the memory cell MC is not changed to the high resistive state by the reset operation (in a case of being determined as “Fail”), the memory cell MC is determined as a memory cell in which an “Unrecoverable Disturb Failure” has occurred.

Thus, executing the disturb failure detection operation process for each set operation process makes it possible to detect that the memory cell MC in which the variable resistor element VR is in the high resistive state and a recovered disturb failure has occurred, and that is mixed with the normal memory cells MC is changed by the set operation into the memory cell MC in which a recoverable disturb failure has occurred. Furthermore, executing the reset operation process after the disturb failure detection operation process makes it possible to recover the memory cell MC in which a recoverable disturb failure has occurred to the memory cell MC in which a recovered disturb failure has occurred.

It is possible to detect a recovered disturb failure only after executing the set operation process to change the recovered disturb failure into a recoverable disturb failure, and the recovered disturb failure becomes a cause of a disturb failure after executing the set operation process. Furthermore, the selector element SE generally has drift characteristics in which a threshold voltage Vt increases in a case where the selector element SE is left in a non-selected state. For this reason, after a lapse of a predetermined time after the set operation process is executed on the memory cell MC, in the selector element SE, a threshold voltage Vth is increased by the drift characteristics, which causes a possibility that no snap occurs in the disturb failure detection operation process and a disturb failure that is supposed to be detected is not detected. Accordingly, there is a possibility that the memory cell MC operates as if a disturb failure has occurred even though no disturb failure has occurred. Thus, after a lapse of a predetermined time after the set operation process is executed on the memory cell MC, it may not be possible to perform disturb failure detection with high accuracy. The memory chip 31 according to the present embodiment is configured to execute a disturb failure detection process operation immediately after the set operation process in order to reliably detect the recoverable disturb failure and to minimize a probability of erroneous detection of occurrence of the disturb failure. As a result, the memory chip 31 is able to reduce erroneous detection of the disturb failure by minimizing the influence of the drift characteristics of the selection element SE. Furthermore, the memory chip 31 is able to recover the memory cell MC in which the recoverable disturb failure has occurred to the memory cell MC in which the recovered disturb failure has occurred in the reset operation process to be executed immediately after the disturb failure detection operation process. Furthermore, the memory chip 31 is able to prevent the normal memory cell MC from being identified as the memory cell MC in which the recovered disturb failure has occurred.

Next, description is given of examples of flows of the normal write operation process and the write operation process with disturb failure detection in the memory chip according to the present embodiment with reference to FIGS. 23 to 29 while referring to FIGS. 3, 4, 6, and 12. First, description is given of the normal write operation process in the memory chip 31 (see FIG. 3) according to the present embodiment with reference to FIGS. 23 to 27.

Upon start of the normal write operation process, the microcontroller 53 (see FIG. 4) first stores data of “0” in the set verification latch circuit, the reset verification latch circuit, and the disturb failure detection latch circuit (all of which are not illustrated, and are described in detail later) provided in the data latch unit 626. The memory chip 31 is configured to prevent a malfunction in the normal write operation process by storing data of “0” in these latch circuits provided in the data latch unit 626 upon start of the normal write operation process. The disturb failure detection latch circuit is not used in the normal write operation process, but storing data of “0” upon start of the normal write operation process makes it possible to reliably prevent a malfunction in the normal write operation process.

### (Step S100)

The microcontroller 53 (see FIG. 4) controls the data latch unit 626 to store data of “0” in the set verification latch circuit, the reset verification latch circuit, and the disturb failure detection latch circuit, and then executes the preread operation process on the memory cell MC as a write target in step S100, and shifts to a process in step S200. In the step S100, the microcontroller 53 executes the preread operation process on the memory cell MC as a write target in each of the plurality of memory tiles 61 included in the memory bank 42 provided with that microcontroller 53. The preread operation process is described in detail later.

### (Step S200)

The microcontroller 53 executes the set operation process on the memory cell MC as the write target in the step S200, and shifts to a process in step S300. In the step S200, the microcontroller 53 executes, as necessary, the set operation process on the memory cell MC on which the preread operation process has been executed in the step S100. The set operation process is described in detail later.

### (Step S300)

The microcontroller 53 executes the reset operation process on the memory cell MC as the write target, and shifts to a process in step S400. In the step S300, the microcontroller 53 executes, as necessary, the reset operation process on the memory cell MC on which the set operation process has been executed in the step S200. The reset operation process is described in detail later.

### (Step S400)

The microcontroller 53 executes the verifying operation process on the memory cell MC as the write target in the step S400, and shifts to a process in step S110. In the step S400, the microcontroller 53 executes the verifying operation process on the memory cell MC on which the set operation process has been executed in the step S200 or the memory cell MC on which the reset operation process has been executed in the step S300. The verifying operation process is described in detail later.

### (Step S110)

The microcontroller 53 determines whether or not data of “1” is stored (held) in the set verification latch circuit (not illustrated) provided in the data latch unit 626 (see FIG. 12) in the step S110. In a case where the microcontroller 53 determines that data of “1” is stored (held) in the set verification latch circuit (not illustrated) (YES), the microcontroller 53 returns to the process in the step S200. In contrast, in a case where the microcontroller 53 determines that data of “1” is not stored (held) (that is, data of “0” is stored (held)) in the set verification latch circuit (NO), the microcontroller 53 shifts to a process in step S111.

A case where data of “1” is stored in the set verification latch circuit indicates that data read out from the memory cell MC as the write target in the verifying operation operation (the step S400) and data written in the set operation (the step S200) do not match each other (details are described later). Accordingly, the microcontroller 53 returns to the process in the step S200 to execute the set operation again. In contrast, a case where the data of “1” is not stored in the set verification latch circuit (that is, data of “0” is stored) indicates that data read out from the memory cell MC as the write target in the verifying operation operation (the step S400) and data written in the set operation (the step S200) match each other, or that the set operation is not executed on the memory cell MC as the write target in the set operation (the step S200) (details are described later). Accordingly, the microcontroller 53 shifts to step S111. Repeat of processes in “the step S110→the step S200→the step S300→the step S400→the step S110” corresponds to a verification loop.

### (Step S111)

The microcontroller 53 determines whether or not data of “1” is stored (held) in the reset verification latch circuit (not illustrated) provided in the data latch unit 622 in the step S111. In a case where the microcontroller 53 determines that the data of “1” is stored (held) in the reset verification latch circuit (not illustrated) (YES), the microcontroller 53 returns to the process in the step S300. In contrast, in a case where the microcontroller 53 determines that the data of “1” is not stored (held) (that is, “0” is stored (held)) in the reset verification latch circuit (NO), the normal write operation ends.

A case where the data of “1” is stored in the reset verification latch circuit indicates that data read out from the memory ell MC as the write target in the verifying operation operation (the step S400) and data written in the reset operation (the step S300) do not match each other. (details are described later). Accordingly, the microcontroller 53 returns to the process in the step S300 to execute the reset operation again. In contrast, a case where the data of “1” is not stored in the reset verification latch circuit (that is, data of “0” is stored) indicates that data read out from the memory cell MC as the write target in the verifying operation operation (the step S400) and data written in the reset operation (the step S300) match each other, or that the reset operation has not been executed on the memory cell MC as the write target in the reset operation (the step S300) (details are described later). Accordingly, the microcontroller 53 ends the normal write operation. Repeat of the processes in “the step S111→the step S300→the step S400→the step S110→the step S111” corresponds to a verification loop.

Thus, the microcontroller 53 controls determination whether or not the selector element SE of the memory cell MC to which the disturb failure detection voltage is applied is turned to the on state.

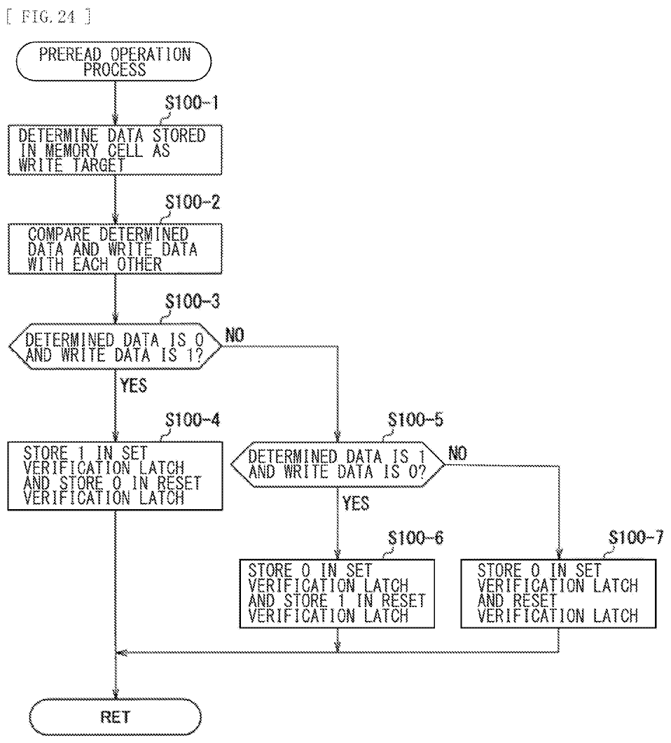

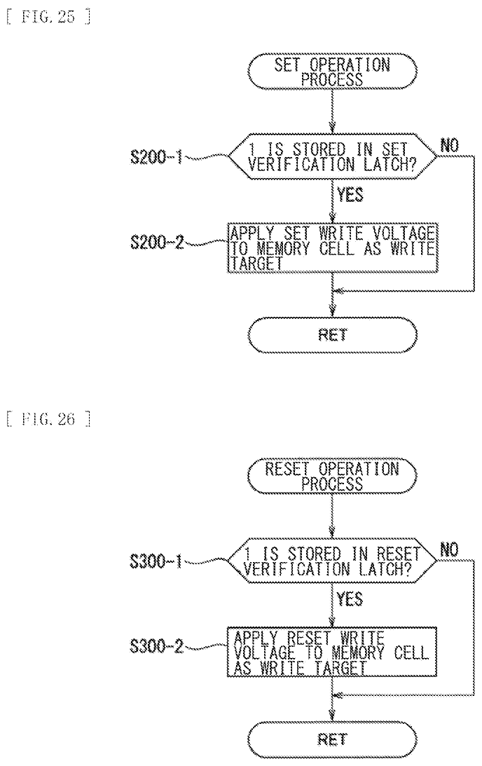

Next, description is given of an example of a flow of specific processes of the preread operation process (the step S100) in the normal write operation process with reference to FIG. 24.

### (Step S100-1)

As illustrated in FIG. 24, upon start of the preread operation process, the microcontroller 53 first determines data stored in the memory cell MC as the write target in step S100-1, and shifts to a process in step S100-2. The microcontroller 53 controls the tile circuit 612 (see FIG. 12) to determine the data stored in the memory cell MC as the write target by the data read operation described with reference to FIGS. 15 and 16. The microcontroller 53 controls the data latch unit 626 to store (hold) the determined data (determined data) in the read data latch circuit (not illustrated) provided in the data latch unit 626.

### (Step S100-2)

The microcontroller 53 compares the determined data and write data with each other in the step S100-2, and shifts to a process in step S100-3. More specifically, the microcontroller 53 compares the determined data stored in the read data latch circuit and the write data WDATA stored in the write data latch circuit (not illustrated) provided in the data latch unit 626 with each other.

### (Step S100-3)

In the step S100-3, the microcontroller 53 determines whether or not the determined data is 0 and the write data WDATA is 1 in a data comparison result in the step S100-2. In a case where the microcontroller 53 determines that the determined data is 0 and the write data WDATA is 1 (YES), the microcontroller 53 shifts to a process in step S100-4. In contrast, in a case where the microcontroller 53 determines that the determined data is 0 and the write data WDATA is not 1 (NO), the microcontroller 53 shifts to a process in step S100-5.

### (Step S100-4)

In the step S100-4, the microcontroller 53 controls the data latch unit 626 to store (hold) “1” in the set verification latch circuit and store (hold) “0” in the reset verification latch circuit, and ends the preread operation process.

### (Step S100-5)

In the step S100-5, the microcontroller 53 determines whether or not the determined data is 1 and the write data WDATA is 0 in a data comparison result in the step S100-2. In a case where the microcontroller 53 determines that the determined data is 1 and the write data WDATA is 0 (YES), the microcontroller 53 shifts to a process in step S100-6. In contrast, in a case where the microcontroller 53 determines that the determined data is 1 and the write data WDATA is not 0 (NO), the microcontroller shifts to a process in step S100-7.

### (Step S100-6)

In the step S100-6, the microcontroller 53 controls the data latch unit 626 to store (hold) “0” in the set verification latch circuit and store (hold) “1” in the reset verification latch circuit, and ends the preread operation process.

### (Step S100-7)

In the step S100-7, the microcontroller 53 controls the data latch unit 626 to store (hold) “0” in the set verification latch circuit and store (hold) “0” in the reset verification latch circuit, and ends the preread operation process.

Next, description is given of an example of a flow of specific processes of the set operation process (the step S200) in the normal write operation process with reference to FIG. 25.

### (Step S200-1)

As illustrated in FIG. 25, upon start of the set operation process, in step S200-1, the microcontroller 53 first determines whether or not “1” is stored (held) in the set verification latch circuit. In a case where the microcontroller 53 determines that “1” is stored (held) in the set verification latch circuit (YES), the microcontroller 53 shifts to a process in step S200-2. In contrast, in a case where the microcontroller 53 determines that “1” is not stored (held) (“0” is stored (held)) in the set verification latch circuit (NO), the microcontroller 53 ends the set operation process.

### (Step S200-2)

In the step S200-2, the microcontroller 53 applies a set write voltage (the set voltage Vset) to the memory cell MC as the write target, and ends the set operation process. That is, the microcontroller 53 changes the resistive state of the variable resistor element VR provided in the memory cell MC as the write target from the high resistive state to the low resistive state to write data of “1” to that memory cell MC.

A state in which the set verification latch circuit stores “1” indicates that it is necessary to rewrite data of “0” stored in the memory cell MC as the write target into the write data WDATA of “1”. In contrast, a state in which the set verification latch circuit stores “0” indicates that it is not necessary to execute the write operation on the memory cell MC as the write target. Accordingly, in a case where “1” is stored in the set verification latch circuit in the step S200-1, the microcontroller 53 shifts to the process in the step S200-2, and rewrites data of the memory cell MC as the write target. In contrast, in a case where “0” is stored in the set verification latch circuit in the step S200-1, the microcontroller 53 ends the set operation process without performing the data write process on the memory cell MC as the write target in the set operation process.

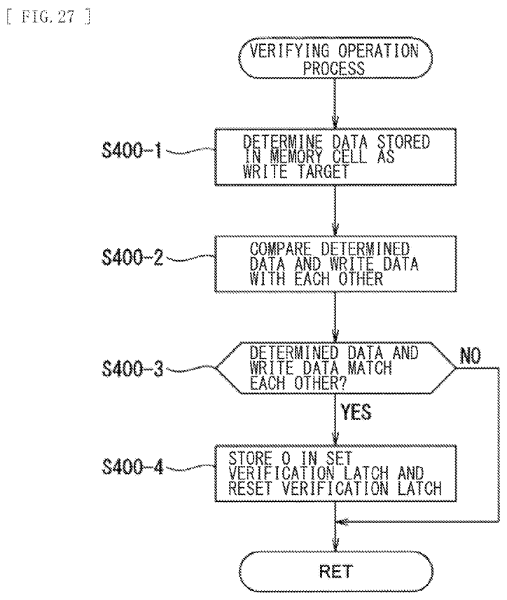

Next, description is given of an example of a flow of specific processes of the reset operation process (the step S300) in the normal write operation process with reference to FIG. 26.

### (Step S300-1)

As illustrated in FIG. 26, upon start of the reset operation process, in the step S300-1, the microcontroller 53 first determines whether or not “1” is stored (held) in the reset verification latch circuit. In a case where the microcontroller 53 determines that “1” is stored (held) in the reset verification latch circuit (YES), the microcontroller 53 shifts to a process in step S300-2. In contrast, in a case where the microcontroller 53 determines that “1” is not stored (held) (“0” is stored (held)) in the reset verification latch circuit (NO), the microcontroller 53 ends the reset operation process.

### (Step S300-2)

The microcontroller 53 applies a reset write voltage (the reset voltage Vrst) to the memory cell MC as the write target in the step S300-2, and ends the reset operation. That is, the microcontroller 53 changes the resistive state of the variable resistor element VR provided in the memory cell MC as the write target from the low resistive state to the high resistive state to write data of “0” to that memory cell MC.

A state in which the reset verification latch circuit stores “1” indicates that it is necessary to rewrite data of “1” stored in the memory cell MC as the write target into the write data WDATA of “0”. In contrast, a state in which the reset verification latch circuit stores “0” indicates that it is not necessary to execute the write operation on the memory cell MC as the write target. Accordingly, in a case where “1” is stored in the reset verification latch circuit in the step S300-1, the microcontroller 53 shifts to the process in the step S300-2, and rewrite data of the memory cell MC as the write target. In contrast, in a case where “0” is stored in the reset verification latch circuit in the step S300-1, the microcontroller 53 ends the reset operation process without performing the data write process on the memory cell MC as the write target in the set operation process.

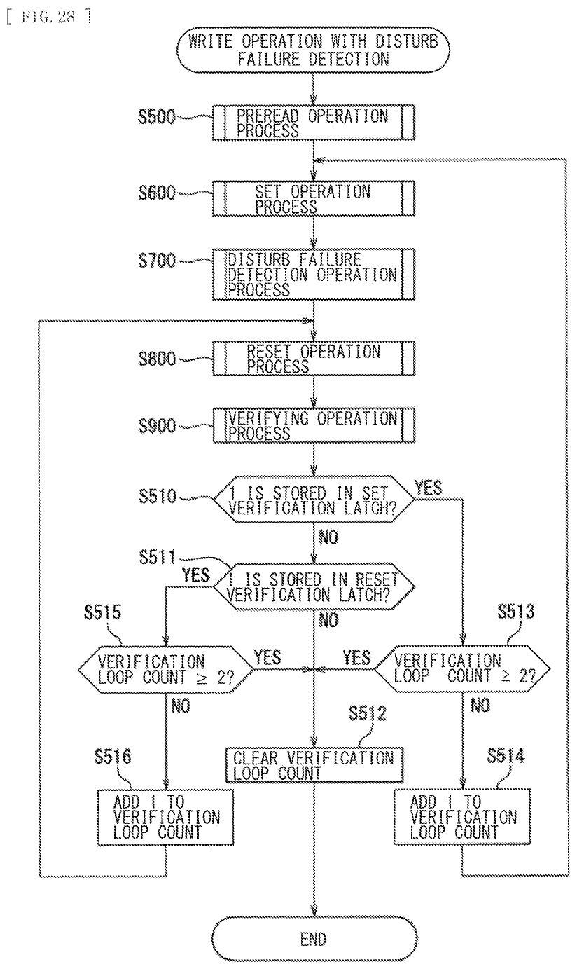

Next, description is given of an example of a flow of specific processes of the verifying operation process (the step S400) in the normal write operation process with reference to FIG. 27.

### (Step S400-1)

As illustrated in FIG. 27, upon start of the verifying operation process, in step S400-1, the microcontroller 53 first determines data stored in the memory cell MC as the write target, and shifts to a process in step S400-2. The microcontroller 53 controls the tile circuit 612 to determine data stored in the memory cell MC as the write target by the data read operation described with reference to FIGS. 15 and 16. The microcontroller 53 controls the data latch unit 626 to store (hold) determined data (determined data) in the read data latch circuit provided in the data latch unit 626.

### (Step S400-2)

The microcontroller 53 compares the determined data and write data with each other in the step S400-2, and shifts to a process in step S400-3. More specifically, the microcontroller 53 compares the determined data stored in the read data latch circuit and the write data WDATA stored in the write data latch circuit with each other.

### (Step S400-3)

In the step S400-3, the microcontroller 53 determines whether or not the determined data and the write data WDATA match each other, on the basis of a data comparison result in the step S400-2. In a case where the microcontroller 53 determines that the determined data and the write data WDATA match each other (YES), the microcontroller 53 shifts to a process in step S400-4. In contrast, in a case where the microcontroller 53 determines that the determined data and the write data WDATA do not match each other (NO), the microcontroller 53 ends the verifying operation process.

### (Step S400-4)

In the step S400-4, the microcontroller 53 controls the data latch unit 626 to store (hold) “0” in each of the set verification latch circuit and the reset verification latch circuit, and ends the verifying operation process.

Thus, in a case where the determined data and the write data WDATA match each other, the microcontroller 53 indicates that writing of data of “1” in the set operation process or writing of data of “0” in the reset operation process has succeeded. Accordingly, the microcontroller 53 determines that it is not necessary to perform the set operation or the reset operation again, and stores (holds) “0” in each of the set verification latch circuit and the reset verification latch circuit. In contrast, in a case where the determined data and the write data WDATA do not match each other, the microcontroller 53 indicates that writing of data of “1” in the set operation process or writing of data of “0” in the reset operation process has failed. Accordingly, the microcontroller 53 determines that it is necessary to perform the set operation or the reset operation again, and ends the verifying operation process without changing data stored in the set verification latch circuit and the reset verification latch circuit.

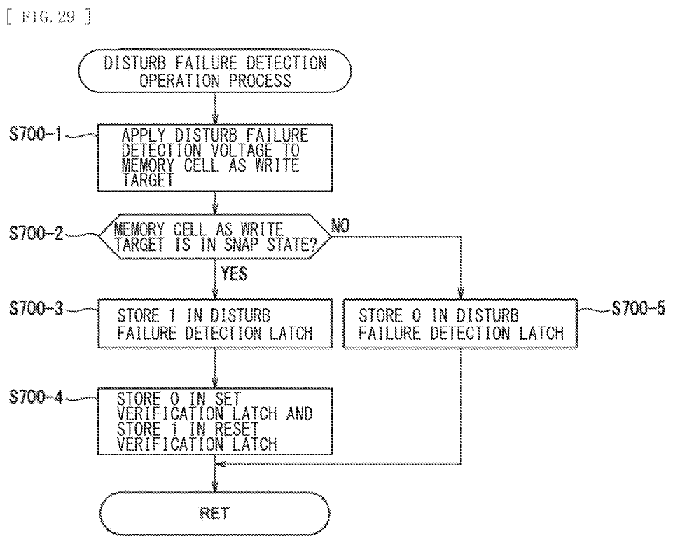

Next, description is given of the write operation process with disturb failure detection in the memory chip 31 according to the present embodiment with reference to FIGS. 28 and 29 while referring to FIGS. 3, 4, 6, 12, and 25 to 27.

Upon start of the write operation process with disturb failure detection, the microcontroller 53 (see FIG. 4) first stores data of “0” in the set verification latch circuit (not illustrated), the reset verification latch circuit (not illustrated), and the disturb failure detection latch circuit (not illustrated, and to be described in detail later) provided in the data latch unit 626. The memory chip 31 is configured to prevent a malfunction in the write operation process with disturb failure detection by storing data of “0” in these latch circuits provided in the data latch unit 626 upon start of the write operation process with disturb failure detection.

### (Step S500)

The microcontroller 53 controls the data latch unit 626 to store data of “0” in the set verification latch circuit, the reset verification latch circuit, and the disturb failure detection latch circuit, and then executes the preread operation process on the memory cell MC as the write target in step S500, and shifts to a process in step S600. In the step S500, the microcontroller 53 executes the preread operation process on the memory cell MC as the write target in each of the plurality of memory tiles 61 included in the memory bank 42 provided with that microcontroller 53. The preread operation process in the write operation process with disturb failure detection is the same as the preread operation process in the normal write operation process, and specific processes thereof are therefore omitted.

### (Step S600)

The microcontroller 53 executes the set operation process on the memory cell MC as the write target in the step S600, and shifts to a process in step S700. In the step S600, the microcontroller 53 executes, as necessary, the set operation process on the memory cell MC on which the preread operation process has been executed in the step S500. The set operation process in the write operation process with disturb failure detection is the same as the set operation process in the normal write operation process, and specific processes thereof are therefore omitted.

### (Step S700)

The microcontroller 53 executes the disturb failure detection operation process on the memory cell MC as the write target in the step S700, and shifts to a process in step S800. The disturb failure detection operation process is described in detail later.

### (Step S800)

The microcontroller 53 executes the reset operation process on the memory cell MC as the write target in the step S800, and shifts to a process in step S900. In the step S800, the microcontroller 53 executes the reset operation process on the memory cell MC on which the disturb failure detection operation process has been executed in the step S700. The reset operation process in the write operation process with disturb failure detection is the same as the reset operation process in the normal write operation process, and specific processes thereof are therefore omitted.

### (Step S900)

The microcontroller 53 executes the verifying operation process on the memory cell MC as the write target in the step S900, and shifts to a process in step S510. In the step S900, the microcontroller 53 executes the verifying operation process on the memory cell MC on which the disturb failure detection operation process has been executed in the step S700. The verifying operation process in the write operation process with disturb failure detection is the same as the verifying operation process in the normal write operation process, and specific processes thereof are therefore omitted.

### (Step S510)

In the step S510, the microcontroller 53 determines whether or not data of “1” is stored (held) in the set verification latch circuit. In a case where the microcontroller 53 determines that data of “1” is stored (held) in the set verification latch circuit (YES), the microcontroller 53 shifts to a process in step S512. In contrast, in a case where the microcontroller 53 determines that data of “1” is not stored (held) (that is, data of “0” is stored (held)) in the set verification latch circuit (NO), the microcontroller 53 shifts to a process in step S511.

A case where data of “1” is stored in the set verification latch circuit indicates that data read out from the memory cell MC as the write target in the verifying operation operation (the step S900) and data written in the set operation (the step S600) do not match each other. Furthermore, a case where data of “1” is stored in the set verification latch circuit indicates that no disturb failure has occurred in the memory cell MC as the write target (to be described in detail later). Accordingly, the microcontroller 53 shifts to the process in the step S512. In contrast, a case where data of “1” is not stored (that is, data of “0” is stored) in the set verification latch circuit indicates that data read out from the memory cell MC as the write target in the verifying operation (the step S900) and data written in the set operation (the step S600) match each other, or that the set operation has not been executed on the memory cell MC as the write target in the set operation (the step S600). Furthermore, a case where data of “1” is not stored (that is, data of “0” is stored) in the set verification latch circuit indicates that a disturb failure has occurred in the memory cell MC as the write target (to be described in detail later). Accordingly, the microcontroller 53 shifts to the process in the step S511. Repeat of the processes in “the step S510→step S513 (to be described in detail later)→step S514 (to be described in detail later)→the step S600→the step S700→the step S800→the step S900→the step S510” corresponds to a verification loop.

### (Step S511)

In the step S511, the microcontroller 53 determines whether or not data of “1” is stored (held) in the reset verification latch circuit. In a case where the microcontroller 53 determines that data of “1” is stored (held) in the reset verification latch circuit (YES), the microcontroller 53 shifts to a process in step S515. In contrast, in a case where the microcontroller 53 determines that data of “1” is not stored (held) (that is, data of “0” is stored (held)) in the reset verification latch circuit (NO), the microcontroller 53 shifts to a process in step S512.

A case where data of “1” is stored in the reset verification latch circuit indicates that data read out from the memory cell MC as the write target in the verifying operation operation (the step S900) and data written in the reset operation (the step S800) do not match each other. Furthermore, a case where data of “1” is stored in the reset verification latch circuit indicates that a disturb failure has occurred in the memory cell MC as the write target (to be described in detail later). Accordingly, the microcontroller 53 returns to the process in the step S800 to execute the reset operation again. In contrast, a case where data of “1” is not stored (that is, data of “0” is stored) in the reset verification latch circuit indicates that data read out from the memory cell MC as the write target in the verifying operation operation (the step S900) and data written in the reset operation (the step S800) match each other, or that the reset operation has not been executed on the memory cell MC as the write target in the reset operation (the step S800). Furthermore, a case where data of “0” is stored in the reset verification latch circuit indicates that no disturb failure has occurred in the memory cell MC as the write target (to be described in detail later). Accordingly, the microcontroller 53 ends the write operation with disturb failure detection. Repeat of the processes in “the step S511→the step S515→the step S516→the step S800→the step S900→the step S510→the step S511” corresponds to a verification loop.

### (Step S512)

In the step S512, the microcontroller 53 clears the present verification loop count (to be described in detail later) stored in a predetermined storage region, that is, sets that count to “0”, and ends the write operation with disturb failure detection. The present verification loop count may be 0; however, the microcontroller 53 is configured to clear the present verification loop count in the step S512 to prevent a malfunction in the write operation process with disturb failure detection.

### (Step S513)

In the step S512, the microcontroller 53 determines whether or not the verification loop count is two or more. In a case where the microcontroller 53 determines that the verification loop count is two or more (YES), the microcontroller 53 shifts to the process in the step S512. In contrast, in a case where the microcontroller 53 determines that the verification loop count is not two or more (that is, less than two) (NO), the microcontroller 53 shifts to the process in the step S514. The microcontroller 53 is configured to specify an upper limit (two in the present embodiment) of the verification loop count to prevent the verification loop starting from the step S510 from becoming a infinite loop in a case where a hard failure has occurred in the memory cell MC. Accordingly, in a case where the verification loop count does not reach the upper limit, the microcontroller 53 shifts to the process in the step S514 in which the verification loop continues. In contrast, in a case where the verification loop count reaches the upper limit, the microcontroller 53 shifts to the process in the step S512 to end the write operation with disturb failure detection.

### (Step S514)

The microcontroller 53 adds “1” to the present verification loop count stored in the predetermined storage region in the step S514, and returns to the process in the step S600. Thus, the verification loop starting from the step S510 continues.

### (Step S515)

In the step S515, the microcontroller 53 determines whether or not the verification loop count is two or more. In a case where the microcontroller 53 determines that the verification loop count is two or more and the verification loop count reaches the upper limit (YES), the microcontroller 53 shifts to a process in step S516. In contrast, in a case where the microcontroller 53 determines that the verification loop count is not two or more (that is, less than two) and the verification loop count does not reach the upper limit (NO), the microcontroller 53 shifts to the process in the step S512. Thus, the microcontroller 53 is configured to specify the upper limit (two in the present embodiment) of the verification loop count to prevent the verification loop starting from the step S511 from becoming an infinite loop in a case where a hard failure has occurred in the memory cell MC.

### (Step S516)

In the step S516, the microcontroller 53 adds “1” to the present verification loop count stored in the predetermined storage region, and returns to the process in the step S800. Thus, the verification loop starting from the step S511 continues.

Next, description is given of an example of a flow of specific processes of the disturb failure detection operation process (the step S700) in the write operation process with disturb failure detection with reference to FIG. 29.

### (Step S700-1)

As illustrated in FIG. 29, upon start of the disturb failure detection operation process, the microcontroller 53 first applies the disturb failure detection voltage Vd to the memory cell MC as the write target in step S700-1, and shifts to a process in step S700-2. The microcontroller 53 controls the tile circuit 612 to apply the disturb failure detection voltage Vd to the memory cell MC as the write target.

### (Step S700-2)

In the step S700-2, the microcontroller 53 determines whether or not the memory cell MC as the write target is changed to a snap state. In a case where the microcontroller 53 determines that the memory cell MC as the write target is changed to the snap state (YES), the microcontroller 53 shifts to a process in step S700-3. In contrast, in a case where the microcontroller 53 determines that the memory cell MC as the write target is not changed to the snap state (NO), the microcontroller 53 shifts to a process in step S700-5.

For example, detecting a voltage of the word line WL coupled to the memory cell MC as the write target by the upper sense amplifier 627u or the lower sense amplifier 627l (see FIGS. 15 and 16) provided in the data detector 627 (see FIG. 12) makes it possible to determine whether or not the memory cell MC as the write target is changed to the snap state. For example, in a case where the write target is the upper memory cell UMC, the upper memory cell UMC snaps, which decreases the voltage of the upper word line UWL. The voltage of the upper word line UWL is higher than the upper reference voltage Vrefu before the upper memory cell UMC snaps, and is lower than the upper reference voltage Vrefu after the upper memory cell UMC snaps. Accordingly, it is possible for the microcontroller 53 to determine that the upper memory cell UMC has snapped in a case where the upper sense amplifier 627u outputs a low-level voltage.

In contrast, in a case where the write target is the lower memory cell LMC, the lower memory cell LMC snaps, which increases the voltage of the lower word line LWL. The voltage of the lower word line LWL is lower than the lower reference voltage Vrefl before the lower memory cell LMC snaps, and higher than the lower reference voltage Vrefl after the lower memory cell LMC snaps. Accordingly, it is possible for the microcontroller 53 to determine that the lower memory cell UMC has snapped in a case where the lower sense amplifier 627l outputs a high-level voltage.

### (Step S700-3)

In the step S700-3, the microcontroller 53 stores (holds) data of “1” in the disturb failure detection latch circuit (not illustrated) provided in the data latch unit 626, and shifts to a process in step S700-4. The disturb failure detection latch circuit is configured to store data of “1” in a case where a disturb failure has occurred in the memory cell MC.

### (Step S700-4)

In the step S700-4, the microcontroller 53 controls the data latch unit 626 to store (hold) data of “0” in the set verification latch circuit and store (hold) data of “1” in the reset verification latch circuit, and ends the write operation process with disturb failure detection. The memory chip 31 stores data of “0” in the set verification latch circuit in the step S700-4, which makes it possible to prevent unexpected data rewriting (set operation) to the memory cell MC in which a disturb failure has occurred. In addition, the memory chip 31 stores data of “1” in the reset verification latch circuit in the step S700-4, thereby executing, on a disturb failure memory cell, a reset operation process similar to the reset operation process on the normal memory cell in accordance with a process flow illustrated in FIG. 26 in the next reset operation process (the reset operation process in the verification loop starting from YES in the step S511 illustrated in FIG. 28).

### (Step S700-5)

In the step S700-5, the microcontroller 53 stores (holds) data of “0” in the recoverable disturb failure detection latch circuit, and ends the write operation process with disturb failure detection.

The data latch unit 626 of the memory tile 61 includes an OR circuit (not illustrated) to which an output signal (1 bit) of the reset verification latch circuit and an output signal (1 bit) of the set verification latch circuit are inputted. The microcontroller 53 obtains an output signal of the OR circuit that is a high-level signal as a write failure signal (1 bit). In contrast, the microcontroller 53 obtains an output signal of the OR circuit that is a low-level signal as a write success signal (1 bit). The memory bank 42 includes a counter circuit (not illustrated) that adds signals (a total of 256 signals in the present embodiment) outputted from the respective memory tiles 61. The counter circuit is configured to output a signal of 4 bits of which an upper limit value is “1111”, and is provided in the microcontroller 53, for example.

The signal of 4 bits outputted from the counter circuit is the number of fail bits (“Fail Bit Number” to be described in Table 3, and corresponds to one piece of memory cell information (see FIG. 6) inputted to the memory access control unit 511 through the signal input/output unit 523. The memory access control unit 511 records the inputted signal of 4 bits on the mode register 514 (see FIG. 6). The memory chip 31 according to the present embodiment includes sixteen memory banks 42. Accordingly, the mode register 514 has a storage region for 64 bits (=4 bits×16) for storing the number of fail bits. The microcontroller 53 is configured to count the number of fail bits with the counter circuit in both cases of the normal write operation process and the write operation process with disturb failure detection.

Furthermore, the data latch unit 626 of the memory tile 61 includes an AND circuit (not illustrated) to which an output signal (1 bit) of the reset verification latch circuit and an output signal (1 bit) of the disturb failure detection latch circuit are inputted. In the write operation process with disturb failure detection, only in the memory tile 61 including the memory cell MC in which an unrecoverable disturb failure (Unrecoverable Disturb: UD) has occurred, the output signal of the disturb failure detection latch circuit becomes a high level (1), and the output signal of the reset verification latch circuit becomes the high level (1). Accordingly, the AND circuit provided in the data latch unit 626 outputs an output signal (1 bit) of which the signal level is the high level in a case where an unrecoverable disturb failure has occurred. In contrast, the AND circuit outputs an output signal (1 bit) of which the signal level is a low level in a case where no unrecoverable disturb failure has occurred. This makes it possible for the microcontroller 53 to obtain a signal having a different signal level (hereinafter referred to as a “UD signal”) outputted from the AND circuit depending on presence or absence of occurrence of an unrecoverable disturb failure. Accordingly, in a case where the variable resistor element VR of the memory cell MC to which the reset voltage Vrst is applied after the disturb failure detection voltage Vd is applied is in the low resistive state, the microcontroller 53 is configured to determine that that memory cell MC is the memory cell MC in which an unrecoverable disturb failure has occurred.

The memory bank 42 includes an OR circuit to which UD signals (a total of 256 signals in the present embodiment) outputted from the respective memory tiles 61 are inputted. The OR circuit is configured to combine a plurality of (a total of 256 in the present embodiment) UD signals into a signal of one bit, and is provided in the microcontroller 53, for example.

The OR circuit to which the UD signals are inputted outputs a high-level signal in a case where at least one high-level UD signal is included. Including at least one high-level UD signal means that there is at least one memory tile 61 including the memory cell MC in which an unrecoverable disturb failure has occurred. In contrast, the OR circuit outputs a low-level signal in a case where all UD signals have the low level. All the UD signal having the low level means that there is no memory tile 61 including the memory cell MC in which an unrecoverable disturb failure has occurred. The signal of 1 bit outputted from the OR circuit corresponds to one piece of memory cell information inputted to the memory access control unit 511 through the signal input/output unit 523. The memory access control unit 511 records the inputted signal of 1 bit on the mode register 514. The memory chip 31 according to the present embodiment includes sixteen memory banks 42. Accordingly, the mode register 514 includes a storage region for 16 bits (=1 bit×16) for storing signals outputted from the OR circuits to which the UD signals are inputted.

A disturb failure detected in the write operation process with disturb failure detection is transmitted as a set of information with the memory cell MC in which the disturb failure has occurred, the word line WL and the bit line BL to which that memory cell MC is coupled, and the type of the disturb failure to, for example, the memory access control unit 511 (see FIG. 6), and is stored in the mode register 514 (see FIG. 6). The memory access control unit 511 obtains the one set of information stored in the mode register 514 on the basis of a request from the memory controller 11, and transmits the one set of information to the memory controller 11 through the signal input/output unit 521.

The memory chip 31 decides which one of the normal write operation process and the write operation process with disturb failure detection is to be executed, on the basis of a command inputted from the memory controller 11 (see FIG. 1). Table 3 illustrates examples of commands to be transmitted from the memory controller 11 to the memory chip 31.

TABLE 3

| | | Bank | WL & BL | | | |
|---|---|---|---|---|---|---|
| Command | IF | Address | Address | Data | Data | |
| Type | Command | Input | Input | Input | Output | Description |
| Read Type | Read1 | Valid | Valid | n/a | Page Data | Normal Read (Default read voltage is |
| | | | | | | used) |
| | Read2 | Valid | Valid | n/a | Page Data | Read voltage variable Read |
| | Read3 | Valid | Valid | n/a | Page Data | Disturb detection-specific command |
| | | | | | | (disturb cell outputs “1”) |
| Write Type | Write1 | Valid | Valid | Page | n/a | Normal Write, internally include |
| | | | | Data | | Preread, formation of mask by |
| | | | | (32 B) | | comparison with write data, |
| | | | | | | application of write pulse, verify and |
| | | | | | | read after write |
| | Write2 | Valid | Valid | Page | n/a | Write equivalent to Write1 + Disturb |
| | | | | Data | | detection + Reset of Disturb cell |
| | | | | (32 B) | | |
| | Refresh1 | Valid | Valid | Page | n/a | Temporarily change all LRS cells into |
| | | | | Data | | HRS, and then write input data |
| | | | | (32 B) | | |
| | Refresh2 | Valid | Valid | Page | n/a | Temporarily change all HRS cells into |
| | | | | Data | | LRS, and then write input data |
| | | | | (32 B) | | |
| | Fill0 | Valid | Valid | n/a | n/a | Write “All 0” without data input |
| | Fill1 | Valid | Valid | n/a | n/a | Write “All 1” without data input |
| Other Type | Mask | Valid | n/a | Mask | n/a | Bias application is blocked at position |
| | | | | Data | | of bit being “1” in Mask Data upon |
| | | | | (32 B) | | issue of Read/Write-based command |
| | | | | | | subsequent to this command |
| | MR Read | Valid | n/a | n/a | Fail + UD | Notification of Write Type CMD |
| | | | | | 4 bit + 1 bit | execution result (Write Fail bit number |
| | | | | | | 4 bit + presence or absence of |
| | | | | | | occurrence of UD 1 bit) |
| | | | | | | Note that presence or absence of |
| | | | | | | occurrence of UD is valid only in |
| | | | | | | Write2 |

As illustrated in Table 3, in the present embodiment, in case where a command “Write1” in “Write Type” described in “Command Type” is inputted from the memory controller 11 to the memory access control unit 511, the memory access control unit 511 gives an instruction for the normal write operation process to the microcontroller 53. This causes the microcontroller 53 to execute the normal write operation process. In contrast, in a case where a command “Write2” in “Write Type” described in “Command Type” is inputted from the memory controller 11 to the memory access control unit 511, the memory access control unit 511 gives an instruction for the write operation process with disturb failure detection to the microcontroller 53. This causes the microcontroller 53 to execute the write operation process with disturb failure detection.

In a case where a write command (e.g., a command “Write2”) including information that gives an instruction to write data to the memory cell MC including the variable resistor element VR that is reversibly changeable between the low resistive state and the high resistive state and the selector element SE that has current-voltage characteristics (one example of nonlinear current-voltage characteristics) of diode characteristics and is coupled in series to the variable resistor element VR, and the write data WDATA to be written to the memory cell MC are inputted from the memory controller 11 (one example of outside), the microcontroller 53 that controls the memory cell MC executes the set operation process (the step S600) (one example of a first voltage application process) in which the set voltage (one example of a first voltage) Vset in the write operation to be applied to the memory cell MC in a case where the variable resistor element VR is changed to the low resistive state is applied to the memory cell MC. After application of the set voltage Vset, the microcontroller 53 executes the disturb failure detection operation process (the step S700) (one example of a specific voltage application process) in which the disturb failure detection voltage (one example of a specific voltage) Vd that is equal to or higher than a half of the set voltage Vset and lower than the read voltage (one example of a second voltage) Vr to be applied to the memory cell MC in a case where the resistive state of the variable resistor element VR is detected is applied to the memory cell MC. In addition, after application of the disturb failure detection voltage Vd, the microcontroller 53 executes the reset operation process (the step S800) (one example of a third voltage application process) in which the reset voltage (one example of a third voltage) Vrst to be applied to the memory cell MC in a case where the variable resistor element VR is changed to the high resistive state is applied to the memory cell MC.

In a case where the write command (e.g., the command “Write2”) including information that gives an instruction to write data to the memory cell MC, and the write data WDATA to be written to the memory cell MC are inputted from the memory controller 11 in such a manner, the microcontroller 53 is configured to be able to execute the set operation process (the step S600) in which the set voltage Vset is applied to the memory cell MC, the disturb failure detection operation process (the step S700) in which the disturb failure detection voltage Vd is applied to the memory cell MC after application of the set voltage Vset, and the reset operation process (the step S800) in which the reset voltage Vrst to be applied to the memory cell MC in a case where the variable resistor element VR is changed to the high resistive state is applied to the memory cell MC after application of the disturb failure detection voltage Vd.

The microcontroller 53 executes the preread process (the step S500) in which data stored in the memory cell MC is read out in advance before the set operation process. In a case where the determined data (one example of read data) read out in the preread process is data corresponding to the resistive state of the variable resistor element VR being the low resistive state (a flow from the step S100-5 to the step S100-6 or the step S100-7), the microcontroller 53 is configured not to apply the set voltage Vset to the memory cell MC in the set operation process (NO in the step S200-1). In a case where the read data read out in the preread process (the step S500) is data corresponding to the resistive state of the variable resistor element VR being the high resistive state (a flow from the step S100-3 to the step S100-4), the microcontroller 53 is configured not to apply the reset voltage Vrst to the memory cell MC in the reset operation process (NO in the step S300-1).

It is desirable that the semiconductor storage device 2 have, as an IF command set that is issued by the memory controller 11 and acceptable by the memory chip 31, a command “Read3” (see Table 3) to perform the disturb failure detection operation process and output a result thereof as data with the same page size (e.g., 32 bytes) as normal read, in addition to a normal read command “Read1” (see Table 3). In contents of output data of 32 bytes, a bit corresponding to the tile circuit 612 in which a disturb failure is detected is “1”, and a bit corresponding to the tile circuit 612 in which no disturb failure is detected is “0”.

The memory controller 11 is able to detect a disturb failure by issuing the command “Read3” as a background process on a regular basis to make the rounds of all regions where user data is stored in a fixed time.

The memory controller 11 writes “0” to a bit where a disturb failure is detected with use of the command “Write1” or a command “Fill0” (see Table 3), which makes it possible to further classify the disturb failure into a recovered disturb failure in a case where writing to that bit succeeds and an unrecoverable disturb failure in a case where writing to that bit fails.

The memory controller 11 is able to record, as management information, information about which address an unrecoverable disturb failure or a recovered disturb failure is included at, on the basis of results of the rounds and classification described above.

Furthermore, it is desirable that the semiconductor storage device 2 have, as an IF command set, a write command “Write2” including the write operation process with the disturb failure detection operation process to perform automatic recovery, in addition to a normal write command “Write1” not including the disturb failure detection process.

The memory controller 11 receives a write command from the host computer 3 and refers to disturb failure management information, and may perform the write operation with use of the command “Write2” in place of the command “Write1” in a case where a recovered disturb failure is included at a write destination address, or there is a possibility that the recovered disturb failure is included at the write destination address. Accordingly, even if “1” is written to the memory cell in which a recovered disturb failure has occurred and the recovered disturb failure is changed into an recoverable disturb failure, the recoverable disturb failure is changed back into the recovered disturb failure by the disturb failure detection operation process, the reset operation process, and the verifying operation process included in the command “Write2”, which makes it possible to prevent a defective bit from causing an error in other memory cells MC that share the bit line BL and the word line WL with the defective bit.

The memory controller 11 is able to read out a result of the command “Write2” from the memory chip 31 by a command “Mode Register Read” (“MR Read” illustrated in Table 3). For the result of the command “Write2”, information indicating occurrence of an unrecoverable disturb failure is returned by 1 bit in addition to the number of write errors. For the number of write errors, the number of bits in which a verify error has occurred among 32 bytes is returned by 4 bits. Note that in a case where an error has occurred in 15 bits or more, binary numbers “1111” indicating “15” in decimal are returned. Information indicating occurrence of an unrecoverable disturb failure is information indicating that a disturb failure is detected in 32 bytes by the disturb failure detection operation process and there are 1 bit or more of memory cells determined, by the verifying operation process, that even if the reset voltage is applied in a read operation process, reset is not possible. Here, the verify error indicates that writing of data fails. Accordingly, the “number of bits in which a verify error has occurred among 32 bytes” indicates the number of memory tiles 61 including a memory cell to which writing of data fails among 256 memory tiles 61 provided in one memory bank 42. This makes it possible for the memory controller 11 to update disturb failure management information.

As described above, according to the memory chip and the method of manufacturing the memory chip, it is possible to detect a disturb failure.

The present disclosure are not limited to the embodiment described above, and may be modified in a variety of ways.

In the embodiment described above, as the variable resistor element, a bipolar element that is set to the high resistive state and the low resistive state by switching the polarity of an applied voltage is used; however, the present disclosure is not limited thereto. Even if a memory chip includes, as the variable resistor element, a unipolar element that is set to the high resistive state and the low resistive state by controlling a voltage value of an applied voltage and voltage application time without switching the polarity of the applied voltage, similar effects are achievable.

The memory chip according to the embodiment described above may be configured to limit the verification loop count in the normal write operation process similarly to the write operation process with disturb failure detection. This makes it possible to prevent the verification loop even in the normal write operation process from becoming a infinite loop in a case where a hard failure has occurred.

The memory chip according to the embodiment described above includes the positive-side read voltage regulator 551 that generates the positive-side read voltage Vr+ and the positive-side disturb failure detection voltage Vd+ and the negative-side read voltage regulator 571 that generates the negative-side read voltage Vr− and the negative-side disturb failure detection voltage Vd−; however, the present disclosure is not limited thereto. For example, the memory chip may be configured to generate respective voltages by individual regulators such as a regulator that generates the positive-side read voltage Vr+, a regulator that generates the positive-side disturb failure detection voltage Vd+, a regulator that generates the negative-side read voltage Vr−, and a regulator that generates the negative-side disturb failure detection voltage Vd−. In addition, one of the positive-side read voltage regulator and the negative-side read voltage regulator may be configured to individually generate respective voltages.

The present disclosure has been described above with reference to underlying technologies, the embodiments, and the modification examples thereof, but the present disclosure are not limited to the embodiments and the like described above, and may be modified in a variety of ways. It is to be noted that the effects described herein are merely illustrative. The effects of the present disclosure are not limited to the effects described herein. The present disclosure may have effects other than the effects described herein.

In addition, the present disclosure may have the following configurations.
(1)
   A memory chip including:
   a memory cell including a variable resistor element and a switching element, the variable resistor element reversibly changeable between a low resistive state and a high resistive state, and the switching element having nonlinear current-voltage characteristics and being coupled in series to the variable resistor element;
   a voltage generator that generates a first voltage to be applied to the memory cell in a case where the variable resistor element is changed to the low resistive state, and generates a second voltage to be applied to the memory cell in a case where a resistive state of the variable resistor element is detected, and a specific voltage that is equal to or higher than a half of the first voltage and lower than the second voltage; and
   a control unit that controls the memory cell.
(2)
   The memory chip according to (1), in which the control unit controls determination whether or not the switching element of the memory cell to which the specific voltage is applied is turned to an on state.
(3)
   The memory chip according to (1) or (2), in which
   the voltage generator includes a digital-analog converter that generates the second voltage and the specific voltage, and
   the digital-analog converter includes
   a first selection unit that selects the second voltage from among a plurality of analog voltages, and
   a second selection unit that selects the specific voltage from among the plurality of analog voltages.
(4)
   The memory chip according to (3), in which the digital-analog converter includes a third selection unit that selects one of the second voltage and the specific voltage.
(5)
   The memory chip according to (4), in which the voltage generator includes an output unit that outputs, to the memory cell, a voltage inputted from the third selection unit.
(6)
   The memory chip according to any one of (1) to (5), in which
   in a case where a write command including information that gives an instruction to write data to the memory cell, and write data to be written to the memory cell are inputted from outside, the control unit is configured to be able to execute
   a first voltage application process in which the first voltage is applied to the memory cell,
   a specific voltage application process in which after the first volage is applied, the specific voltage is applied to the memory cell, and
   a third voltage application process in which after the specific voltage is applied, a third voltage to be applied to the memory cell in a case where the variable resistor element is changed to the high resistive state is applied to the memory cell.
(7)
   The memory chip according to (6), in which in a case where the variable resistor element of the memory cell to which the third voltage is applied after the specific voltage is applied is in the low resistive state, the control unit determines that the memory cell is a memory cell in which an unrecoverable disturb failure has occurred.
(8)
   The memory chip according to any one of (1) to (7), including:
   a plurality of first lines provided in parallel with each other; and
   a plurality of second lines provided in parallel with each other, and disposed to intersect with the plurality of first lines, in which
   the memory cell is disposed at each of intersections of the plurality of first lines and the plurality of second lines,
   the voltage generator applies the specific voltage to the memory cell disposed at an intersection of a selected first line selected from among the plurality of first lines and a selected second line selected from among the plurality of second lines through the selected first line and the selected second line, and
   a voltage lower than the specific voltage is applied across the memory cell disposed at each of intersections of unselected first lines, which are the plurality of first lines other than the selected first line, and unselected second lines, which are the plurality of second lines other than the selected second line.
(9)
   The memory chip according to (8), in which the voltage lower than the specific voltage comprises a reference voltage.
(10)
   The memory chip according to (8) or (9), in which some of the plurality of second lines are disposed to be opposed to remaining ones of the plurality of second lines with the plurality of first lines interposed therebetween.
(11)
   The memory chip according to any one of (8) to (10), including a plurality of memory banks, each of the memory banks includes
   the plurality of first lines,
   the plurality of second lines,
   a plurality of the memory cells,
   a cell array circuit that executes one of a write process and a read process of data on a memory cell selected from among the plurality of the memory cells, and
   the control unit.
(12)
   The memory chip according to (11), in which
   the cell array circuit includes
   a first global line to which a positive electrode-side potential or a negative electrode-side potential of one of the first voltage, the second voltage, and the specific voltage is applied as necessary,
   a second global line to which the negative electrode-side potential or the positive electrode-side potential of one of the first voltage, the second voltage, and the specific voltage is applied as necessary,
   a first decoder that selects the selected first line from among the plurality of first lines on a basis of a bit line address inputted from the control unit, and couples the selected first line to the first global line,
   a second decoder that selects the selected second line from among the plurality of second lines on a basis of a word line address inputted from the control unit, and couples the selected second line to the second global line,
   a switching circuit that switches a voltage to be applied o the first global line and the second global line among the first voltage, the second voltage, and the specific voltage,
   a detector that detects the resistive state of the variable resistor element provided in the memory cell corresponding to the cell array circuit, and
   a holding unit that is able to hold write data and read data.
(13)

The memory chip according to (11) or (12), including a peripheral unit including a peripheral interface unit and a peripheral circuit, the peripheral interface unit to which write data and a bit address to be written to the memory cell are inputted and from which read data to be read out from the memory cell is outputted, and the peripheral circuit including the voltage generator.
(14)
   The memory chip according to (13), in which
   the peripheral circuit includes
   a memory access control unit that controls the plurality of memory banks, and
   a storage unit that stores information inputted from the control unit.
(15)
   The memory chip according to (14), in which the memory access control unit activates one of the plurality of memory banks on a basis of a bank address inputted from outside.
(16)
   A method of controlling a memory chip comprising:
   in a case where a write command including information that gives an instruction to write data to a memory cell, and write data to be written to the memory cell are inputted from outside, the memory cell including a variable resistor element and a switching element, the variable resistor element reversibly changeable between a low resistive state and a high resistive state, and the switching element having nonlinear current-voltage characteristics and being coupled in series to the variable resistor element,
   executing a first voltage application process, a specific voltage application process, and a third voltage application process by a control unit that controls the memory cell,
   the first voltage application process in which a first voltage to be applied to the memory cell in a case where the variable resistor element is changed to the low resistive state is applied to the memory cell,
   the specific voltage application process in which after the first volage is applied, a specific voltage is applied to the memory cell, the specific voltage being equal to or higher than a half of the first voltage and lower than a second voltage to be applied to the memory cell in a case where a resistive state of the variable resistor element is detected, and
   the third voltage application process in which after the specific voltage is applied, a third voltage to be applied to the memory cell in a case where the variable resistor element is changed to the high resistive state is applied to the memory cell.
(17)
   The method of controlling the memory chip according to (16), in which
   the control unit executes a preread process in which data stored in the memory cell is read out in advance before the first voltage application process,
   in a case where read data read out in the preread process is data corresponding to the resistive state of the variable resistor element being the low resistive state, the first voltage is not applied in the first voltage application process, and
   in a case where the read data read out in the preread process is data corresponding to the resistive state of the variable resistor element being the high resistive state, the third voltage is not applied to the memory cell in the third voltage application process.

It should be understood by those skilled in the art that various modifications, combinations, sub-combinations, and alterations may occur depending on design requirements and other factors insofar as they are within the scope of the appended claims or the equivalents thereof.

### REFERENCE SIGNS LIST

1: information processing system
2: semiconductor storage device
3: host computer
11: memory controller
12: memory device
13: work memory
31: memory chip
14: memory interface
15: printed circuit board
21: memory package
41: peripheral unit
42: memory bank
51: peripheral circuit
52: peripheral interface unit
52a: controller-side interface unit
52b: bank-side interface unit
53: microcontroller
54: memory cell arrangement region
61: memory tile
511: memory access control unit
512: write data register
513: read data register
514: mode register
515: DC/DC converter
516: voltage generator
517: current source
521: signal input/output unit
522: power input unit
523: signal input/output unit
524: analog voltage output unit
525: current output unit
531: positive-side voltage generator
532: negative-side voltage generator
533: reference voltage generator
541: positive-side write voltage regulator
542, 552, 562, 572: digital-analog converter
542a, 552a, 562a, 572a: ladder resistor circuit
542b, 552b, 552c, 572b, 572c: analog voltage selection unit
543, 553, 563, 573: output unit
543a, 553a, 563a, 573a: amplifier
543b, 553b: PMOS transistor
543c, 553c, 563c, 573c: capacitor
552d, 572d: selection unit
561: negative-side write voltage regulator
562b: analog voltage selection unit
563b, 573b: NMOS transistor
571: negative-side read voltage regulator
611: memory cell array
612: tile circuit
621: even number-side word line decoder
622: odd number-side word line decoder
623: even number-side bit line decoder
624: odd number-side bit line decoder
625: voltage switching unit
626: data latch unit
627: data detector
627l: lower sense amplifier
627u: upper sense amplifier
BL, BL0, BL1, BL2, BL3, BLk: bit line
GBL: global bit line
GWL: global word line
LMC, LMC00, LMC01, LMC10, LMC11: lower memory cell
LW: word line
LWL, LWL0, LWL1, LWL2, LWL3, LWLj: lower word line
MC: memory cell
r: resistor element
SE: selector element
UMC, UMC00, UMC01, UMC10, UMC11: upper memory cell
UWL, UWL0, UWL1, UWL2, UWL3, UWLi: upper word line
Vd+: positive-side disturb failure detection voltage
Vd: disturb failure detection voltage
Vd−: negative-side disturb failure detection voltage
Vinh_bl, Vinh_wl, Vinh_wu: blocking voltage
VR: variable resistor element
Vr: read voltage
Vr+: positive-side read voltage
Vr−: negative-side read voltage
Vref: reference voltage
Vrefl: lower reference voltage
Vrefu: upper reference voltage
Vrst: reset voltage
Vset: set voltage
Vw: write voltage
Vw+: positive-side write voltage
Vw−: negative-side write voltage
WL, WLi: word line

1. A memory chip comprising:
a memory cell including a variable resistor element and a switching element, the variable resistor element reversibly changeable between a low resistive state and a high resistive state, and the switching element having nonlinear current-voltage characteristics and being coupled in series to the variable resistor element;
a voltage generator that generates a first voltage to be applied to the memory cell in a case where the variable resistor element is changed to the low resistive state, and generates a second voltage to be applied to the memory cell in a case where a resistive state of the variable resistor element is detected, and a specific voltage that is equal to or higher than a half of the first voltage and lower than the second voltage; and
a control unit that controls the memory cell.

2. The memory chip according to claim 1, wherein the control unit controls determination whether or not the switching element of the memory cell to which the specific voltage is applied is turned to an on state.

3. The memory chip according to claim 1, wherein
the voltage generator includes a digital-analog converter that generates the second voltage and the specific voltage, and
the digital-analog converter includes
a first selection unit that selects the second voltage from among a plurality of analog voltages, and
a second selection unit that selects the specific voltage from among the plurality of analog voltages.

4. The memory chip according to claim 3, wherein the digital-analog converter includes a third selection unit that selects one of the second voltage and the specific voltage.

5. The memory chip according to claim 4, wherein the voltage generator includes an output unit that outputs, to the memory cell, a voltage inputted from the third selection unit.

6. The memory chip according to claim 1, wherein
in a case where a write command including information that gives an instruction to write data to the memory cell, and write data to be written to the memory cell are inputted from outside, the control unit is configured to be able to execute
a first voltage application process in which the first voltage is applied to the memory cell,
a specific voltage application process in which after the first volage is applied, the specific voltage is applied to the memory cell, and
a third voltage application process in which after the specific voltage is applied, a third voltage to be applied to the memory cell in a case where the variable resistor element is changed to the high resistive state is applied to the memory cell.

7. The memory chip according to claim 6, wherein in a case where the variable resistor element of the memory cell to which the third voltage is applied after the specific voltage is applied is in the low resistive state, the control unit determines that the memory cell is a memory cell in which an unrecoverable disturb failure has occurred.

8. The memory chip according to claim 1, comprising:
a plurality of first lines provided in parallel with each other; and
a plurality of second lines provided in parallel with each other, and disposed to intersect with the plurality of first lines, wherein
the memory cell is disposed at each of intersections of the plurality of first lines and the plurality of second lines,
the voltage generator applies the specific voltage to the memory cell disposed at an intersection of a selected first line selected from among the plurality of first lines and a selected second line selected from among the plurality of second lines through the selected first line and the selected second line, and
a voltage lower than the specific voltage is applied across the memory cell disposed at each of intersections of unselected first lines, which are the plurality of first lines other than the selected first line, and unselected second lines, which are the plurality of second lines other than the selected second line.

9. The memory chip according to claim 8, wherein the voltage lower than the specific voltage comprises a reference voltage.

10. The memory chip according to claim 8, wherein some of the plurality of second lines are disposed to be opposed to remaining ones of the plurality of second lines with the plurality of first lines interposed therebetween.

11. The memory chip according to claim 8, comprising a plurality of memory banks, each of the memory banks includes
the plurality of first lines,
the plurality of second lines,
a plurality of the memory cells,
a cell array circuit that executes one of a write process and a read process of data on a memory cell selected from among the plurality of the memory cells, and
the control unit.

12. The memory chip according to claim 11, wherein
the cell array circuit includes
a first global line to which a positive electrode-side potential or a negative electrode-side potential of one of the first voltage, the second voltage, and the specific voltage is applied as necessary,
a second global line to which the negative electrode-side potential or the positive electrode-side potential of one of the first voltage, the second voltage, and the specific voltage is applied as necessary,
a first decoder that selects the selected first line from among the plurality of first lines on a basis of a bit line address inputted from the control unit, and couples the selected first line to the first global line,
a second decoder that selects the selected second line from among the plurality of second lines on a basis of a word line address inputted from the control unit, and couples the selected second line to the second global line,
a switching circuit that switches a voltage to be applied o the first global line and the second global line among the first voltage, the second voltage, and the specific voltage,
a detector that detects the resistive state of the variable resistor element provided in the memory cell corresponding to the cell array circuit, and
a holding unit that is able to hold write data and read data.

13. The memory chip according to claim 11, comprising a peripheral unit including a peripheral interface unit and a peripheral circuit, the peripheral interface unit to which write data and a bit address to be written to the memory cell are inputted and from which read data to be read out from the memory cell is outputted, and the peripheral circuit including the voltage generator.

14. The memory chip according to claim 13, wherein
the peripheral circuit includes
a memory access control unit that controls the plurality of memory banks, and
a storage unit that stores information inputted from the control unit.

15. The memory chip according to claim 14, wherein the memory access control unit activates one of the plurality of memory banks on a basis of a bank address inputted from outside.

16. A method of controlling a memory chip comprising:
in a case where a write command including information that gives an instruction to write data to a memory cell, and write data to be written to the memory cell are inputted from outside, the memory cell including a variable resistor element and a switching element, the variable resistor element reversibly changeable between a low resistive state and a high resistive state, and the switching element having nonlinear current-voltage characteristics and being coupled in series to the variable resistor element,
executing a first voltage application process, a specific voltage application process, and a third voltage application process by a control unit that controls the memory cell,
the first voltage application process in which a first voltage to be applied to the memory cell in a case where the variable resistor element is changed to the low resistive state is applied to the memory cell,
the specific voltage application process in which after the first volage is applied, a specific voltage is applied to the memory cell, the specific voltage being equal to or higher than a half of the first voltage and lower than a second voltage to be applied to the memory cell in a case where a resistive state of the variable resistor element is detected, and
the third voltage application process in which after the specific voltage is applied, a third voltage to be applied to the memory cell in a case where the variable resistor element is changed to the high resistive state is applied to the memory cell.

17. The method of controlling the memory chip according to claim 16, wherein
the control unit executes a preread process in which data stored in the memory cell is read out in advance before the first voltage application process,
in a case where read data read out in the preread process is data corresponding to the resistive state of the variable resistor element being the low resistive state, the first voltage is not applied in the first voltage application process, and
in a case where the read data read out in the preread process is data corresponding to the resistive state of the variable resistor element being the high resistive state, the third voltage is not applied to the memory cell in the third voltage application process.
